(19) United States
(12) Patent Application Publication
(10) Pub. No.: US 2025/0283762 A1
(43) Pub. Date: Sep. 11, 2025

(54) PHOTODETECTOR PIXEL, PHOTODETECTOR AND METHODS OF FORMING THE SAME

(71) Applicant: Nanyang Technological University, Singapore (SG)

(72) Inventors: Mingjin Dai, Singapore (SG); Chongwu Wang, Singapore (SG); Fakun Wang, Singapore (SG); Qijie Wang, Singapore (SG)

(21) Appl. No.: 18/862,532

(22) PCT Filed: May 23, 2023
(86) PCT No.: PCT/SG2023/050355

§ 371 Date: Nov. 3, 2024

(30) Foreign Application Priority Data
Jun. 7, 2022 (SG) 10202250076Y

(51) Int. Cl. G01J 5/12; G01J 5/08; H10N 10/10

(52) U.S. Cl. CPC G01J 5/12; G01J 5/0853; G01J 2005/123; H10N 10/10

(57) ABSTRACT

Various embodiments may provide a photodetector pixel. The photodetector pixel may include a chiral plasmonic molecule array configured to generate heat upon incidence of an electromagnetic wave on the chiral plasmonic molecule array. The photodetector pixel may also include a thermoelectric layer configured to generate an electric current or voltage upon transfer of heat from the chiral plasmonic molecule array to the thermoelectric layer. The chiral plasmonic molecule array may include a metal layer, one or more nanostructures, and a dielectric spacer such that the dielectric spacer is between the metal layer and the one or more nanostructures. The one or more nanostructures may include one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

### CROSS-REFERENCE TO RELATED APPLICATION

This application claims the benefit of priority of Singapore application No. 10202250076Y filed Jun. 7, 2022, the contents of it being hereby incorporated by reference in its entirety for all purposes.

### TECHNICAL FIELD

Various embodiments of this disclosure may relate to a photodetector pixel. Various embodiments of this disclosure may relate to a photodetector. Various embodiments of this disclosure may relate to a method of forming a photodetector pixel. Various embodiments of this disclosure may relate to a method of forming a photodetector.

### BACKGROUND

State of polarization (SoP) charactering the electric field oscillation is essential for optic-related applications such as optical communication, remote sensing, and navigation. Mid-infrared (mid-IR) polarization detectors are especially attractive owing to its widespread applications in chemical analysis, biomedical diagnosis, and face recognition. For decades, conventional polarization detection approaches include division-of-time, division-of-amplitude, division-of-aperture, and division-of-focal-plane, which normally require a combination of linear retarders, polarizers, half-wave plates, and quarter-wave plates. However, such bulky and complicated optical systems by using free-space polarizer have inherent drawbacks such as limited speed, limited accuracy, and incomplete polarization state detection. Recent advances in low-dimensional materials science and nanophotonic technologies have unveiled fascinating avenues to develop the next-generation polarimeters. As a potential candidate for next-generation compact polarimeters, the on-chip polarization-sensitive photodetectors have been widely studied recently owning to their advantages including high level of miniaturization and ultrahigh-density integration.

Up to now, one of the mainstream approaches to detect SoP is based on the structural anisotropy or chirality from the natural materials. In general, photodetectors for linear polarization detection rely on the anisotropic absorption of one-dimensional nanowires or two-dimensional van der Waals materials, while photodetectors for circular polarization detection are based on the chiral absorption of light in organic semiconductors and hybrid perovskites, the spin photogalvanic effect in topological insulator or semimetals, inverse spin Hall effect at metal-semiconductor interface, and spin dependent recombination of conduction electrons. However, the applications of these kind polarization sensitive photodetectors are hindered by intrinsic limitations such as bandgap-dependent spectral response, chemical instability, low polarization sensitivity correlated by intrinsic anisotropy or chirality. In addition, most of these polarization-sensitive photodetectors only work for detection of either linear polarization or circular polarization of light but cannot be applied to full-Stokes detection. As artificial structures can achieve strong anisotropy and chirality, and have a great design flexibility and a filterless configuration, such functional photodetectors enabled by artificial structures can realize compact polarimetry for polarized light detection, as well as polarization imaging with potentially ultra-high pixel density. Using artificial structures integrated with active materials is another main approach for detection of SoP. This approach led to polarization-sensitive photodetectors operating in scattered, absorbed, and guided radiation modes. As an example, the plasmonic metamaterials with polarization-selective field enhancement have been integrated with semiconductors to generate polarization sensitive photocurrents. However, most of previous detectors relied on the photoconductive or the photovoltaic effect, which requires matching between the resonant wavelength of plasmonic metamaterials and the bandgap of semiconductors. Therefore, an efficient way to transfer strong anisotropy and chirality to electrical readouts without the operation wavelength limitation by the bandgap of active materials is highly desired.

### SUMMARY

Various embodiments may provide a photodetector pixel. The photodetector pixel may include a chiral plasmonic molecule array configured to generate heat upon incidence of an electromagnetic wave on the chiral plasmonic molecule array. The photodetector pixel may also include a thermoelectric layer configured to generate an electric current or voltage upon transfer of heat from the chiral plasmonic molecule array to the thermoelectric layer. The chiral plasmonic molecule array may include a metal layer. The chiral plasmonic molecule array may include one or more nanostructures. The chiral plasmonic molecule array may also include a dielectric spacer such that the dielectric spacer is between the metal layer and the one or more nanostructures. The one or more nanostructures may include one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

Various embodiments may relate to a photodetector. The photodetector may include a first photodetector pixel, which may be a photodetector pixel as described herein. The one or more nanostructures of the first photodetector may include or consist of one or more left hand (LH) chiral metamaterial nanostructures and one or more right hand (RH) chiral metamaterial nanostructures. The photodetector may also include a second photodetector pixel, which may be a photodetector pixel as described herein. The second photodetector pixel may be oriented 90° to the first photodetector pixel. The one or more nanostructures of the second photodetector pixel may include or consist of one or more left hand (LH) chiral metamaterial nanostructures and one or more right hand (RH) chiral metamaterial nanostructures. The photodetector may further include a third photodetector pixel, which may be a photodetector pixel as described herein. The third photodetector pixel may be oriented 45° to the first photodetector pixel. The one or more nanostructures may include or consist of one or more left hand (LH) chiral metamaterial nanostructures. The photodetector may also include a fourth photodetector pixel, which may be a photodetector pixel as described herein. The fourth photodetector pixel may be oriented 45° to the first photodetector pixel. The one or more nanostructures may include or consist of one or more right hand (RH) chiral metamaterial nanostructures. The third photodetector pixel or the fourth photodetector pixel may be configured to determine an ellipticity angle of a state of polarization of the electromagnetic wave. The third photodetector pixel or the fourth photodetector pixel that is not used or configured to determine the ellipticity angle may be grounded. The first photodetector pixel and the second photodetector pixel may be configured to determine an azimuthal angle of the state of polarization of the electromagnetic waves.

Various embodiments may provide a method of forming a photodetector pixel. The method may include forming a chiral plasmonic molecule array configured to generate heat upon incidence of an electromagnetic wave on the chiral plasmonic molecule array. The method may also include forming a thermoelectric layer configured to generate an electric current or voltage upon transfer of heat from the chiral plasmonic molecule array to the thermoelectric layer. The chiral plasmonic molecule array may include a metal layer. The chiral plasmonic molecule array may include one or more nanostructures. The chiral plasmonic molecule array may include a dielectric spacer such that the dielectric spacer is between the metal layer and the one or more nanostructures. The one or more nanostructures may include one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

Various embodiments may relate to a method of forming a photodetector. The method may include forming a first photodetector pixel, which may be a photodetector pixel as described herein. The one or more nanostructures of the first photodetector may include or consist of one or more left hand (LH) chiral metamaterial nanostructures and one or more right hand (RH) chiral metamaterial nanostructures. The method may also include forming a second photodetector pixel, which may be a photodetector pixel as described herein. The second photodetector pixel may be oriented 90° to the first photodetector pixel. The one or more nanostructures of the second photodetector pixel may include or consist of one or more left hand (LH) chiral metamaterial nanostructures and one or more right hand (RH) chiral metamaterial nanostructures. The method may further include forming a third photodetector pixel, which may be a photodetector pixel as described herein. The third photodetector pixel may be oriented 45° to the first photodetector pixel. The one or more nanostructures may include or consist of one or more left hand (LH) chiral metamaterial nanostructures. The method may also include forming a fourth photodetector pixel, which may be a photodetector pixel as described herein. The fourth photodetector pixel may be oriented 45° to the first photodetector pixel. The one or more nanostructures may include or consist of one or more right hand (RH) chiral metamaterial nanostructures. The third photodetector pixel or the fourth photodetector pixel may be configured to determine an ellipticity angle of a state of polarization of the electromagnetic wave. The third photodetector pixel or the fourth photodetector pixel that is not used or configured to determine the ellipticity angle may be grounded. The first photodetector pixel and the second photodetector pixel may be configured to determine an azimuthal angle of the state of polarization of the electromagnetic waves.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows a schematic of a photodetector pixel according to various embodiments.

FIG. 2 shows a schematic of a method of forming a photodetector pixel according to various embodiments.

FIG. 3A shows (left) a schematic of a photodetector pixel for resonance thermoelectric photoresponse according to various embodiments; and (right) a chiral plasmonic molecule array including a metal layer, a dielectric spacer and metamaterial layer according to various embodiments.

FIG. 3B is a plot of absorption (in percent or %)/temperature change or ΔT (in Kelvins or K) as a function of wavelength (in micrometres or m) showing the simulated absorption and temperature increase with varying wavelengths of incident light having input power of 5 mW according to various embodiments.

FIG. 3C shows full wave simulations of normalized electric field distribution (left) and normalized power absorption distribution (right) of cross-sections of the photodetector pixel according to various embodiments.

FIG. 3D shows a thermal simulation of a device with left half-channel covered by the nanostructures at peak absorption with input power of 5 mW according to various embodiments.

FIG. 3E shows a plot of temperature (in Kelvins or K)/potential (in microVolts or μV) as a distance along the channel (in micrometres or m) illustrating the corresponding temperature and potential profiles across the device channel shown in FIG. 3D according to various embodiments.

FIG. 4A shows plots of absorbance (in percent or %) as a function of wavelengths (in micrometres or m) illustrating the effect of the thickness of the dielectric spacer (aluminium oxide or Al₂O₃) on the optical absorption of different polarized light (a)-(d) by the metamaterials according to various embodiments.

FIG. 4B shows a table of structure parameters of metamaterials (M₁ to M₅) with different absorption wavelength peaks according to various embodiments.

FIG. 5A shows plots of absorbance (in percent or %) as a function of wavelength (in micrometres or m) illustrating the simulated linear polarization dependent optical absorption of metal materials (a) M₁, (b) M₂ and (c) M₄ according to various embodiments.

FIG. 5B shows a plot of absorbance (in percent or %) as a function of wavelength (in micrometres or m) showing the simulated optical absorption under left-handed circular polarized (LCP) and right-handed circular polarized (RCP) light illumination for left hand (LH) metamaterials with different dimensions (M₁ to M₅) according to various embodiments.

FIG. 5C shows a plot of circular dichroism (CD) (in percent or %) as a function of wavelength (in micrometres or m) illustrating the corresponding CD for both left hand (LH) metamaterials and right hand (RH) metamaterials according to various embodiments.

FIG. 6A shows (left) an image of left-hand (LH) metamaterials M₁ according to various embodiments; and (right) an image of right-hand (RH) metamaterials M₁ according to various embodiments.

FIG. 6B shows a plot of absorbance (in percent or %) as a function of wavelength (in micrometres or m) illustrating measured linear polarization dependent optical absorption for left-hand (LH) metamaterials M₁ according to various embodiments.

FIG. 6C shows a plot of circular dichroism (CD) (in percent or %) as a function of wavelength (in micrometres or m) illustrating the variation of CD with wavelength for both left-hand (LH) metamaterials M₁ according to various embodiments and right-hand (RH) metamaterials M₁ according to various embodiments.

FIG. 6D shows plots of absorbance (in percent or %) as a function of wavelength (in micrometres or m) illustrating the measured optical absorption under left-handed circular polarized (LCP) and right-handed circular polarized (RCP) light illumination for (left) left-hand (LH) metamaterials M₁ according to various embodiments and (right) right-hand (RH) metamaterials M₁ according to various embodiments.

FIG. 7A shows (left) an image of left-hand (LH) metamaterials M₂ according to various embodiments; and (right) an image of right-hand (RH) metamaterials M₂ according to various embodiments.

FIG. 7B shows a plot of absorbance (in percent or %) as a function of wavelength (in micrometres or m) illustrating measured linear polarization dependent optical absorption for left-hand (LH) metamaterials M₂ according to various embodiments.

FIG. 7C shows a plot of circular dichroism (CD) (in percent or %) as a function of wavelength (in micrometres or m) illustrating the variation of CD with wavelength for both left-hand (LH) metamaterials M₂ according to various embodiments and right-hand (RH) metamaterials M₂ according to various embodiments.

FIG. 7D shows plots of absorbance (in percent or %) as a function of wavelength (in micrometres or m) illustrating the measured optical absorption under left-handed circular polarized (LCP) and right-handed circular polarized (RCP) light illumination for (left) left-hand (LH) metamaterials M₂ according to various embodiments and (right) right-hand (RH) metamaterials M₂ according to various embodiments.

FIG. 8A shows (left) an image of left-hand (LH) metamaterials M₄ according to various embodiments; and (right) an image of right-hand (RH) metamaterials M₄ according to various embodiments.

FIG. 8B shows a plot of absorbance (in percent or %) as a function of wavelength (in micrometres or m) illustrating measured linear polarization dependent optical absorption for left-hand (LH) metamaterials M₄ according to various embodiments.

FIG. 8C shows a plot of circular dichroism (CD) (in percent or %) as a function of wavelength (in micrometres or m) illustrating the variation of CD with wavelength for both left-hand (LH) metamaterials M₄ according to various embodiments and right-hand (RH) metamaterials M₄ according to various embodiments.

FIG. 8D shows plots of absorbance (in percent or %) as a function of wavelength (in micrometres or m) illustrating the measured optical absorption under left-handed circular polarized (LCP) and right-handed circular polarized (RCP) light illumination for (left) left-hand (LH) metamaterials M₄ according to various embodiments and (right) right-hand (RH) metamaterials M₄ according to various embodiments.

FIG. 9A shows a schematic of the left-hand (LH) M₂ metamaterial according to various embodiments.

FIG. 9B is a two-dimensional contour map of ellipticity angle φ (in degrees or °) as a function of azimuthal angle θ (in degrees or °) illustrating both simulated absorbance (Abs, in percent or %) and induced temperature increase (ΔT, in Kelvins or K) for both different light polarization status according to various embodiments.

FIG. 9C shows the corresponding power absorption density normalized by P₀ for different polarization status labelled by (i)-(v) in FIG. 9B of the left-hand (LH) metamaterial according to various embodiments.

FIG. 9D shows the electric field distributions normalized to incident electric field at different polarization status for the left-hand (LH) metamaterial according to various embodiments.

FIG. 9E shows a plot of temperature increase (ΔT) (in Kelvins or K) as a function of laser power (in milliWatts or mW) illustrating the analytical temperature increase of the left-hand (LH) metamaterial under incident laser power of different polarization status according to various embodiments.

FIG. 9F shows a plot of absorption (in percent or %) as a function of azimuthal angle θ (in degrees or °) illustrating the stimulated absorbance at different ellipticity angles φ for both left-hand (LH) and right-hand (RH) metamaterials according to various embodiments.

FIG. 9G shows a plot of absorption (in percent or %) as a function of ellipticity angle φ (in degrees or °) illustrating the stimulated absorbance at different azimuthal angles θ for both left-hand (LH) and right-hand (RH) metamaterials according to various embodiments.

FIG. 10A shows an optical image of a graphene-based device according to various embodiments.

FIG. 10B shows a plot of the photovoltage (Vₚₕ) response (in microVolts or μV) as a function of polarization angle θ (in degrees or °) illustrating the polarization angle dependent photoresponse of the graphene-based device according to various embodiments.

FIG. 10C shows a plot of the photovoltage (Vₚₕ) response (in microVolts or μV) as a function of quarter-wave plate (QWP) angle θ (in degrees or °) illustrating the QWP angle dependent photoresponse of the graphene-based device according to various embodiments.

FIG. 11A shows an optical image of a black phosphorous (BP)-based device according to various embodiments.

FIG. 11B shows a plot of the photovoltage (Vₚₕ) response (in microVolts or μV) as a function of polarization angle θ (in degrees or °) illustrating the polarization angle dependent photoresponse of the black phosphorous (BP)-based device according to various embodiments.

FIG. 11C shows a plot of the photovoltage (Vₚₕ) response (in microVolts or μV) as a function of quarter-wave plate (QWP) angle θ (in degrees or °) illustrating the QWP angle dependent photoresponse of the black phosphorous (BP)-based device according to various embodiments.

FIG. 12A shows an optical image of a lead selenide (PdSe₂) device for 4.5 μm infrared light detection according to various embodiments.

FIG. 12B shows a plot of the photovoltage (Vₚₕ) response (in microVolts or μV) as a function of polarization angle (in degrees or °) illustrating the half-wave plate (HWP) angle dependent photoresponse of the lead selenide (PdSe₂) device under 4.5 μm infrared illumination according to various embodiments.

FIG. 12C shows a plot of the photovoltage (Vₚₕ) response (in microVolts or μV) as a function of quarter-wave plate (QWP) angle (in degrees or °) illustrating the quarter-wave plate (QWP) angle dependent photoresponse of the lead selenide (PdSe₂) device under 4.5 μm infrared illumination according to various embodiments.

FIG. 12D shows an optical image of a lead selenide (PdSe₂) device for 7.0 μm infrared light detection according to various embodiments.

FIG. 12E shows a plot of the photovoltage (Vₚₕ) response (in microVolts or μV) as a function of polarization angle (in degrees or °) illustrating the half-wave plate (HWP) angle dependent photoresponse of the lead selenide (PdSe₂) device under 7.0 μm infrared illumination according to various embodiments.

FIG. 12F shows a plot of the photovoltage (Vₚₕ) response (in microVolts or μV) as a function of quarter-wave plate (QWP) angle (in degrees or °) illustrating the quarter-wave plate (QWP) angle dependent photoresponse of the lead selenide (PdSe₂) device under 7.0 μm infrared illumination according to various embodiments.

FIG. 13A shows a plot of absorption (in percent or %)/responsivity (in volts per watt or V/W) as a function of wavelength (in micrometres or m) illustrating the absorption spectrum (line) of left hand (LH)—M₂ metamaterials under linear polarized light illumination and the corresponding responsivity (dots) of the LH-M₂ metamaterials mediated device according to various embodiments. The incident laser power is fixed at 20 mW.

FIG. 13B shows plots of photoresponse (in arbitrary units or a.u.) as a function of time (in microseconds or s) illustrating the time-resolved photoresponse (left: rise; right: decay) of the lead selenide (PdSe₂) device under 5.3 μm laser illumination according to various embodiments.

FIG. 13C shows a plot of photoresponse (in arbitrary units or a.u.) as a function of time (in milliseconds or ms) illustrating the measured time-resolved photoresponse of the lead selenide (PdSe₂) device with illumination signal chopped at 1000 Hz according to various embodiments.

FIG. 13D shows a plot of normalized photoresponse (in decibels or dB) as a function of frequency (in hertz or Hz) of the lead selenide (PdSe₂) device illustrating a −3 dB bandwidth of around 1.1 kHz according to various embodiments.

FIG. 13E shows a plot of the photovoltage (Vₚₕ) response (in microVolts or μV) as a function of time (in seconds or s) illustrating the measured long-term photoresponse of the lead selenide (PdSe₂) device according to various embodiments.

FIG. 14A shows a plot of voltage (in nanoVolts or nV) as a function of data illustrating the voltage data measured with a lock-in amplifier under an internal reference frequency of 100 Hz according to various embodiments.

FIG. 14B shows a plot of voltage (in nanoVolts or nV) as a function of data illustrating the voltage data measured with a lock-in amplifier under an internal reference frequency of 1 kHz according to various embodiments.

FIG. 14C shows a plot of voltage (in nanoVolts or nV) as a function of data illustrating the voltage data measured with a lock-in amplifier under different internal reference frequency of 10 kHz according to various embodiments.

FIG. 14D shows a plot of noise (in nanoVolts per square root Hertz or nV Hz^{-1/2}) as a function of frequency (in Hertz or Hz) illustrating the spectral density of voltage noise showing a dramatic decrease with frequency and then keeping constant when the frequency is over about 1 kHz according to various embodiments.

FIG. 15A shows a plot of photovoltage (Vₚₕ) response (in microVolts or μV) as a function of time (in seconds or s) illustrating the photoresponses of the device at different temperatures according to various embodiments.

FIG. 15B shows a plot of photovoltage (Vₚₕ) response (in microVolts or μV) as a function of temperature (in Kelvins or K) illustrating the temperature-dependent photovoltages generated by the device with an incident light power of 38 W according to various embodiments.

FIG. 16A is a schematic of a photodetector having two pixels or nanoantenna arrays with an orientation angles of 90° between each other according to various embodiments.

FIG. 16B shows a plot of polarization angle (in degrees or °) as a function of polarization ratio (PR) illustrating the variation of the linear polarization angle θ-dependent photoresponse Vₚₕ (A₁, A₂, θ) and the PR transition from unipolar regime to bipolar regime according to various embodiments. The bar shows the normalized photoresponse.

FIG. 16C shows a plot of photoresponse Vₚₕ (in arbitrary units or a.u.) as a function of polarization angle (in degrees or °) illustrating the simulated (lines) and measured (solid circles) photoresponse of five devices (i)-(v) according to various embodiments.

FIG. 17A shows an optical image of a device with A₂/A₁ ratio of 0 according to various embodiments.

FIG. 17B shows a plot of the channel current (I_{ds}) (in nanoAmperes or nA) as a function of the channel voltage (V_{ds}) (in microVolts or μV) of the device with A₂/A₁ ratio of 0 according to various embodiments.

FIG. 17C shows a plot of photovoltage response Vₚₕ (in microVolts or μV) as a function of polarization angle θ (in degrees or °) showing the linear polarization response of the device with A₂/A₁ ratio of 0 according to various embodiments.

FIG. 18A shows an optical image of a device with A₂/A₁ ratio of 0.33 according to various embodiments.

FIG. 18B shows a plot of the channel current (I_{ds}) (in nanoAmperes or nA) as a function of the channel voltage (V_{ds}) (in microVolts or μV) of the device with A₂/A₁ ratio of 0.33 according to various embodiments.

FIG. 18C shows a plot of photovoltage response Vₚₕ (in microVolts or μV) as a function of polarization angle θ (in degrees or °) showing the linear polarization response of the device with A₂/A₁ ratio of 0.33 according to various embodiments.

FIG. 19A shows an optical image of a device with A₂/A₁ ratio of 0.5 according to various embodiments.

FIG. 19B shows a plot of the channel current (I_{ds}) (in nanoAmperes or nA) as a function of the channel voltage (V_{ds}) (in microVolts or μV) of the device with A₂/A₁ ratio of 0.5 according to various embodiments.

FIG. 19C shows a plot of photovoltage response Vₚₕ (in microVolts or μV) as a function of polarization angle θ (in degrees or °) showing the linear polarization response of the device with A₂/A₁ ratio of 0.5 according to various embodiments.

FIG. 20A shows an optical image of a device with A₂/A₁ ratio of 0.67 according to various embodiments.

FIG. 20B shows a plot of the channel current (I_{ds}) (in nanoAmperes or nA) as a function of the channel voltage (V_{ds}) (in microVolts or μV) of the device with A₂/A₁ ratio of 0.67 according to various embodiments.

FIG. 20C shows a plot of photovoltage response Vₚₕ (in microVolts or μV) as a function of polarization angle θ (in degrees or °) showing the linear polarization response of the device with A₂/A₁ ratio of 0.67 according to various embodiments.

FIG. 21A shows an optical image of a device with A₂/A₁ ratio of 1 and orientation angle α of 0° according to various embodiments.

FIG. 21B shows a plot of photovoltage response Vₚₕ (in microVolts or μV) as a function of polarization angle θ (in degrees or °) showing the linear polarization response of the device with A₂/A₁ ratio of 1 and orientation angle α of 0° according to various embodiments.

FIG. 22A shows an optical image of a device with A₂/A₁ ratio of 1 and orientation angle α of 45° according to various embodiments.

FIG. 22B shows a plot of photovoltage response Vₚₕ (in microVolts or μV) as a function of polarization angle θ (in degrees or °) showing the linear polarization response of the device with A₂/A₁ ratio of 1 and orientation angle α of 45° according to various embodiments.

FIG. 23A shows an optical image of a device with A₂/A₁ ratio of 1 and orientation angle α of 90° according to various embodiments.

FIG. 23B shows a plot of photovoltage response Vₚₕ (in microVolts or μV) as a function of polarization angle θ (in degrees or °) showing the linear polarization response of the device with A₂/A₁ ratio of 1 and orientation angle α of 90° according to various embodiments.

FIG. 24A is a schematic showing the calculation of the linear polarization angle θ-dependent photoresponses Vₚₕ (α, θ) with different orientation angles α of two arrays of metamaterials with the same distribution area according to various embodiments.

FIG. 24B is a plot of polarization angle θ (in degrees or °) as a function of orientation angle (in degrees or °) illustrating the variation of linear polarization angle θ-dependent photoresponses Vₚₕ (α, θ) of the device with orientation angle according to various embodiments.

FIG. 24C shows a plot of normalized photoresponses (in arbitrary units or a.u.) as a function of polarization angle θ (in degrees or °) illustrating the simulated photoresponses of various devices (lines) and measured photoresponses of three devices (circles) with polarization ratio (PR) of −1 according to various embodiments.

FIG. 25A is a schematic of a photodetector having a pixel or nanoantenna array having left-hand (LH) and another pixel or nanoantenna array having right-hand (RH) metamaterials according to various embodiments.

FIG. 25B shows a plot of quarter-wave plate QWP angle (in degrees or °) as a function of g-factor illustrating the variation of the QWP angle ψ (A₁, A₂, ψ) and the g-factor transition from unipolar regime to bipolar regime according to various embodiments.

FIG. 25C shows a plot of photoresponse Vph (in arbitrary units or a.u.) as a function of quarter-wave plate QWP angle (in degrees or °) illustrating the simulated (lines) and measured (solid circles) photoresponse of four devices (i)-(iv) according to various embodiments.

FIG. 26A shows an optical image of a device with A₂/A₁ ratio of 0 according to various embodiments.

FIG. 26B shows a plot of photovoltage response Vₚₕ (in microVolts or μV) as a function of quarter-wave plate QWP angle (in degrees or °) showing the measured QWP angle dependent response of the device with A₂/A₁ ratio of 0 according to various embodiments.

FIG. 27A shows an optical image of a device with A₂/A₁ ratio of 0.33 according to various embodiments.

FIG. 27B shows a plot of photovoltage response Vₚₕ (in microVolts or μV) as a function of quarter-wave plate QWP angle (in degrees or °) showing the measured QWP angle dependent response of the device with A₂/A₁ ratio of 0.33 according to various embodiments.

FIG. 28A shows an optical image of a device with A₂/A₁ ratio of 0.67 according to various embodiments.

FIG. 28B shows a plot of photovoltage response Vₚₕ (in microVolts or μV) as a function of quarter-wave plate QWP angle (in degrees or °) showing the measured QWP angle dependent response of the device with A₂/A₁ ratio of 0.67 according to various embodiments.

FIG. 29A shows an optical image of a device with A₂/A₁ ratio of 1 and orientation angle α of 0° according to various embodiments.

FIG. 29B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 0° according to various embodiments.

FIG. 30A shows an optical image of a device with A₂/A₁ ratio of 1 and orientation angle α of 10° according to various embodiments.

FIG. 30B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 10° according to various embodiments.

FIG. 31A shows an optical image of a device with A₂/A₁ ratio of 1 and orientation angle α of 20° according to various embodiments.

FIG. 31B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 20° according to various embodiments.

FIG. 32A shows a plot of photovoltage response Vₚₕ (in microVolts or μV) as a function of quarter-wave plate QWP angle (in degrees or °) showing the measured QWP angle dependent response of the device when the linear polarization angle is 30° according to various embodiments.

FIG. 32B shows a plot of photovoltage response Vₚₕ (in microVolts or μV) as a function of quarter-wave plate QWP angle (in degrees or °) showing the measured QWP angle dependent response of the device when the linear polarization angle is 60° according to various embodiments.

FIG. 32C shows a plot of photovoltage response Vₚₕ (in microVolts or μV) as a function of quarter-wave plate QWP angle (in degrees or °) showing the measured QWP angle dependent response of the device when the linear polarization angle is 90° according to various embodiments.

FIG. 32D shows a plot of photovoltage response Vₚₕ (in microVolts or μV) as a function of quarter-wave plate QWP angle (in degrees or °) showing the measured QWP angle dependent response of the device when the linear polarization angle is 120° according to various embodiments.

FIG. 32E shows a plot of photovoltage response Vₚₕ (in microVolts or μV) as a function of quarter-wave plate QWP angle (in degrees or °) showing the measured QWP angle dependent response of the device when the linear polarization angle is 150° according to various embodiments.

FIG. 32F shows a plot of photovoltage response Vₚₕ (in microVolts or μV) as a function of quarter-wave plate QWP angle (in degrees or °) showing the measured QWP angle dependent response of the device when the linear polarization angle is 180° according to various embodiments.

FIG. 33A shows a table comparing existing linear polarization sensitive photodetectors with the photodetector according to various embodiments.

FIG. 33B shows a table comparing existing circular polarization sensitive photodetectors with the photodetector according to various embodiments.

FIG. 34A shows an optical image of a three-ports photodetector according to various embodiments.

FIG. 34B shows a schematic illustration of the full-Stokes information in a Poincare sphere according to various embodiments.

FIG. 35A shows a plot of half-wave plate (HWP) angle (degrees or °) as a function of quarter-wave plate (QWP) angle (degrees or °) illustrating the photoresponse (Vₚₕ) of Port 1 of the photodetector with HWP angle and QWP angle according to various embodiments.

FIG. 35B shows a plot of half-wave plate (HWP) angle (degrees or °) as a function of quarter-wave plate (QWP) angle (degrees or °) illustrating the photoresponse (Vₚₕ) of Port 2 of the photodetector with HWP angle and QWP angle according to various embodiments.

FIG. 35C shows a plot of half-wave plate (HWP) angle (degrees or °) as a function of quarter-wave plate (QWP) angle (degrees or °) illustrating the photoresponse (Vₚₕ) of Port 3 of the photodetector with HWP angle and QWP angle according to various embodiments.

FIG. 36A shows a two-dimensional (2D) plot of the photoresponse voltage at Port 2 (in microVolts or μV) as a function of the photoresponse voltage at Port 1 (in microVolts or μV) of the photodetector under different azimuthal angles θ and the ellipticity angles φ according to various embodiments.

FIG. 36B shows plots of the photoresponse voltage at Port 3 (in microVolts or μV) as a function of ellipticity angle φ (in radians) showing the variation of the photoresponse voltage with ellipticity angle φ at different azimuthal angles θ according to various embodiments.

FIG. 36C shows a two-dimensional (2D) plot of the photoresponse voltage at Port 2 (in microVolts or μV) as a function of the photoresponse voltage at Port 1 (in microVolts or μV) of the photodetector under different incident light powers according to various embodiments.

FIG. 36D shows a plot of the photoresponse voltage at Port 3 (in microVolts or μV) as a function of power (in microWatts or μW) illustrating the photoresponse for left-handed circular polarized (LCP) and right-handed circular polarized (RCP) light under different laser powers at the photodetector according to various embodiments.

FIG. 37A illustrates the retrieved Stokes parameters with different polarization states according to various embodiments.

FIG. 37B shows a plot of average error (in percent or %) as a function of Stokes parameter illustrating the calculated average errors of three Stokes parameters (S₁, S₂ and S₃) according to various embodiments.

FIG. 38A shows a schematic of the polarimetric imaging measurement system and the mechanism for the calculation of angle of linear polarization (AoLP), degree of linear polarization (DoLP) or degree of circular polarization (DoCP) according to various embodiments.

FIG. 38B shows the measured imaging results of the ports (Port 1, Port 2, and Port 3) and calculated imaging results of angle of linear polarization (AoLP) and degree of circular polarization (DoCP) under linear polarized (LP) 45° light illumination according to various embodiments.

FIG. 38C shows the measured imaging results of the ports (Port 1, Port 2, and Port 3) and calculated imaging results of angle of linear polarization (AoLP) and degree of circular polarization (DoCP) under linear polarized (LP) 135° light illumination according to various embodiments.

FIG. 38D shows the measured imaging results of the ports (Port 1, Port 2, and Port 3) and calculated imaging results of angle of linear polarization (AoLP) and degree of circular polarization (DoCP) under left circular polarized (LCP) light illumination according to various embodiments.

FIG. 38E shows the measured imaging results of the ports (Port 1, Port 2, and Port 3) and calculated imaging results of angle of linear polarization (AoLP) and degree of circular polarization (DoCP) under right circular polarized (RCP) light illumination according to various embodiments.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a” “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the photodetector pixels or photodetectors are analogously valid for the other photodetector pixels or photodetectors. Similarly, embodiments described in the context of a method are analogously valid for a photodetector pixel or photodetector, and vice versa.

Standard SoP detection requires at least four measurements for obtaining four Stokes parameters, namely the light intensity, two linear polarization components, and one circular polarization component. In other words, both linear and circular polarization sensitive photodetectors are needed for full-Stokes detection. For linear and circular polarization-sensitive photodetectors, the crucial figure of merits to characterize the polarization sensitivity are the polarization ratio (PR) and dissymmetry factor (g). The large PR and g values are highly critical for improving the accuracy of detection in practical applications. However, most previously reported polarization sensitive photodetectors usually exhibit unipolar polarization-dependent photoresponses and the corresponding PR and g-factor are generally small, e.g. 0<PR<20 and 0<g<2. It may be noted that the PR and g factor are calculated using PR=Vₘₐₓ/Vₘᵢₙ, and g=2×(V_{LCP}−V_{RCP})/(V_{LCP}+V_{RCP}), where Vₘₐₓ and Vₘᵢₙ indicate the maximum and minimum linear polarization dependent photovoltage, respectively, and V_{LCP} and V_{RCP} denote the photovoltages under left-handed circular polarized (LCP) and right-handed circular polarized (RCP) light illumination, respectively. To increase the PR value, the bipolar linear polarization-sensitive photodetectors have been realized by introducing the Dember effect modulated by the photonic mechanism and hot-carrier mechanism by integrating nanoantenna on graphene. As a result, the PR values can be controlled to have values in the range of (1→∞/−∞→−1) with a transition from positive to negative. However, such a realization only demonstrated the bipolar linear polarization detection, while the polarity transition for circular polarisation detection has not been realized till today. On the other hand, the robust detection of circular polarized light with immunity against the ubiquitous unpolarized and linearly polarized light has not been realized.

Various embodiments may seek to tackle such a challenge. Various embodiments may achieve the bipolar linear and circular polarization detection, simultaneously, for the development of a monolithic full-Stokes polarimeter.

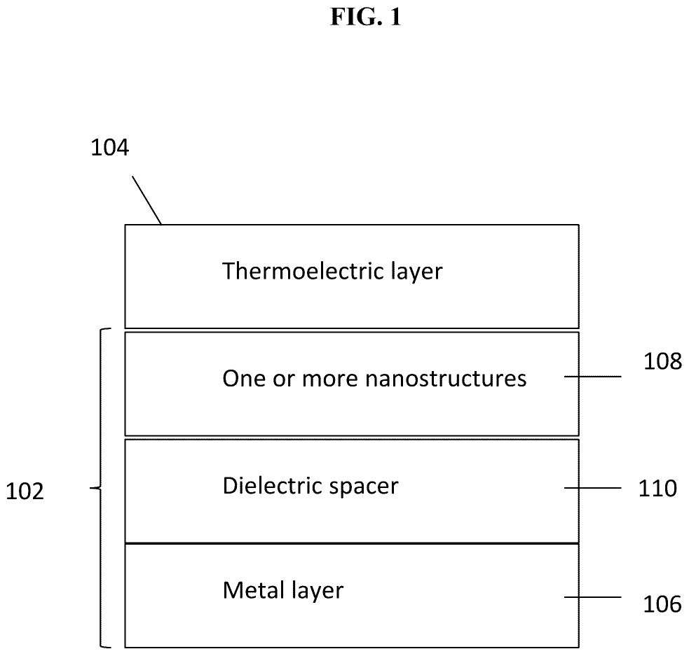

FIG. 1 shows a schematic of a photodetector pixel according to various embodiments. The photodetector pixel may include a chiral plasmonic molecule array 102 configured to generate heat upon incidence of an electromagnetic wave on the chiral plasmonic molecule array. The photodetector pixel may also include a thermoelectric layer 104 configured to generate an electric current or voltage upon transfer of heat from the chiral plasmonic molecule array 102 to the thermoelectric layer 104. The chiral plasmonic molecule array 102 may include a metal layer 106. The chiral plasmonic molecule array may include one or more nanostructures 108. The chiral plasmonic molecule array 102 may also include a dielectric spacer 110 such that the dielectric spacer 110 is between the metal layer 106 and the one or more nanostructures 108. The one or more nanostructures 108 may include one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

In other words, the photodetector pixel may include a thermoelectric layer 104 and a chiral plasmonic molecule array 102. The chiral plasmonic molecule array 102 may include a metal layer 106, one or more nanostructures 108 and a dielectric spacer 110. The one or more nanostructures 108 may be one or more left hand (LH) chiral metamaterial nanostructures, one or more right hand (RH) chiral metamaterial nanostructures, or a combination thereof.

For avoidance of doubt, FIG. 1 seeks to illustrate some features of a photodetector according to various embodiments, and is intended to limit, for instance, the size, shape, arrangement, dimensions, orientation of the various components.

For instance, FIG. 1 show the thermoelectric layer 104 over the chiral plasmonic molecule array 102. However, it may also be envisioned that in some embodiments, the chiral plasmonic molecule array 102 may be over the thermoelectric layer 104. Likewise, while FIG. 1 shows that the one or more nanostructures 108 is over the metal layer 106, it may also be envisioned that in some embodiments, the metal layer 106 may be over the one or more nanostructures 108 (with the dielectric spacer 110 between the metal layer 106 and the one or more nanostructures 108).

In various embodiments, the photodetector pixel may further include a substrate such that the chiral plasmonic molecule array 102 and the thermoelectric layer 104 are over the substrate. The substrate may include any suitable semiconductor material, e.g. silicon, germanium, or gallium arsenide.

In various embodiments, the thermoelectric layer 104 may include any material that exhibits Seebeck effect. The thermoelectric layer 104 may include a two-dimensional (2D) thermoelectric material. For instance, the thermoelectric layer 104 may include graphene, black phosphorous, palladium selenide (PdSe₂), tin selenide (SnSe), tellurium (Te), molybdenum disulphide (MoS₂), or indium selenide (InSe).

In various embodiments, the one or more left hand (LH) chiral metamaterial nanostructures may be “Z” shaped nanostructures (i.e. each nanostructure having a zigzag surface). In various embodiments, the one or more right hand (RH) chiral metamaterial nanostructures may be “Z” shaped nanostructures (i.e. each nanostructure having a zigzag surface). For avoidance of doubt, a “Z” shaped nanostructure may also refer to or include any nanostructure with two arms extending in opposite or different directions and a middle portion joining the two arms such that the nanostructure has a “Z” or mirrored “Z” surface. The two arms may be shifted or offset from each other. The “Z” shaped nanostructures may be orientated in any suitable direction along a plane, which may substantially be parallel to, for instance, a surface of the substrate and/or the dielectric spacer 110. A LH chiral metamaterial nanostructure and a RH chiral metamaterial nanostructure may be mirrored images of each other.

In various embodiments, the one or more nanostructures 108 may include any suitable metal or metals. The metal or metals may, for instance, be gold (Au), chromium (Cr), silver (Ag), copper, aluminium (Al) and/or platinum (Pt). The one or more nanostructures 108 may alternatively be referred to as metamaterials, antennas or nanoantennas, and may form a metamaterial layer.

In various embodiments, the dielectric spacer 110 may include a dielectric material or materials. For instance, the dielectric spacer 110 may include aluminium oxide, silicon oxide, silicon nitride and/or poly(methyl methacrylate) (PMMA).

In various embodiments, the metal layer 106 may include any suitable metal or metals. For instance, the metal layer 106 may include gold (Au), chromium (Cr), silver (Ag), copper, aluminium (Al) and/or platinum (Pt). The metal layer 106 may alternatively be referred to as a backplate.

Various embodiments may relate to a photodetector. The photodetector may include a first photodetector pixel, which may be a photodetector pixel as described herein. The one or more nanostructures of the first photodetector may include or consist of one or more left hand (LH) chiral metamaterial nanostructures and one or more right hand (RH) chiral metamaterial nanostructures. The photodetector may also include a second photodetector pixel, which may be a photodetector pixel as described herein. The second photodetector pixel may be oriented substantially 90° to the first photodetector pixel. The one or more nanostructures of the second photodetector pixel may include or consist of one or more left hand (LH) chiral metamaterial nanostructures and one or more right hand (RH) chiral metamaterial nanostructures. The photodetector may further include a third photodetector pixel, which may be a photodetector pixel as described herein. The third photodetector pixel may be oriented substantially 45° to the first photodetector pixel. The one or more nanostructures of the third photodetector pixel may include or consist of one or more left hand (LH) chiral metamaterial nanostructures. The photodetector may also include a fourth photodetector pixel, which may be a photodetector pixel as described herein. The fourth photodetector pixel may be oriented substantially 45° to the first photodetector pixel. The one or more nanostructures of the fourth photodetector pixel may include or consist of one or more right hand (RH) chiral metamaterial nanostructures. The third photodetector pixel or the fourth photodetector pixel may be configured to determine an ellipticity angle of a state of polarization of the electromagnetic wave. The third photodetector pixel or the fourth photodetector pixel that is not used or configured to determine the ellipticity angle may be grounded. The first photodetector pixel and the second photodetector pixel may be configured to determine an azimuthal angle of the state of polarization of the electromagnetic waves.

In other words, various embodiments may relate to a photodetector having four photodetector pixels. The first photodetector pixel and the second photodetector pixel, each having both LH chiral metamaterial nanostructures and RH chiral metamaterial nanostructures may be used to determine an azimuthal angle of the state of polarization of the incoming electromagnetic waves. The third photodetector pixel may include only LH chiral metamaterial nanostructure, while the fourth photodetector pixel may include only RH chiral metamaterial nanostructure. Either the third photodetector pixel or the fourth photodetector pixel may be used to determine the ellipticity angle, while the remaining photodetector pixel may be grounded.

In the current context, a first component oriented substantially at an angle to a second component may refer to an instance in which the first component is oriented at the angle to the second component as well as instances in which the first component is oriented within a range of ±2° of the angle to the second component. For instance, the second photodetector pixel oriented substantially 90° to the first photodetector pixel may refer to the second photodetector pixel oriented at any angle selected from a range of 88° to 92° to the first photodetector pixel. Likewise, the third photodetector pixel (or fourth photodetector pixel) may be oriented substantially 45° to the first photodetector pixel may refer to the third photodetector pixel (or fourth photodetector pixel) oriented at any angle selected from a range of 43° to 47° to the first photodetector pixel.

In various embodiments, the second photodetector pixel oriented substantially 90° to the first photodetector pixel may refer to the one or more nanostructures of the second photodetector pixel having an equivalent orientation substantially 90° to an equivalent orientation of the one or more nanostructures of the first photodetector pixel. Likewise, the third photodetector pixel oriented substantially 45° to the first photodetector pixel may refer to the one or more nanostructures of the third photodetector pixel having an equivalent orientation substantially 45° to an equivalent orientation of the one or more nanostructures of the first photodetector pixel, and the fourth photodetector pixel oriented substantially 45° to the first photodetector pixel may refer to the one or more nanostructures of the fourth photodetector pixel having an equivalent orientation substantially 45° to an equivalent orientation of the one or more nanostructures of the first photodetector pixel. In the current context, the equivalent orientation may refer to a sum of all the respective orientations of the one of more nanostructures of a particular photodetector. In a photodetector pixel (e.g. the first photodetector pixel or the second photodetector pixel) having one or more left hand (LH) chiral metamaterial nanostructures and one or more right hand (RH) chiral metamaterial nanostructures, the one or more (LH) chiral metamaterial nanostructures may be oriented in a direction different from an orientation direction of the one or more right hand (RH) chiral metamaterial nanostructures.

For instance, the one or more left hand (LH) chiral metamaterial nanostructures of the first photodetector pixel may have an angle of substantially 20° relative to the one or more right hand (RH) chiral metamaterial nanostructures of the first photodetector pixel. The one or more left hand (LH) chiral metamaterial nanostructures of the second photodetector pixel may have an angle of substantially 20° relative to the one or more right hand (RH) chiral metamaterial nanostructures of the second photodetector pixel. In other words, the one or more left hand (LH) chiral metamaterial nanostructures of the first photodetector pixel may have an angle selected from a range from 18° to 22°, e.g. 20° relative to the one or more right hand (RH) chiral metamaterial nanostructures of the first photodetector pixel. The one or more left hand (LH) chiral metamaterial nanostructures of the second photodetector pixel may have an angle selected from a range from 18° to 22°, e.g. 20° relative to the one or more right hand (RH) chiral metamaterial nanostructures of the second photodetector pixel.

The equivalent orientation of a particular photodetector pixel may be based on the orientation directions of the one or more left hand (LH) chiral metamaterial nanostructures and the orientation directions of the one or more right hand (RH) chiral metamaterial nanostructures of the particular photodetector pixel.

In various embodiments, all of the left hand (LH) chiral metamaterial nanostructures of a particular photodetector pixel may be oriented in the same direction, i.e. aligned in parallel to one another. In various embodiments, all of the RH hand (RH) chiral metamaterial nanostructures of a particular photodetector pixel may be oriented in the same direction, i.e. aligned in parallel to one another.

In various embodiments, a number of the one or more left hand (LH) chiral metamaterial nanostructures included in the first photodetector pixel may be equal to a number of the one or more right hand (RH) chiral metamaterial nanostructures included in the first photodetector pixel. In various embodiments, a number of the one or more left hand (LH) chiral metamaterial nanostructures included in the second photodetector pixel may be equal to a number of the one or more right hand (RH) chiral metamaterial nanostructures included in the second photodetector pixel.

In various embodiments, the one or more left hand (LH) chiral metamaterial nanostructures of the first photodetector pixel may be arranged or grouped in one region of the first photodetector pixel, while the one or more right hand (RH) chiral metamaterial nanostructures of the first photodetector pixel may be arranged or grouped in another region of the first photodetector pixel. The one or more left hand (LH) chiral metamaterial nanostructures of the first photodetector pixel may form a first triangular-shaped region in the first photodetector pixel, while the one or more right hand (RH) chiral metamaterial nanostructures of the first photodetector pixel may form a second triangular-shaped region in the first photodetector pixel.

Likewise, the one or more left hand (LH) chiral metamaterial nanostructures of the second photodetector pixel may be arranged or grouped in one region of the second photodetector pixel, while the one or more right hand (RH) chiral metamaterial nanostructures of the second photodetector pixel may be arranged or grouped in another region of the second photodetector pixel. The one or more left hand (LH) chiral metamaterial nanostructures of the second photodetector pixel may form a first triangular-shaped region in the second photodetector pixel, while the one or more right hand (RH) chiral metamaterial nanostructures of the second photodetector pixel may form a second triangular-shaped region in the second photodetector pixel.

In various embodiments, the one or more left hand (LH) chiral metamaterial nanostructures of the third photodetector pixel may form a square or rectangular region in the third photodetector pixel. In various embodiments, the one or more right hand (RH) chiral metamaterial nanostructures of the fourth photodetector pixel may form a square or rectangular region in the fourth photodetector pixel.

In various embodiments, the first photodetector pixel may be connected to Port 1. The second photodetector pixel may be connected to Port 2. The third photodetector pixel may be connected to Port 3. The fourth photodetector pixel may be connected to Port 4. Either Port 3 or Port 4 may be a ground port (i.e. grounded).

In various embodiments, the first photodetector pixel and the second photodetector pixel may be diagonal to each other, while the third photodetector pixel and the fourth photodetector pixel may be diagonal to each other.

In various embodiments, the ellipticity angle may also be determined by the first photodetector pixel and the second photodetector pixel (in combination with the third photodetector pixel or the fourth photodetector).

In various embodiments, the azimuthal angle of the state of polarization of the electromagnetic wave may be used to determine an angle of linear polarization (AoLP). In various embodiments, the ellipticity angle of the state of polarization of the electromagnetic wave may be used to determine a degree of linear polarization (DoLP) and/or a degree of circular polarization (DoCP).

In various embodiments, the photodetector may be coupled or may include a processor for determination or calculation of the AoLP, the DoLP and/or the DoCP.

In various embodiments, the electromagnetic wave may be or may be part of a polarized light.

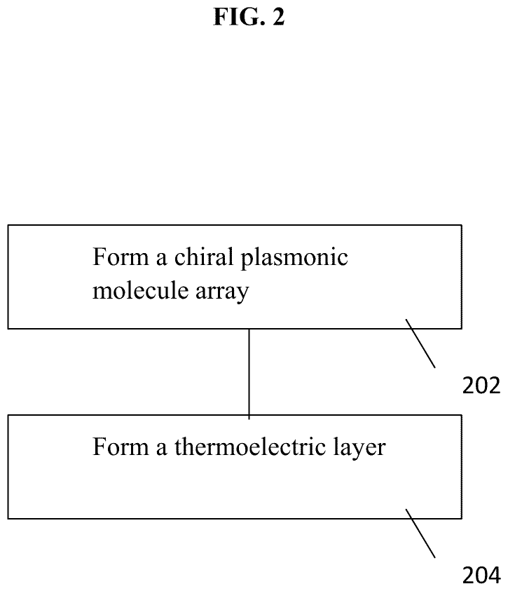

FIG. 2 shows a schematic of a method of forming a photodetector pixel according to various embodiments. The method may include, in 202, forming a chiral plasmonic molecule array configured to generate heat upon incidence of an electromagnetic wave on the chiral plasmonic molecule array. The method may also include, in 204, forming a thermoelectric layer configured to generate an electric current or voltage upon transfer of heat from the chiral plasmonic molecule array to the thermoelectric layer. The chiral plasmonic molecule array may include a metal layer. The chiral plasmonic molecule array may include one or more nanostructures. The chiral plasmonic molecule array may include a dielectric spacer such that the dielectric spacer is between the metal layer and the one or more nanostructures. The one or more nanostructures may include one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

In other words, the method may include forming a thermoelectric layer and a chiral plasmonic molecule array, which may include a metal layer, one or more nanostructures, and a dielectric spacer between the metal layer and the one or more nanostructures.

For avoidance of doubt, FIG. 2 is not intended to limit the sequence of steps. Step 202 may occur before, after, or at the same time as step 204.

In various embodiments, the chiral plasmonic molecule array may be formed before the thermoelectric layer. In various other embodiments, the thermoelectric layer may be formed before the chiral plasmonic molecule array.

In various embodiments, forming the chiral plasmonic molecule array may include forming the metal layer over a substrate. In various embodiments, forming the chiral plasmonic molecule array may further include forming the dielectric spacer over the metal layer. In various embodiments, forming the chiral plasmonic molecule array may also include forming the one or more nanostructures over the dielectric spacer.

In various embodiments, the metal layer may be formed using electron beam (e-beam) evaporation or thermal evaporation. The dielectric spacer may also be formed using electron beam (e-beam) evaporation or thermal evaporation. The one or more nanostructures may be formed using a lithography process. In the lithography process, a suitable resist may be deposited over the dielectric spacer. A suitable mask may be provided over the suitable resist, and lithography (e.g. electron beam (e-beam) lithography) may be carried out. Portions of the deposited resist may then be removed. For instance, portions of the deposited resist that is exposed through the mask may be removed. A suitable metal (e.g. gold (Au) and chromium (Cr)) may be deposited using blanket deposition. The remaining portions of the deposited resist may then be removed together with overlying portions of the deposited metal, with the remaining portions of the deposited metal forming the one or more nanostructures.

In various embodiments, the thermoelectric layer may be formed over the chiral plasmonic molecule array. In various embodiments, the thermoelectric layer may be formed over the chiral plasmonic molecule array via a dry-transfer method.

In various embodiments, the thermoelectric layer may include any material that exhibits Seebeck effect. The thermoelectric layer may include a two-dimensional (2D) thermoelectric material. The thermoelectric layer may, for instance, include graphene, black phosphorous, or palladium selenide (PdSe₂).

In various embodiments, the one or more left hand (LH) chiral metamaterial nanostructures may be “Z” shaped nanostructures. The one or more right hand (RH) chiral metamaterial nanostructures may be “Z” shaped nanostructures.

In various embodiments, the one or more nanostructures may include any suitable metal or metals. The metal or metals may, for instance, be gold (Au), chromium (Cr), silver (Ag) and/or platinum (Pt).

In various embodiments, the dielectric spacer may include a dielectric material or materials. For instance, the dielectric spacer may include aluminium oxide, silicon oxide, silicon nitride and/or poly(methyl methacrylate) (PMMA).

In various embodiments, the metal layer may include any suitable metal or metals. For instance, the metal layer may include gold (Au), chromium (Cr), silver (Ag) and/or platinum (Pt).

Various embodiments may relate to a method of forming a photodetector. The method may include forming a first photodetector pixel, which may be a photodetector pixel as described herein. The one or more nanostructures of the first photodetector may include or consist of one or more left hand (LH) chiral metamaterial nanostructures and one or more right hand (RH) chiral metamaterial nanostructures. The method may also include forming a second photodetector pixel, which may be a photodetector pixel as described herein. The second photodetector pixel may be oriented substantially 90° to the first photodetector pixel. The one or more nanostructures of the second photodetector pixel may include or consist of one or more left hand (LH) chiral metamaterial nanostructures and one or more right hand (RH) chiral metamaterial nanostructures. The method may further include forming a third photodetector pixel, which may be a photodetector pixel as described herein. The third photodetector pixel may be oriented substantially 45° to the first photodetector pixel. The one or more nanostructures of the third photodetector pixel may include or consist of one or more left hand (LH) chiral metamaterial nanostructures. The method may also include forming a fourth photodetector pixel, which may be a photodetector pixel as described herein. The fourth photodetector pixel may be oriented substantially 45° to the first photodetector pixel. The one or more nanostructures of the fourth photodetector pixel may include or consist of one or more right hand (RH) chiral metamaterial nanostructures. The third photodetector pixel or the fourth photodetector pixel may be configured to determine an ellipticity angle of a state of polarization of the electromagnetic wave. The third photodetector pixel or the fourth photodetector pixel that is not used or configured to determine the ellipticity angle may be grounded. The first photodetector pixel and the second photodetector pixel may be configured to determine an azimuthal angle of the state of polarization of the electromagnetic waves.

In various embodiments, the ellipticity angle may also be determined by the first photodetector pixel and the second photodetector pixel.

In various embodiments, the one or more left hand (LH) chiral metamaterial nanostructures of the first photodetector pixel may have an angle of substantially 20° relative to the one or more right hand (RH) chiral metamaterial nanostructures of the first photodetector pixel. The one or more left hand (LH) chiral metamaterial nanostructures of the second photodetector pixel may have an angle of substantially 20° relative to the one or more right hand (RH) chiral metamaterial nanostructures of the second photodetector pixel.

Various embodiments may relate to a room temperature and mid-infrared (IR) photothermoelectric (PTE) polarization-sensitive photodetector that leverage on the SoP-dependent photothermal effect in plasmonic chiral metamaterials and Seebeck effect in two-dimensional (2D) thermoelectric materials for both linear and circular polarization detections. The design principle not only provides a powerful platform to transfer the polarization-sensitive optical response to an electrical signal readout, but also can be readily applied to other wavelength regions, such as the visible, the near-infrared, and the terahertz, because the response according to various embodiments may not be limited by the bandgap of active semiconductors. The chiral plasmonic metamaterials designed for SoP-dependent absorption may create localized temperature gradients through photothermal effect under uniform illumination, which in turn generates a polarization-resolved photovoltage response in 2D thermoelectric materials. In addition, the polarity transition for both linear and circular polarization detections can be realized by spatial and geometric configurations of chiral metamaterials within the device channel. Furthermore, as a proof-of-concept demonstration of superiority of the balanced photodetectors (PR=−1, g=∞), a properly designed device with three-ports for full-Stokes detection is demonstrated, and a polarization imaging demonstration is presented with the developed device. The results show a filterless, uncooled, bandgap-independent photodetection mechanism based on the combination of nanophotonic structures and thermoelectric materials on an integrated chip. Various embodiments may offer a promising platform for optoelectronic applications and opens possibilities for the next-generation mid-infrared photodetection, polarimetry, and imaging technologies.

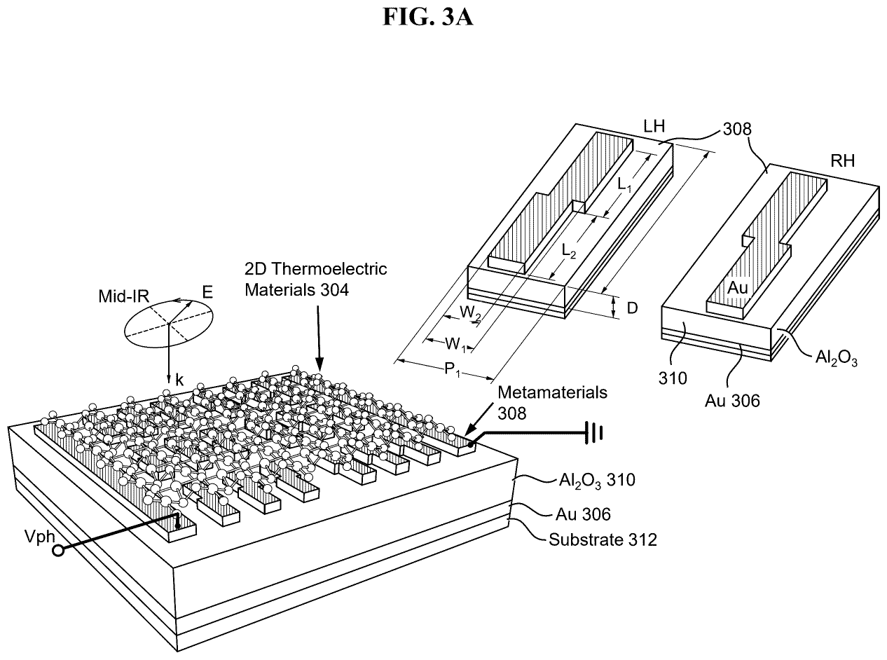

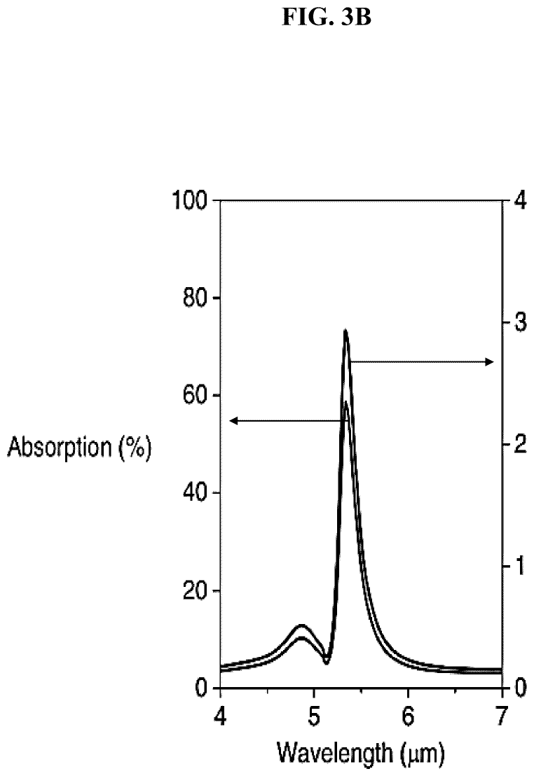

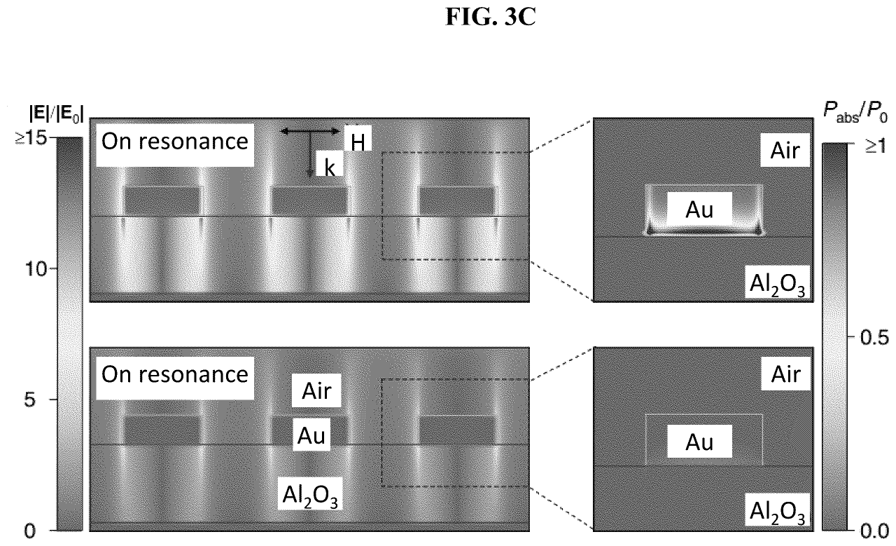

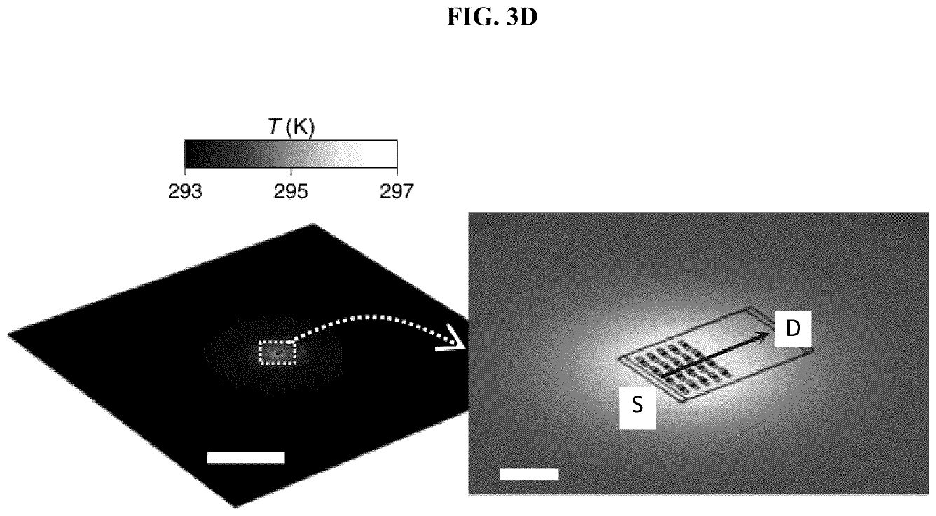

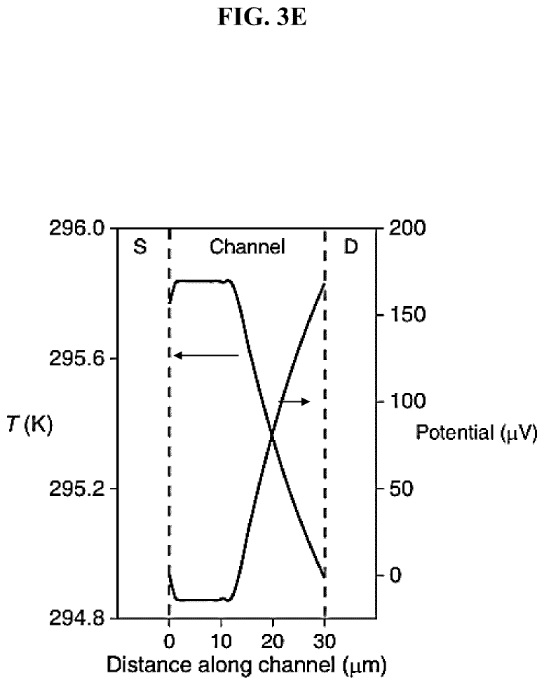

FIG. 3A shows (left) a schematic of a photodetector pixel for resonance thermoelectric photoresponse according to various embodiments; and (right) a chiral plasmonic molecule array including a metal layer 306, a dielectric spacer 310 and metamaterial layer 308 according to various embodiments. In the left panel of FIG. 3A, k, E, and Vₚₕ represent wavevector, electric field vector, and photovoltage, respectively. In the right panel of FIG. 3A, W_{1,2}, L_{1,2}, P_{1,2}, and D indicate the width, length, periodic scale, and thickness of the dielectric spacer 310, respectively.

The photodetector (alternatively referred to as mid-infrared (IR) PTE detector) may include thermoelectric layer 304 of a two-dimensional thermoelectric material, two electrodes (not shown in FIG. 3A), and a chiral plasmonic molecule array including the metal layer 306 (e.g. Au backplate), the dielectric spacer 310 (e.g. aluminium oxide or Al₂O₃) and chiral plasmonic metamaterial layer 308 which includes a periodic array of chiral plasmonic meta-atoms, i.e. nanostructures. As shown in FIG. 3A, the metal layer 306 may be on a substrate 312, the dielectric spacer 310 may be on the metal layer, and the chiral plasmonic metamaterial layer 308 may be on the dielectric spacer 310. The thermoelectric layer 304 may be over the chiral plasmonic metamaterial layer 308. The right panel of FIG. 3A shows the unit cells of left-handed (LH) and right-handed (RH) nanostructures for LCP light absorber and RCP absorber, respectively. The LH nanostructure (i.e. LH chiral metamaterial nanostructure) and the RH nanostructure (i.e. RH chiral metamaterial nanostructure) may be mirrored or chiral images of each other. For a typical metamaterial layer under normal incident radiation with a transverse magnetic polarization, the simulated absorption spectrum shows a wavelength peak at around 5.3 μm as shown in FIG. 3B. FIG. 3B is a plot of absorption (in percent or %)/temperature change or ΔT (in Kelvins or K) as a function of wavelength (in micrometres or m) showing the simulated absorption and temperature increase with varying wavelengths of incident light having input power of 5 mW according to various embodiments. FIG. 3C shows full wave simulations of normalized electric field distribution (left) and normalized power absorption distribution (right) of cross-sections of the photodetector pixel according to various embodiments. The normalized power absorption distribution may be calculated by P_{abs}=½ωε″|E|² and normalized by P₀. The on- and off-resonance modes correspond to the maximum and the minimum absorptions at wavelengths of 5.3 μm and 5.1 μm, respectively. As compared with the off-resonance mode, the on-resonance mode induces larger electric fields in the Au nanostructures 308 (also referred to as antennas), giving rise to a higher absorption of light. On the other hand, the main absorption of light occurs at the Au antennas 308. When the metamaterials are illuminated by a mid-IR light beam with a diameter of 100 μm and a power of 5 mW, the photothermal effect increases the temperature of the Au antennas 308. FIG. 3B also plots the increased temperature ΔT as a function of wavelength. The maximum ΔT located at resonance wavelength can reach up to 3K. More importantly, the absorption spectrum shows a similar response (i.e. the two curves in FIG. 3B nearly overlap), indicating a linear relation between the absorption and ΔT. Such a linear relation may be crucial for transferring polarization-dependent optical absorption to polarization-resolved electrical signal outputs.

A device with left half-channel covered by the nanostructures may be considered as one example to illustrate PTE response. The channel may include a thermoelectric layer with a 2D thermoelectric material with a Seebeck coefficient (S) of −200 μV K⁻¹ and a thermal conduction of 4.5 W m⁻¹ K⁻¹. A temperature source designed according to the results of photothermal simulations is used as the input. The temperature distribution in the device is simulated with consideration of the heat conductance, radiation, and convection. An example illustrating the temperature distribution in the device is shown in FIG. 3D. FIG. 3D shows a thermal simulation of a device with left half-channel covered by the nanostructures at peak absorption with input power of 5 mW according to various embodiments. “S” and “D” denote the source electrode and drain electrode respectively. The scale bar on the left indicates 400 μm, while the scale bar on the right indicates 10 μm. Similarly, when the device with a channel length of 30 μm is illuminated by a mid-IR light beam with a diameter of 100 μm and a power of 5 mW, the left half-channel covered by nanostructures exhibits a higher temperature than the right half-channel without nanostructures. As a result, a temperature gradient is built up within the device channel (i.e. between the drain electrode and the source electrode) as shown in FIG. 3E. FIG. 3E shows a plot of temperature (in Kelvins or K)/potential (in microVolts or μV) as a distance along the channel (in micrometres or m) illustrating the corresponding temperature and potential profiles across the device channel of the device shown in FIG. 3D according to various embodiments. The two vertical dashed lines indicate the interfaces between electrodes and channel. Such a temperature gradient can generate a potential difference between the source (S) and the drain (D) electrodes, giving rise to a photovoltage response (Vₚₕ) of 170 μV shown in FIG. 3E, which can be calculated by Vₚₕ=−SΔT, where S is the Seebeck coefficient.

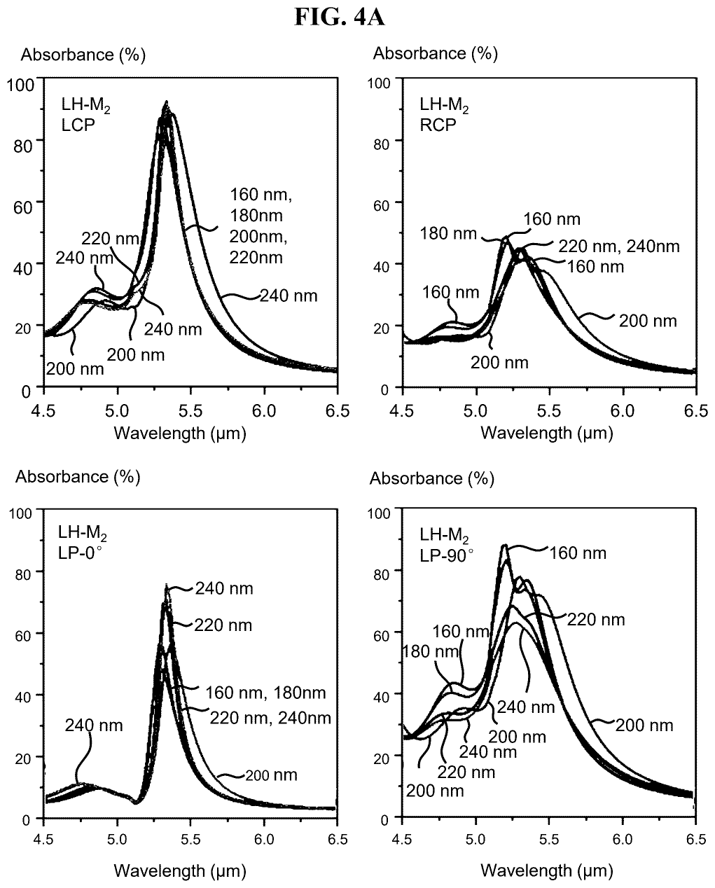

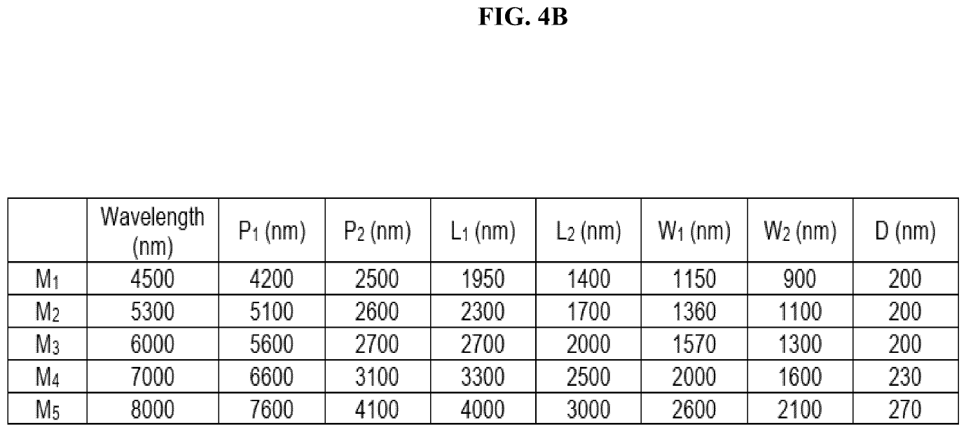

In order to investigate the photothermal response of the chiral plasmonic metamaterials, full-wave electromagnetic simulations were performed on the Z-shaped Au antenna array. First, structural parameters as indicated in FIG. 3A are obtained using global optimization. The optical absorption of chiral metamaterials can be tuned across a broadband mid-IR regime (4-8 μm) as shown in FIGS. 4A-B.

FIG. 4A shows plots of absorbance (in percent or %) as a function of wavelengths (in micrometres or m) illustrating the effect of the thickness of the dielectric spacer (aluminium oxide or Al₂O₃) on the optical absorption of different polarized light (a)-(d) by the metamaterials according to various embodiments. FIG. 4B shows a table of structure parameters of metamaterials (M₁ to M₅) with different absorption wavelength peaks according to various embodiments. Owing to the sandwich construction of metamaterials, a Fabry-Perot-like cavity is formed between the Z-shaped antennas and the ground plane, leading to a multiple reflection under a wide-field illumination. On the other hand, because the planar metamaterials are anisotropic and lossy, linear polarization conversion is introduced and results in destructive or constructive interference for the incident light with different SoP. The simulated absorptions for different metamaterials show not only a linear polarization dependency, but also a circular polarization dependency with a circular dichroism (CD) of 50% in a broadband mid-IR regime.

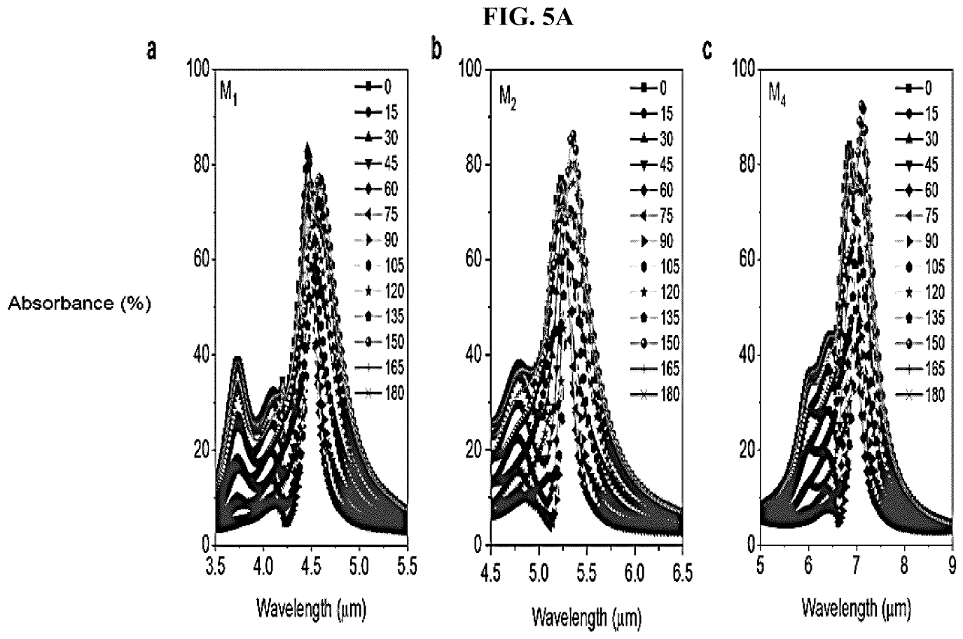

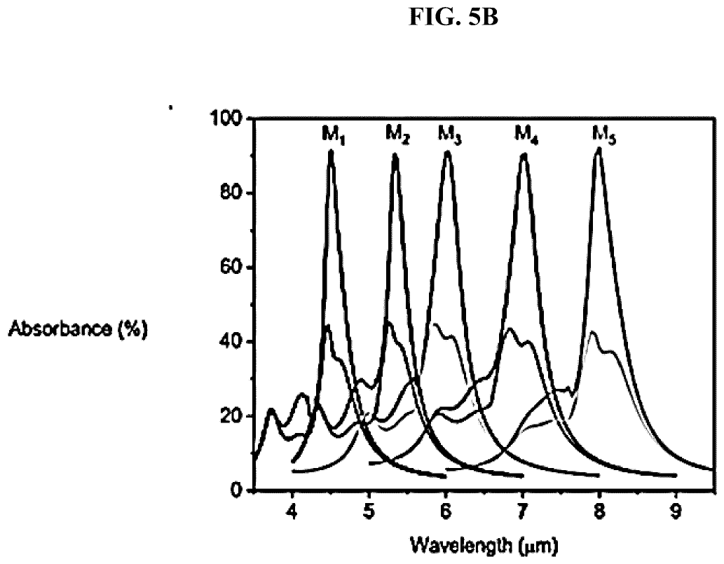

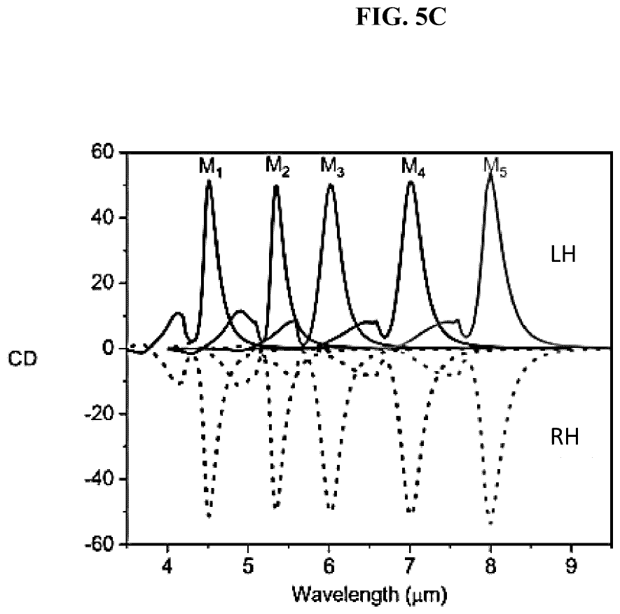

FIG. 5A shows plots of absorbance (in percent or %) as a function of wavelength (in micrometres or m) illustrating the simulated linear polarization dependent optical absorption of metal materials (a) M₁, (b) M₂ and (c) M₄ according to various embodiments. FIG. 5B shows a plot of absorbance (in percent or %) as a function of wavelength (in micrometres or m) showing the simulated optical absorption under left-handed circular polarized (LCP) and right-handed circular polarized (RCP) light illumination for left hand (LH) metamaterials with different dimensions (M₁ to M₅) according to various embodiments. FIG. 5C shows a plot of circular dichroism (CD) (in percent or %) as a function of wavelength (in micrometres or m) illustrating the corresponding CD for both left hand (LH) metamaterials and right hand (RH) metamaterials according to various embodiments.

Furthermore, the simulated polarization-dependent optical absorption of the as-designed metamaterials are experimentally verified. Here, three typical metamaterials (M₁, M₂, and M₄) are fabricated and their polarization-dependent absorptions are measured.

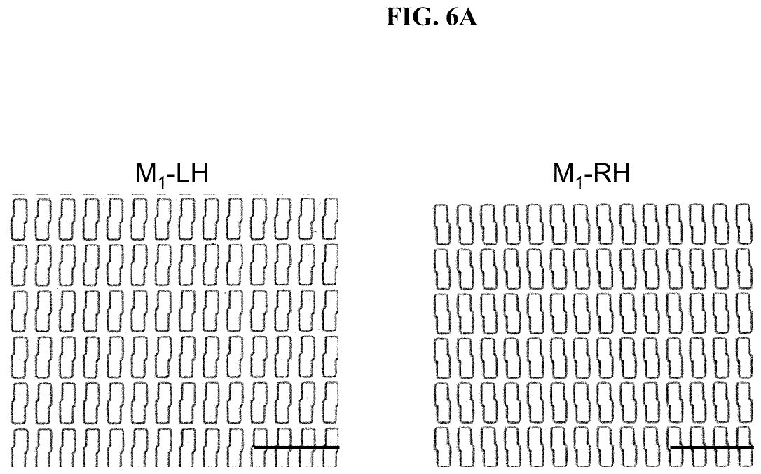

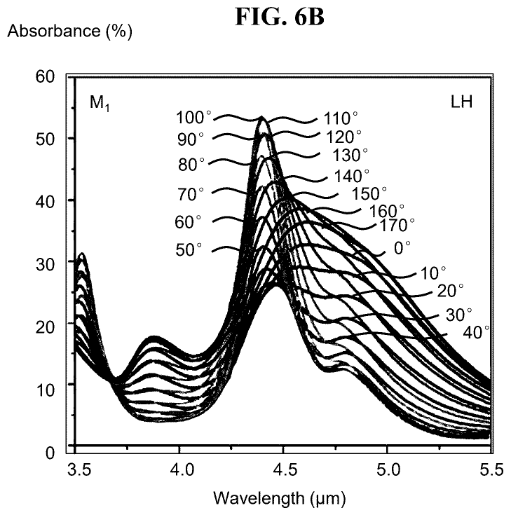

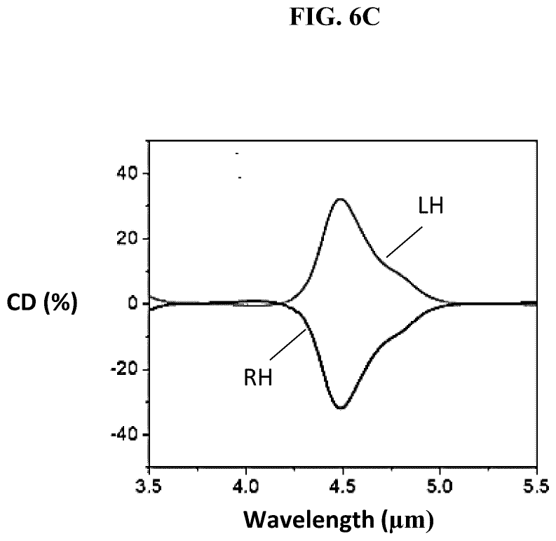

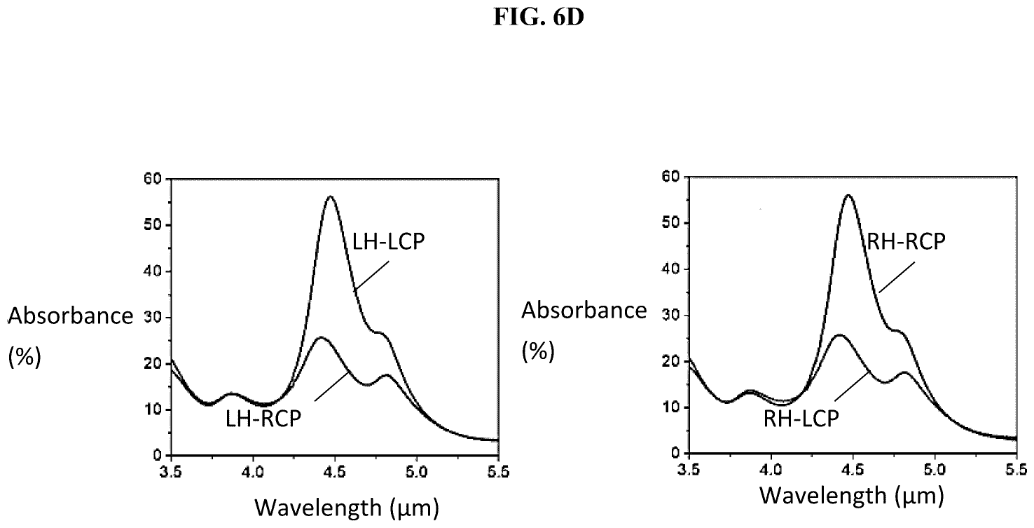

FIG. 6A shows (left) an image of left-hand (LH) metamaterials M₁ according to various embodiments; and (right) an image of right-hand (RH) metamaterials M₁ according to various embodiments. The scale bar shown represents 10 km. FIG. 6B shows a plot of absorbance (in percent or %) as a function of wavelength (in micrometres or km) illustrating measured linear polarization dependent optical absorption for left-hand (LH) metamaterials M₁ according to various embodiments. FIG. 6C shows a plot of circular dichroism (CD) (in percent or %) as a function of wavelength (in micrometres or km) illustrating the variation of CD with wavelength for both left-hand (LH) metamaterials M₁ according to various embodiments and right-hand (RH) metamaterials M₁ according to various embodiments. FIG. 6D shows plots of absorbance (in percent or %) as a function of wavelength (in micrometres or km) illustrating the measured optical absorption under left-handed circular polarized (LCP) and right-handed circular polarized (RCP) light illumination for (left) left-hand (LH) metamaterials M₁ according to various embodiments and (right) right-hand (RH) metamaterials M₁ according to various embodiments.

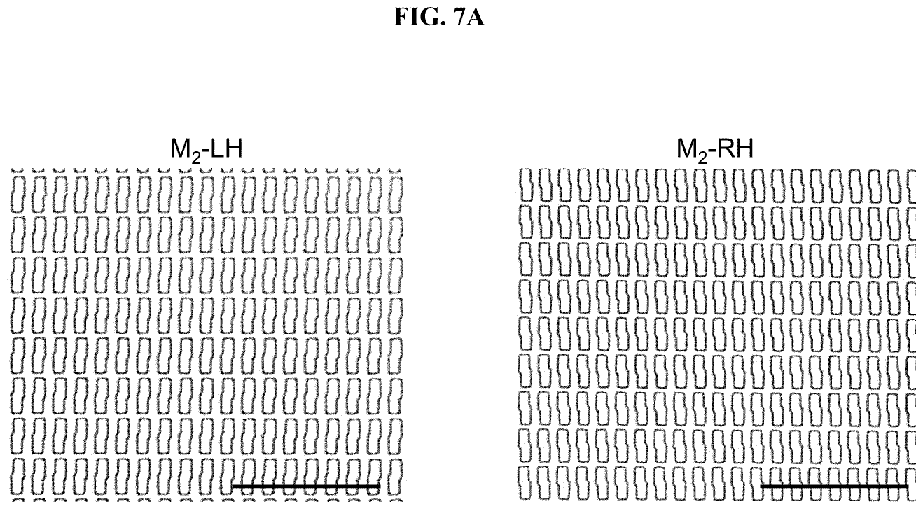

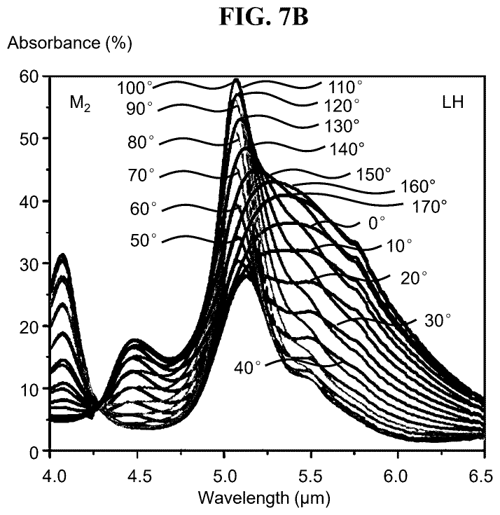

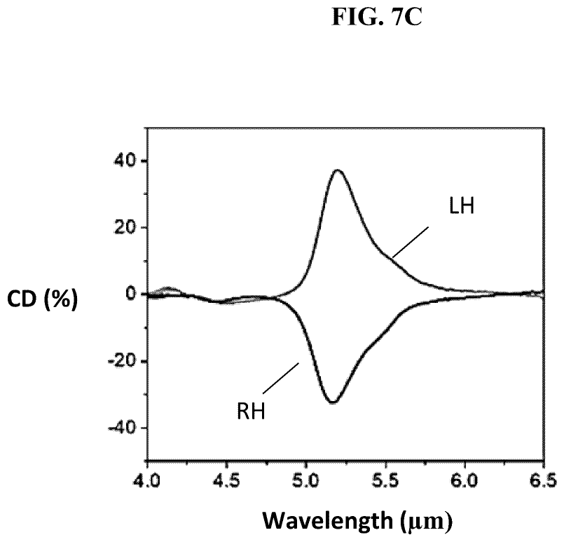

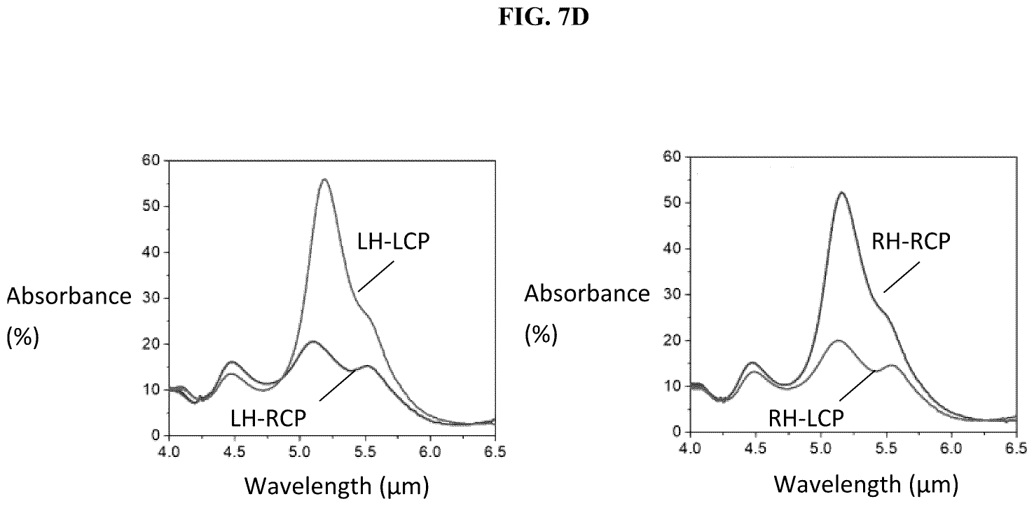

FIG. 7A shows (left) an image of left-hand (LH) metamaterials M₂ according to various embodiments; and (right) an image of right-hand (RH) metamaterials M₂ according to various embodiments. The scale bar shown represents 20 km. FIG. 7B shows a plot of absorbance (in percent or %) as a function of wavelength (in micrometres or km) illustrating measured linear polarization dependent optical absorption for left-hand (LH) metamaterials M₂ according to various embodiments. FIG. 7C shows a plot of circular dichroism (CD) (in percent or %) as a function of wavelength (in micrometres or m) illustrating the variation of CD with wavelength for both left-hand (LH) metamaterials M₂ according to various embodiments and right-hand (RH) metamaterials M₂ according to various embodiments. FIG. 7D shows plots of absorbance (in percent or %) as a function of wavelength (in micrometres or m) illustrating the measured optical absorption under left-handed circular polarized (LCP) and right-handed circular polarized (RCP) light illumination for (left) left-hand (LH) metamaterials M₂ according to various embodiments and (right) right-hand (RH) metamaterials M₂ according to various embodiments.

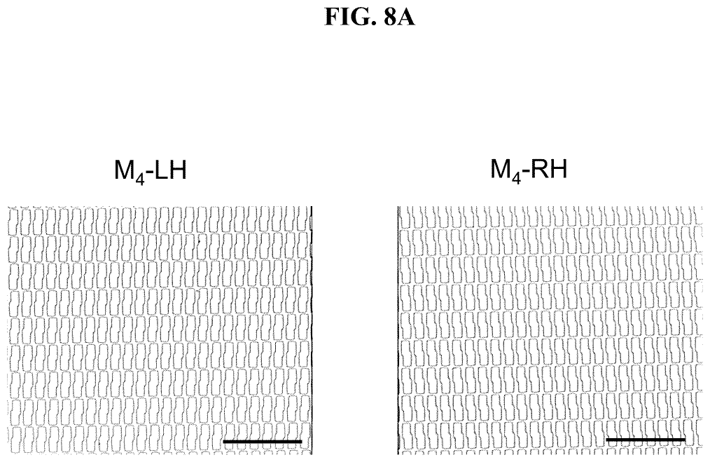

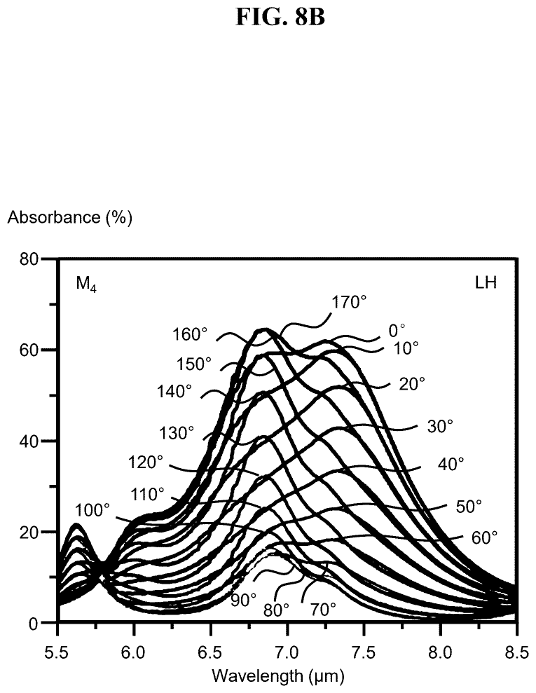

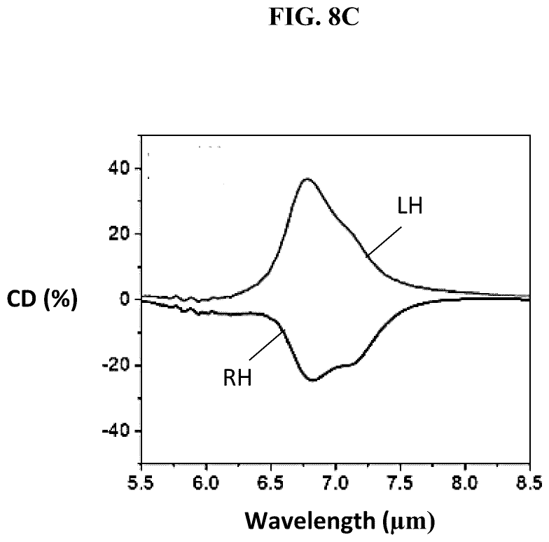

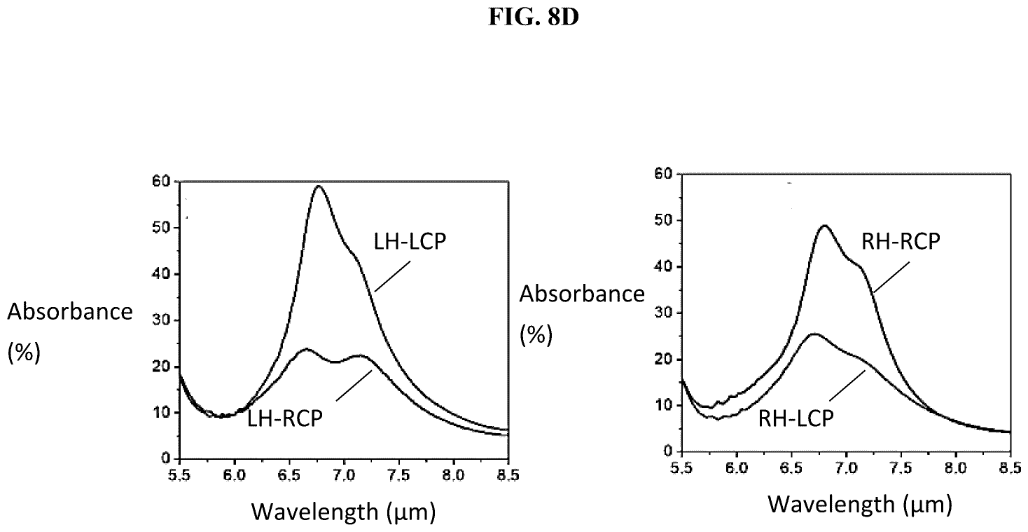

FIG. 8A shows (left) an image of left-hand (LH) metamaterials M₄ according to various embodiments; and (right) an image of right-hand (RH) metamaterials M₄ according to various embodiments. The scale bar shown represents 20 μm. FIG. 8B shows a plot of absorbance (in percent or %) as a function of wavelength (in micrometres or m) illustrating measured linear polarization dependent optical absorption for left-hand (LH) metamaterials M₄ according to various embodiments. FIG. 8C shows a plot of circular dichroism (CD) (in percent or %) as a function of wavelength (in micrometres or m) illustrating the variation of CD with wavelength for both left-hand (LH) metamaterials M₄ according to various embodiments and right-hand (RH) metamaterials M₄ according to various embodiments. FIG. 8D shows plots of absorbance (in percent or %) as a function of wavelength (in micrometres or m) illustrating the measured optical absorption under left-handed circular polarized (LCP) and right-handed circular polarized (RCP) light illumination for (left) left-hand (LH) metamaterials M₄ according to various embodiments and (right) right-hand (RH) metamaterials M₄ according to various embodiments.

The experimentally measured optical absorption spectra of both the LH and RH metamaterials show the same polarization dependence as the simulation results. For the LH metamaterial, the absorption at the resonance wavelength is a cosine function of the linear polarization angle, which fits well with simulation results. In addition, the absorptions are significantly different under the LCP and RCP light illuminations, resulting in a large CD of about 30%. Such a value may be high enough to distinguish the LCP and RCP light in practical devices.

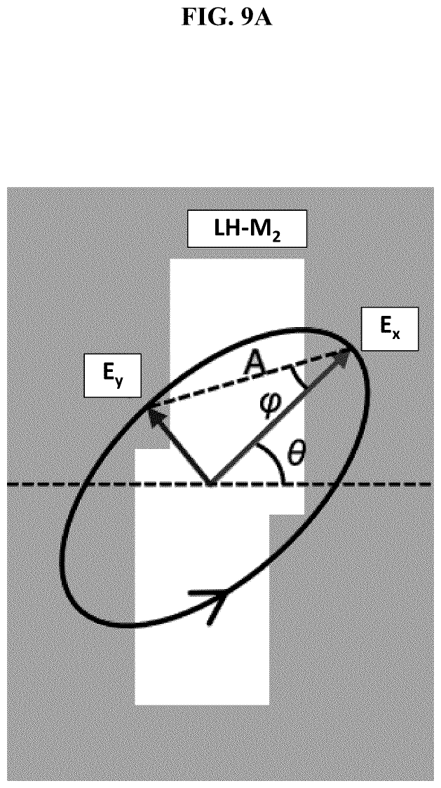

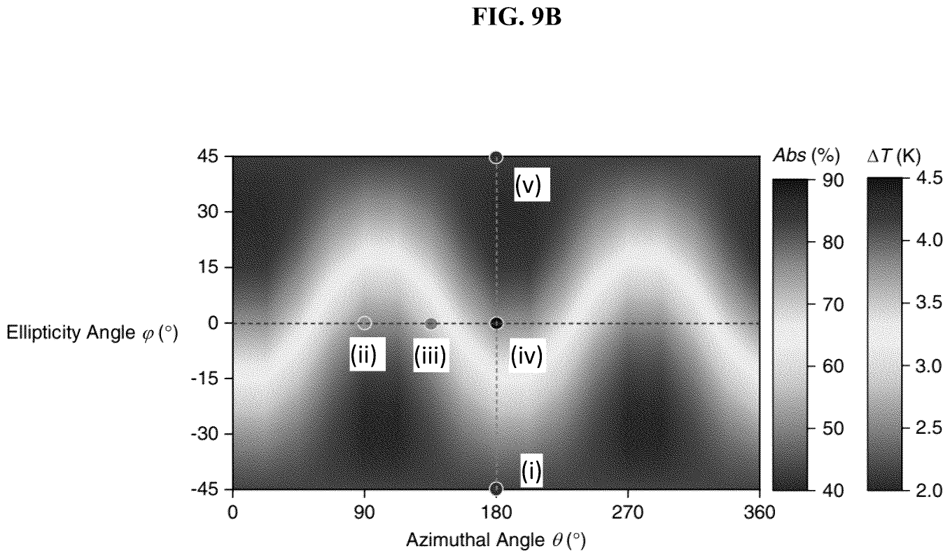

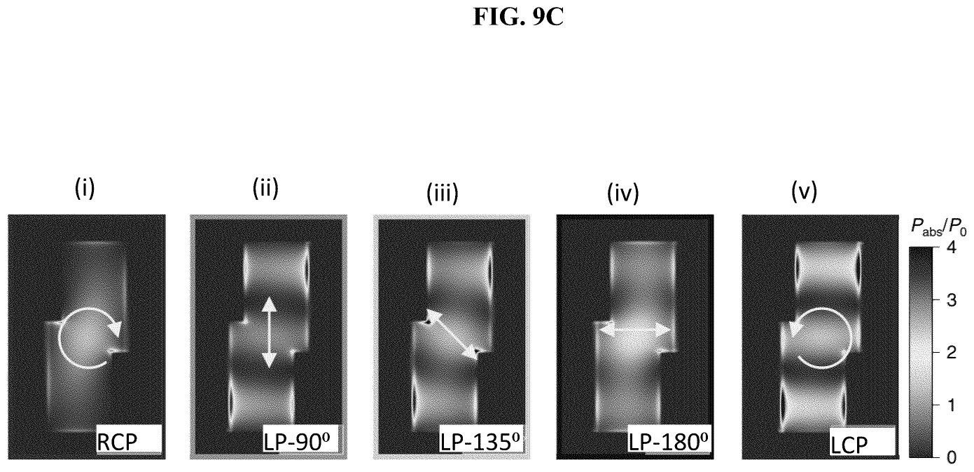

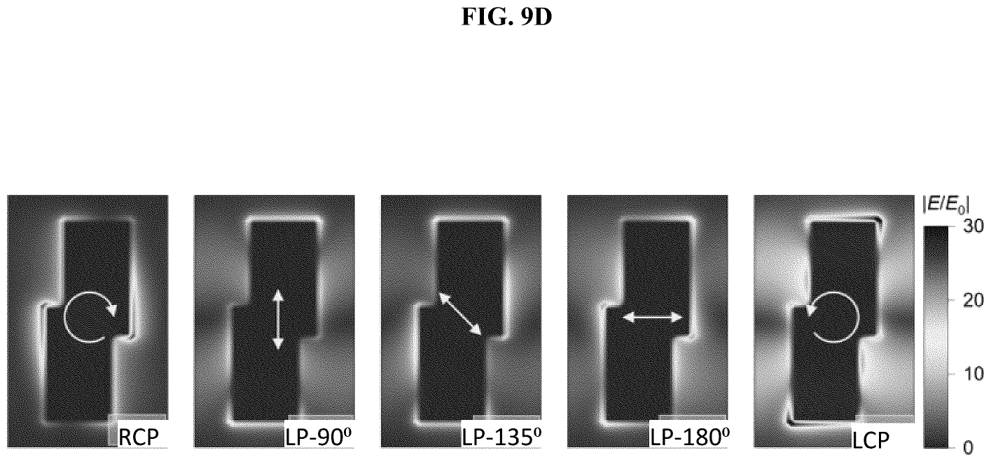

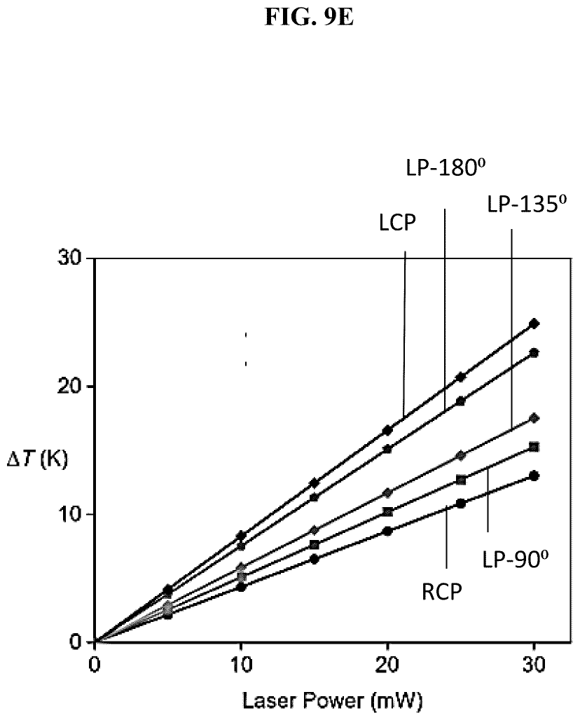

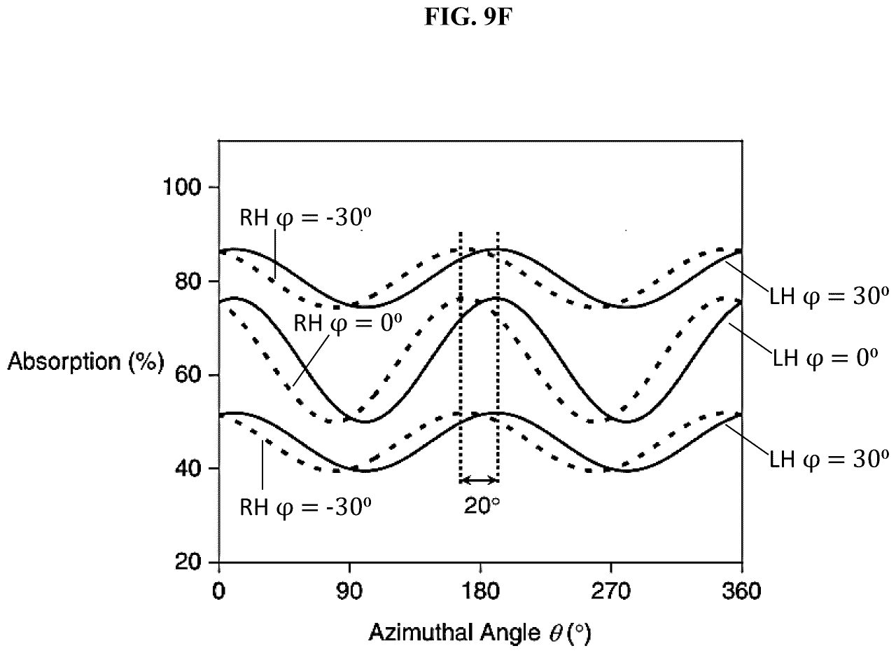

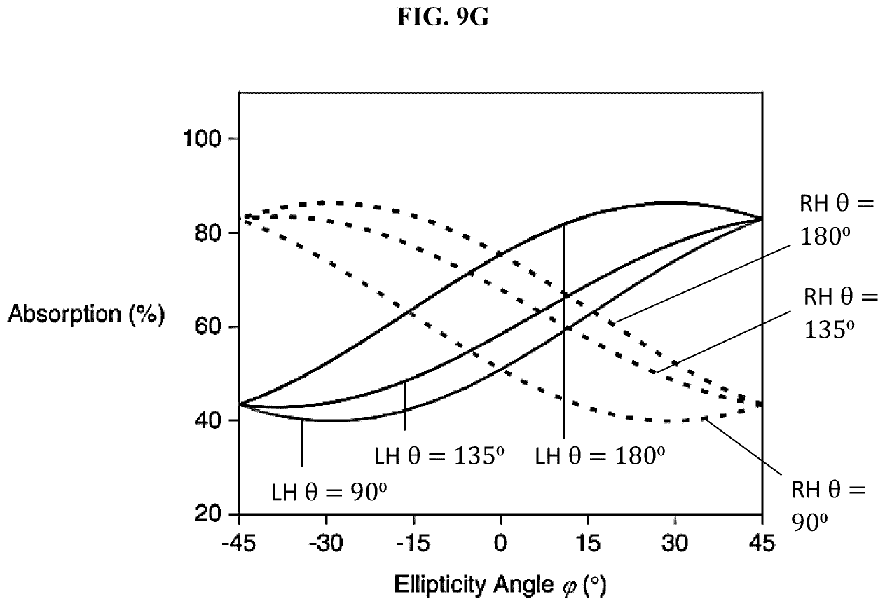

To further investigate the SoP-dependent photothermal response of metamaterials, a typical LH-M₂ metamaterial with a resonance peak at 5.3 μm is studied as another example. FIG. 9A shows a schematic of the left-hand (LH) M₂ metamaterial according to various embodiments. The incident polarized light may be described by the geometrical parameters of the ellipse. Ex and Ey denote the electric field vector along the semi-major axis and semi-minor axis, respectively. Θ denotes the angle between the semi-major axis of the polarization ellipse and the x-axis. φ denotes the ellipticity angle and equals to arctan Ex/Ey. The sign of φ indicates the chirality of polarization (positive—left-handed, negative—right-handed). FIG. 9B is a two-dimensional contour map of ellipticity angle φ (in degrees or °) as a function of azimuthal angle θ (in degrees or °) illustrating both simulated absorbance (Abs, in percent or %) and induced temperature increase (ΔT, in Kelvins or K) for both different light polarization status according to various embodiments. Due to the linear relation between the absorption (Abs) and the temperature increase (ΔT), ΔT shows a similar dependence on the azimuthal angle θ and ellipticity angle φ. The absorption difference between the maximum and the minimum absorptions can reach about 50%, leading to a temperature increase difference of about 2.5 K. For a fixed ellipticity angle φ, both the absorption and the temperature increase ΔT can fit well with a cosine function of the azimuthal angle θ with a weighted shift factor given by ellipticity angle φ. In detail, the absorption (Abs) can be calculated by the following fitted formula:

$$Abs = a + b cos ( 2 ( θ + 10 ) ) \qquad ( 1 )$$

$$( \begin{matrix}a \\ b\end{matrix} ) = ( \begin{matrix}{a}_{1} \\ {b}_{1}\end{matrix} ) + ( \begin{matrix}{a}_{2} \\ {b}_{2}\end{matrix} ) ( sin ( 2 φ ) cos ( 2 φ ) ) \qquad ( 2 )$$

where a indicates the azimuthal angle independent constant background absorption, and b indicates the amplitude of θ-resolved absorption component with a fixed φ. The a₁ and a₂ represent the constant component and the amplitude of the φ-resolved a component as a function of sine, respectively, and b₁ and b₂ represent constant component and the amplitude of the φ-resolved b component as a function of cosine, respectively. The 10° indicates the relative angle between the equivalent orientation and the long axis direction of the Z-shaped nanoantenna.

$$( \begin{matrix}{a}_{1} \\ {b}_{1}\end{matrix} ) ∼ ( \begin{matrix}63.15 \\ 0\end{matrix} ) \qquad ( 3 )$$

$$( \begin{matrix}{a}_{2} \\ {b}_{2}\end{matrix} ) ∼ ( \begin{matrix}19.7 \\ 13.16\end{matrix} ) \qquad ( 4 )$$

here, the values in the matrix are extracted by fitting the simulation results (the details of the extraction process are provided below). In particular, full-wave electromagnetic simulations have been performed for five polarization states indicated by dots as shown in FIG. 9B. FIG. 9C shows the corresponding power absorption density normalized by P₀ for different polarization status labelled by (i)-(v) in FIG. 9B of the left-hand (LH) metamaterial according to various embodiments. As shown in FIG. 9C, the high polarization-dependent absorptions come from the destructive or constructive interferences of the incident light beams through the linear polarization conversion. FIG. 9D shows the electric field distributions normalized to incident electric field at different polarization status for the left-hand (LH) metamaterial according to various embodiments.

The simulated temperature increase, ΔT, also shows a high polarization dependency and a linear relation to the incident light intensity. FIG. 9E shows a plot of temperature increase (ΔT) (in Kelvins or K) as a function of laser power (in milliWatts or mW) illustrating the analytical temperature increase of the left-hand (LH) metamaterial under incident laser power of different polarization status according to various embodiments.

The SoP-dependent optical responses for both LH and RH metamaterials are also considered. FIG. 9F shows a plot of absorption (in percent or %) as a function of azimuthal angle θ (in degrees or °) illustrating the stimulated absorbance at different ellipticity angles φ for both left-hand (LH) and right-hand (RH) metamaterials according to various embodiments. FIG. 9G shows a plot of absorption (in percent or %) as a function of ellipticity angle φ (in degrees or °) illustrating the stimulated absorbance at different azimuthal angles θ for both left-hand (LH) and right-hand (RH) metamaterials according to various embodiments. As shown in FIG. 9F, for a fixed ellipticity angle φ, absorptions for both LH and RH metamaterials follow a similar cosine-dependence on the azimuthal angle with only a 200 phase shift. As shown in FIG. 9G, for the elliptically polarized light with different fixed azimuthal angles θ, the absorption shows a reverse trend for LH and RH metamaterials when the ellipticity angle φ changes from −45° to 45°. It is noticed that the change of absorption with the ellipticity angle φ is non-monotonic and is also dependent on the azimuthal angle θ. These optical absorption properties of the designed metamaterials may directly correspond to the temperature increase ΔT of Au antenna, thereby directly determining the photovoltage response in the metamaterial-mediated devices.

The high SoP-dependent optical absorption may directly lead to a polarization-resolved PTE response in the detector integrated with chiral plasmonic metamaterials. To experimentally demonstrate this, devices may be fabricated using 2D thermoelectric materials including graphene (Gr), black phosphorus (BP), and palladium selenide (PdSe₂) nanoflakes as the active thermoelectric materials according to the configuration shown in FIG. 3D. All the fabricated devices show a linear polarization angle-dependent photovoltage (Vₚₕ) response, and hence, can also be applied to distinguish the LCP and RCP lights, indicating a high tolerance for selection of active materials for the proposed polarization-sensitive photodetection mechanism.

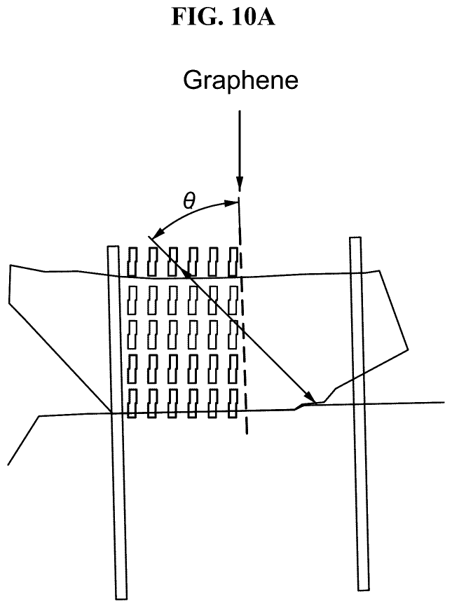

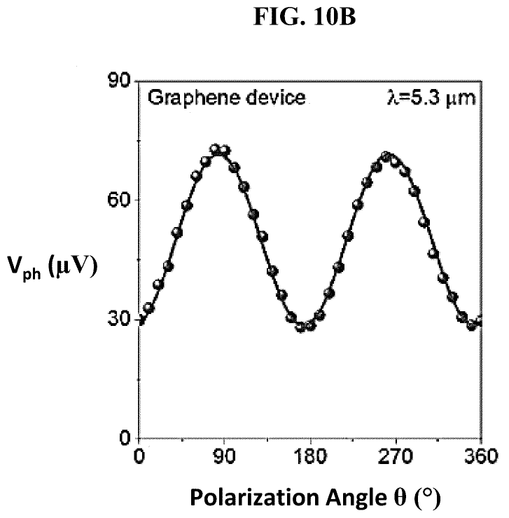

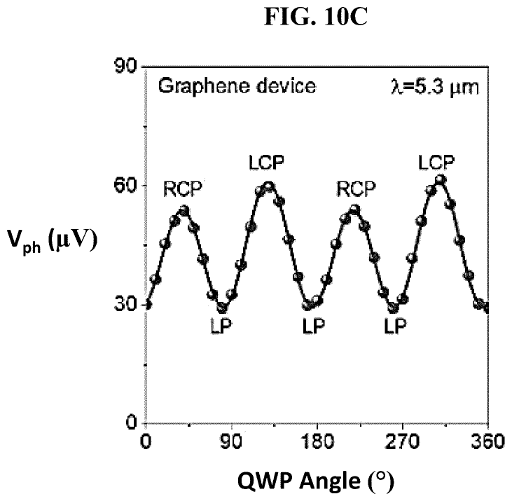

FIG. 10A shows an optical image of a graphene-based device according to various embodiments. FIG. 10B shows a plot of the photovoltage (Vₚₕ) response (in microVolts or μV) as a function of polarization angle θ (in degrees or °) illustrating the polarization angle dependent photoresponse of the graphene-based device according to various embodiments. FIG. 10C shows a plot of the photovoltage (Vₚₕ) response (in microVolts or μV) as a function of quarter-wave plate (QWP) angle θ (in degrees or °) illustrating the QWP angle dependent photoresponse of the graphene-based device according to various embodiments.

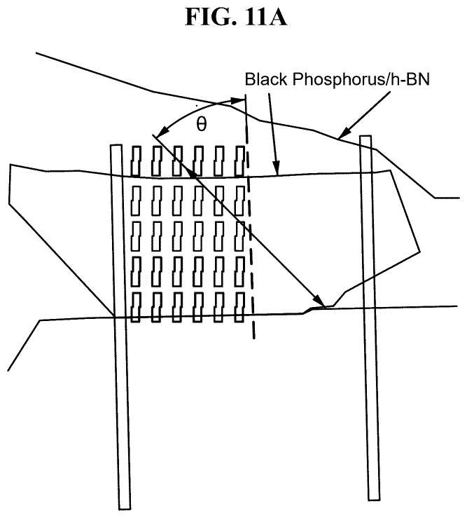

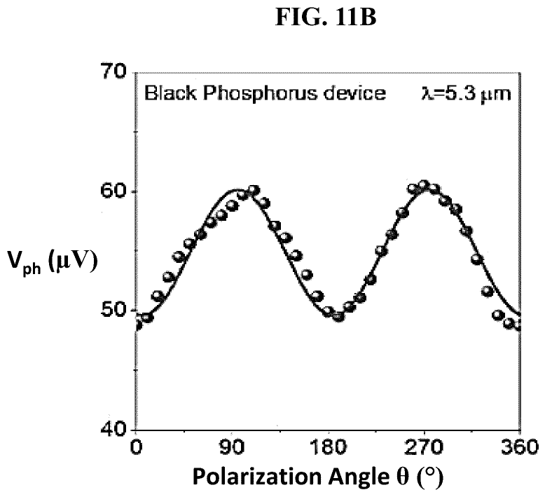

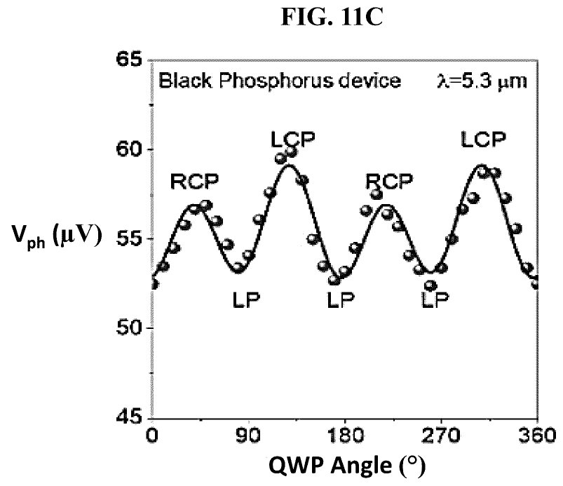

FIG. 11A shows an optical image of a black phosphorous (BP)-based device according to various embodiments. FIG. 11B shows a plot of the photovoltage (Vₚₕ) response (in microVolts or μV) as a function of polarization angle θ (in degrees or °) illustrating the polarization angle dependent photoresponse of the black phosphorous (BP)-based device according to various embodiments. FIG. 11C shows a plot of the photovoltage (Vₚₕ) response (in microVolts or μV) as a function of quarter-wave plate (QWP) angle θ (in degrees or °) illustrating the QWP angle dependent photoresponse of the black phosphorous (BP)-based device according to various embodiments.

The polarization-sensitive photoresponse comes from the plasmonic chiral metamaterials, but not from the intrinsic anisotropy of the active thermoelectric materials owing to the uniform illumination. Particularly, the working wavelength for BP photodetection can be extended to 5.3 μm, which is beyond its conventional cut-off wavelength of about 4.1 μm according to its bandgap at 0.3 eV. This indicates that the operation wavelength of the proposed approach may no longer be limited by the bandgap of the active material. On the other hand, the photoresponse of the PdSe₂-based device is higher than that of Gr- and BP-based devices because of its higher Seebeck coefficient.

In the following experimental demonstrations, PdS₂ nanoflakes and M₂ meta materials are used as active materials unless noted otherwise. In addition, the working wavelength of the proposed detectors can be designed by using appropriate metamaterials, revealing a devisable wavelength photodetection mechanism.

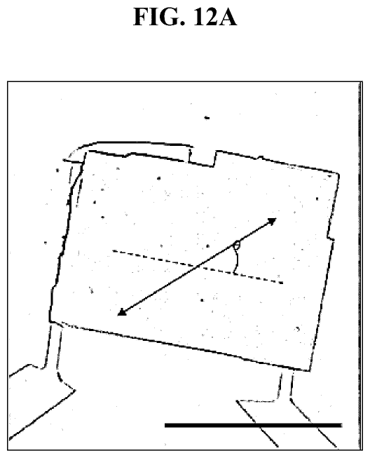

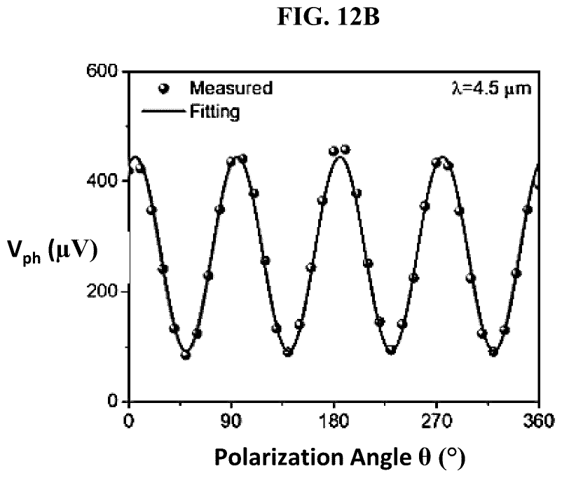

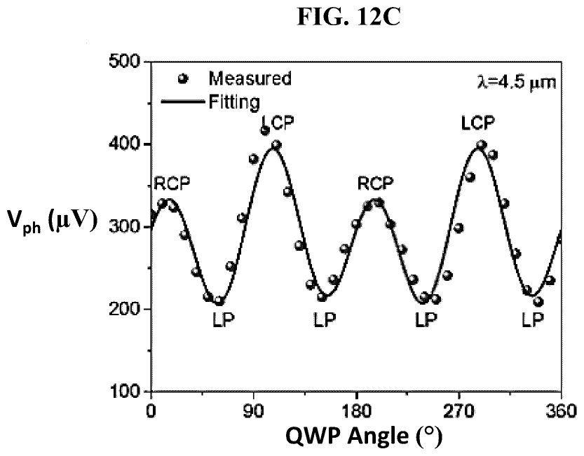

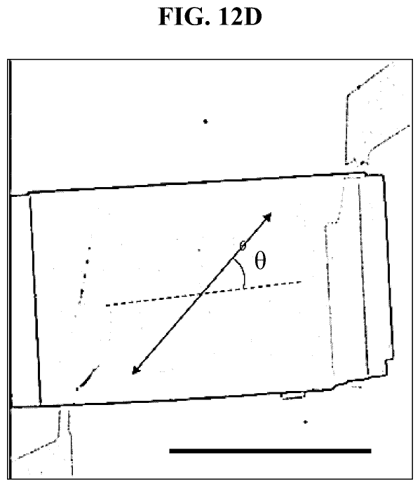

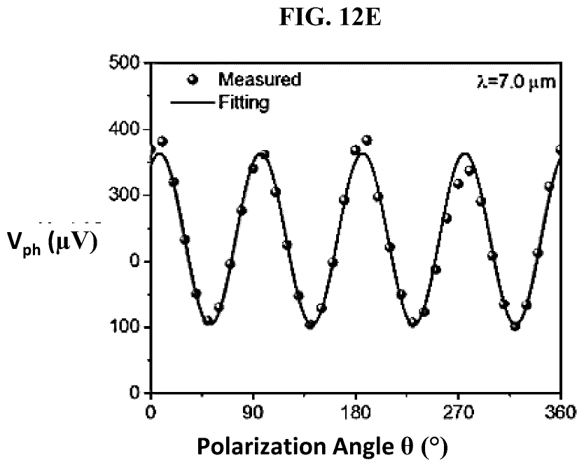

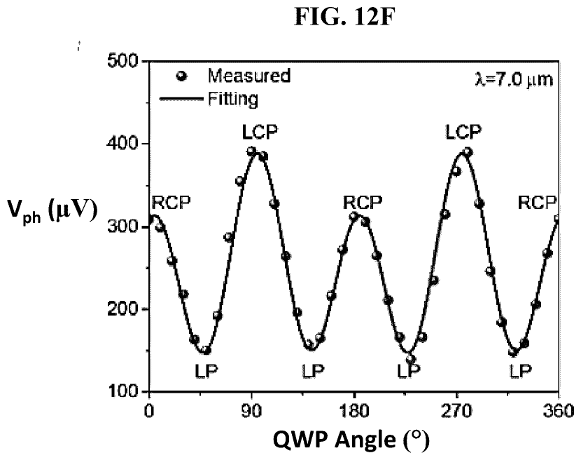

FIG. 12A shows an optical image of a lead selenide (PdSe₂) device for 4.5 μm infrared light detection according to various embodiments. The scale bar in FIG. 12A represents m. FIG. 12B shows a plot of the photovoltage (Vₚₕ) response (in microVolts or μV) as a function of polarization angle (in degrees or °) illustrating the half-wave plate (HWP) angle dependent photoresponse of the lead selenide (PdSe₂) device under 4.5 μm infrared illumination according to various embodiments. FIG. 12C shows a plot of the photovoltage (Vₚₕ) response (in microVolts or μV) as a function of quarter-wave plate (QWP) angle (in degrees or °) illustrating the quarter-wave plate (QWP) angle dependent photoresponse of the lead selenide (PdSe₂) device under 4.5 μm infrared illumination according to various embodiments. FIG. 12D shows an optical image of a lead selenide (PdSe₂) device for 7.0 μm infrared light detection according to various embodiments. The scale bar in FIG. 12D represents 20 μm. FIG. 12E shows a plot of the photovoltage (Vₚₕ) response (in microVolts or μV) as a function of polarization angle (in degrees or °) illustrating the half-wave plate (HWP) angle dependent photoresponse of the lead selenide (PdSe₂) device under 7.0 μm infrared illumination according to various embodiments. FIG. 12F shows a plot of the photovoltage (Vₚₕ) response (in microVolts or μV) as a function of quarter-wave plate (QWP) angle (in degrees or °) illustrating the quarter-wave plate (QWP) angle dependent photoresponse of the lead selenide (PdSe₂) device under 7.0 μm infrared illumination according to various embodiments.

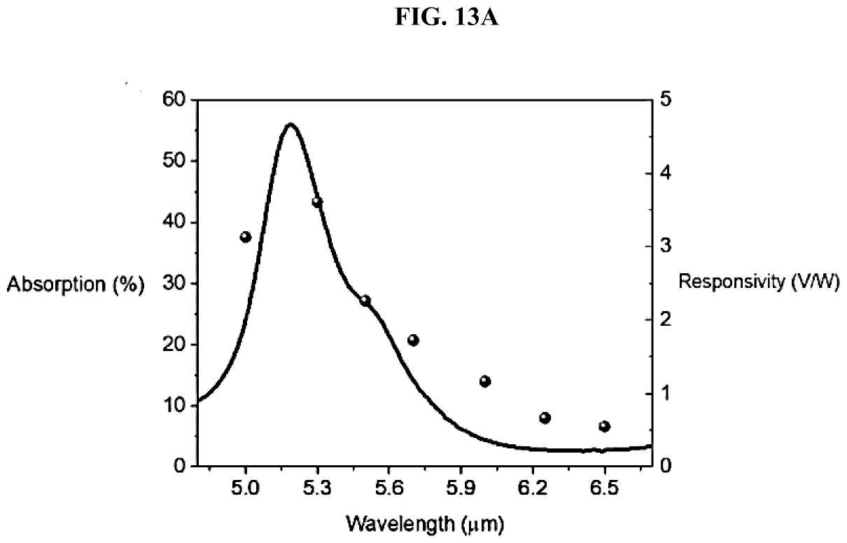

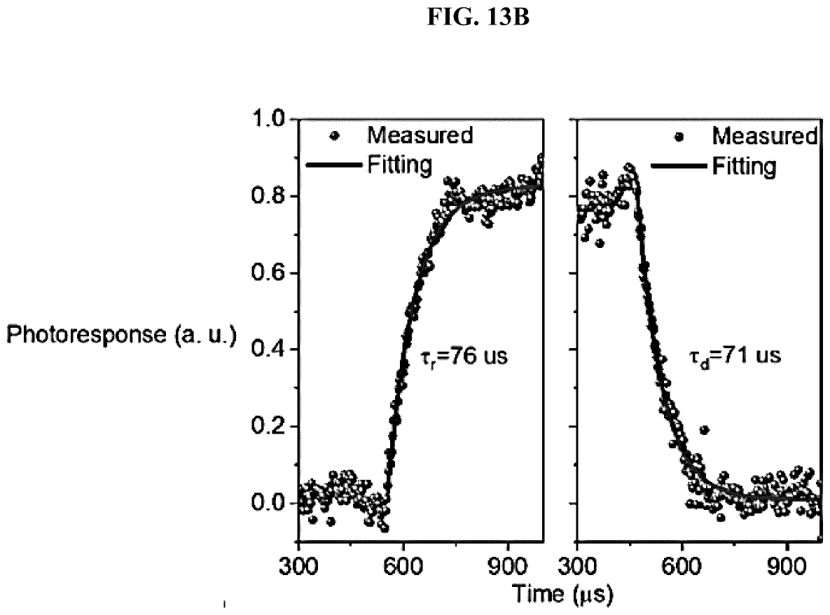

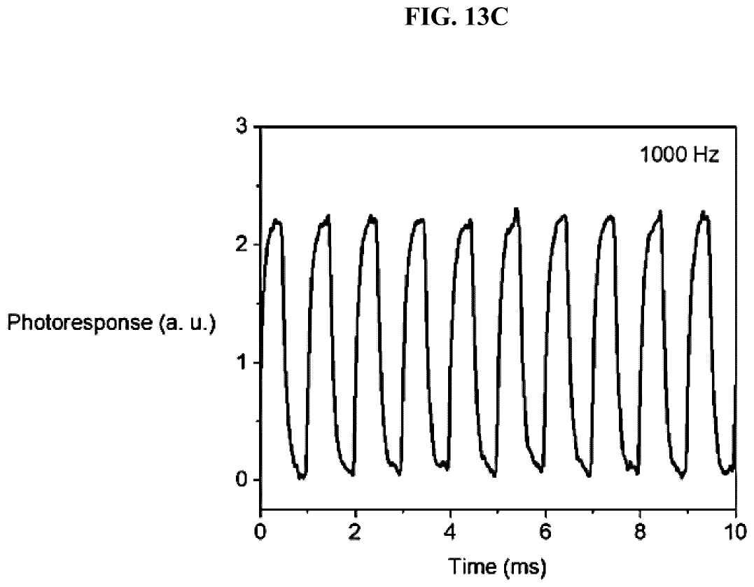

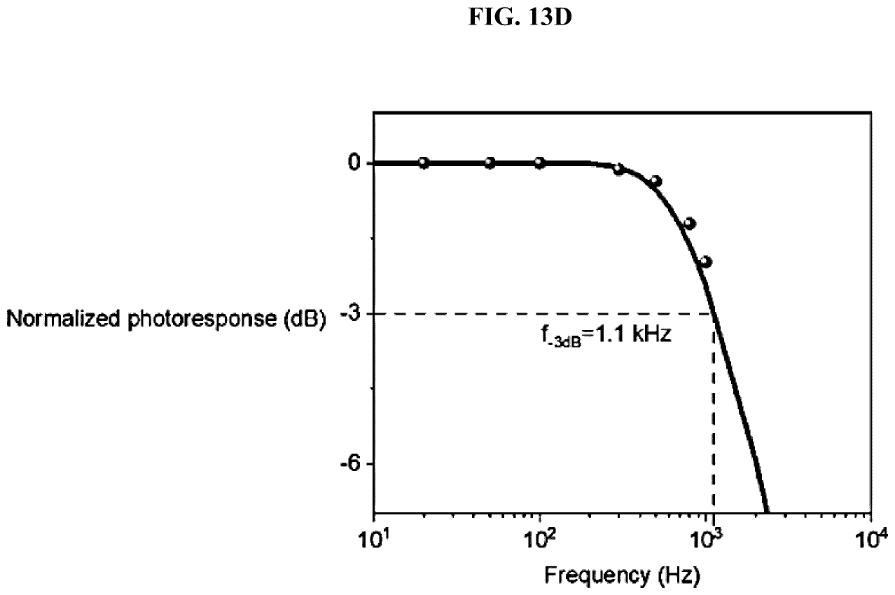

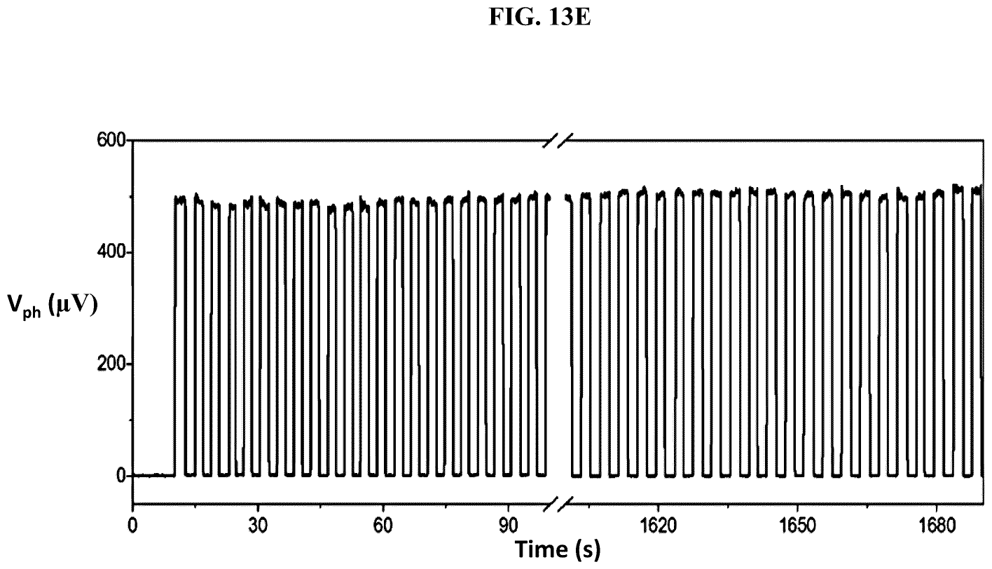

The device performance of a PdSe₂-based device integrated with LH-M₂ metamaterials at room temperature is also investigated. FIG. 13A shows a plot of absorption (in percent or %)/responsivity (in volts per watt or V/W) as a function of wavelength (in micrometres or μm) illustrating the absorption spectrum (line) of left hand (LH)-M₂ metamaterials under linear polarized light illumination and the corresponding responsivity (dots) of the LH-M₂ metamaterials mediated device according to various embodiments. The incident laser power is fixed at 20 mW. FIG. 13B shows plots of photoresponse (in arbitrary units or a.u.) as a function of time (in microseconds or μs) illustrating the time-resolved photoresponse (left: rise; right: decay) of the lead selenide (PdSe₂) device under 5.3 μm laser illumination according to various embodiments. The solid curves are fitted using exponential function, and show rise and decay response time constants of 76 μs and 71 μs, respectively. FIG. 13C shows a plot of photoresponse (in arbitrary units or a.u.) as a function of time (in milliseconds or ms) illustrating the measured time-resolved photoresponse of the lead selenide (PdSe₂) device with illumination signal chopped at 1000 Hz according to various embodiments. FIG. 13D shows a plot of normalized photoresponse (in decibels or dB) as a function of frequency (in hertz or Hz) of the lead selenide (PdSe₂) device illustrating a −3 dB bandwidth of around 1.1 kHz according to various embodiments. FIG. 13E shows a plot of the photovoltage (Vₚₕ) response (in microVolts or μV) as a function of time (in seconds or s) illustrating the measured long-term photoresponse of the lead selenide (PdSe₂) device according to various embodiments. The measured long-term photoresponse show good repeatability and stability.

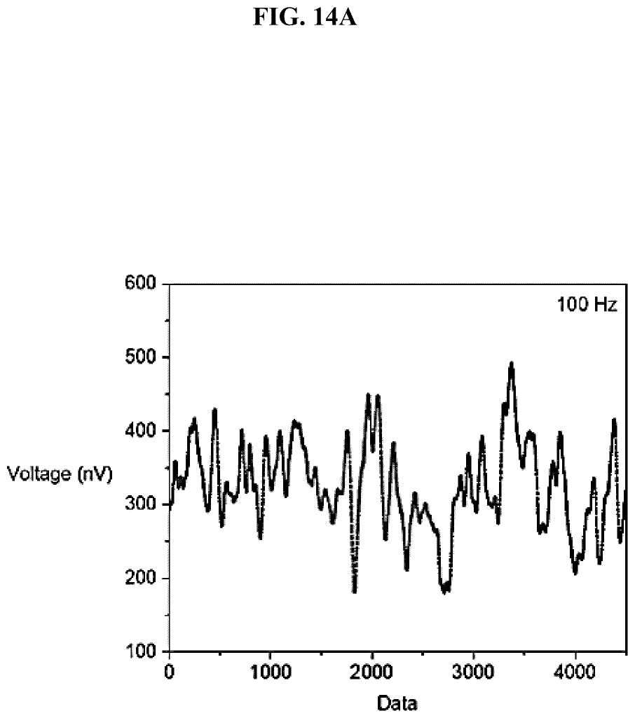

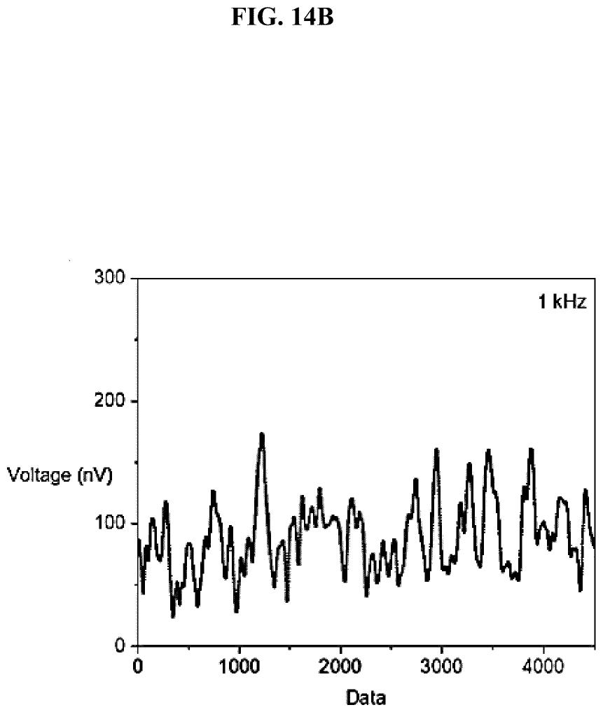

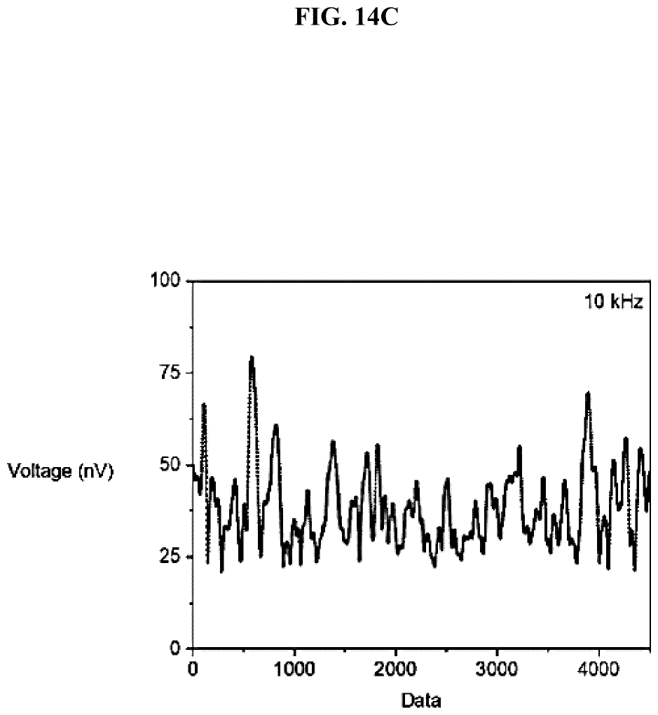

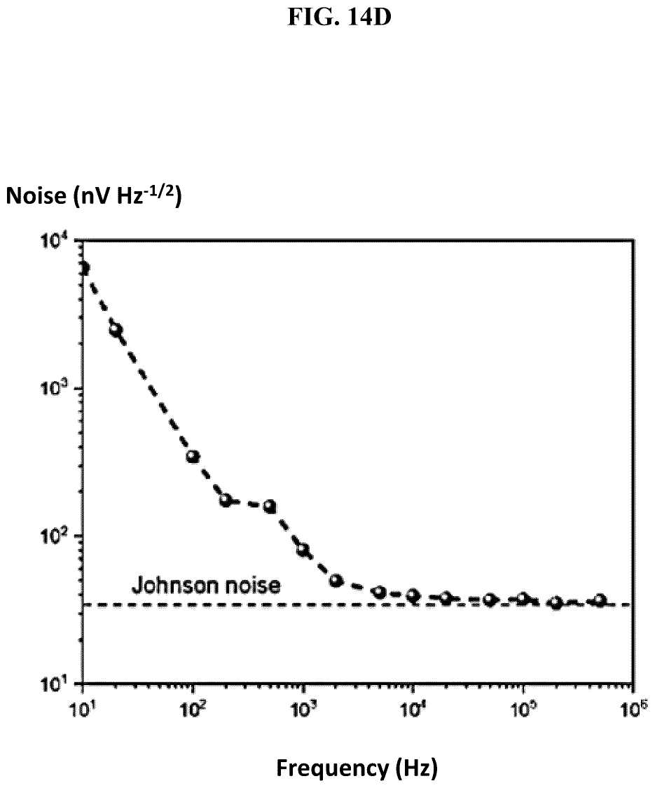

FIG. 14A shows a plot of voltage (in nanoVolts or nV) as a function of data illustrating the voltage data measured with a lock-in amplifier under an internal reference frequency of 100 Hz according to various embodiments. FIG. 14B shows a plot of voltage (in nanoVolts or nV) as a function of data illustrating the voltage data measured with a lock-in amplifier under an internal reference frequency of 1 kHz according to various embodiments. FIG. 14C shows a plot of voltage (in nanoVolts or nV) as a function of data illustrating the voltage data measured with a lock-in amplifier under different internal reference frequency of 10 kHz according to various embodiments. FIG. 14D shows a plot of noise (in nanoVolts per square root Hertz or nV Hz^{-1/2}) as a function of frequency (in Hertz or Hz) illustrating the spectral density of voltage noise showing a dramatic decrease with frequency and then keeping constant when the frequency is over about 1 kHz according to various embodiments.

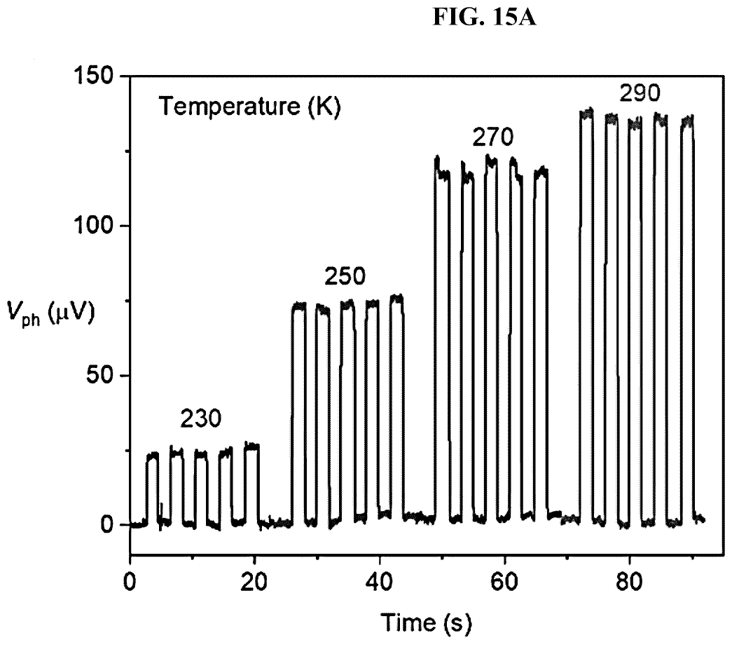

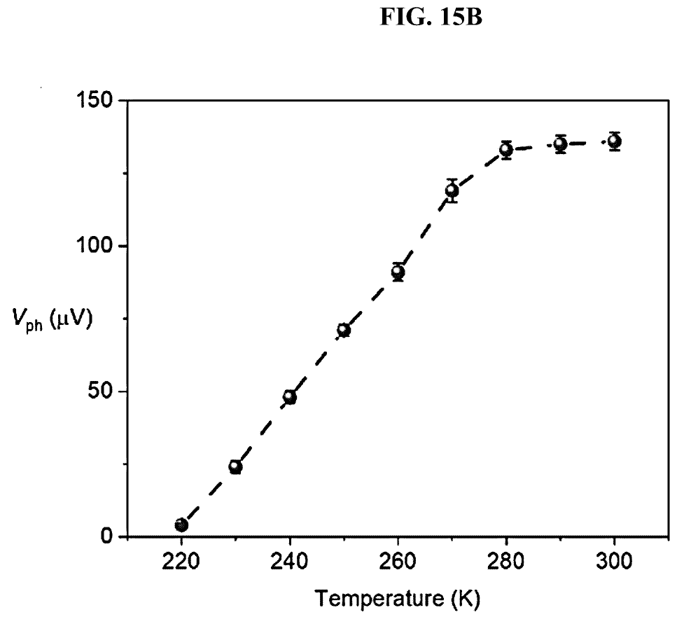

FIG. 15A shows a plot of photovoltage (Vₚₕ) response (in microVolts or μV) as a function of time (in seconds or s) illustrating the photoresponses of the device at different temperatures according to various embodiments. FIG. 15B shows a plot of photovoltage (Vₚₕ) response (in microVolts or μV) as a function of temperature (in Kelvins or K) illustrating the temperature-dependent photovoltages generated by the device with an incident light power of 38 W according to various embodiments.

As shown in FIGS. 13A-E, 14A-D, 15A-B, the wavelength-dependent photovoltage responsivity is in accordance with the absorption spectrum of the metamaterials, which may further verify the resonant PTE response of the device. Moreover, the detector exhibits a high responsivity up to 3.6 V W⁻¹, a short response time of 76 μs corresponding to a −3 dB bandwidth of 1.1 kHz, a low dark noise spectrum down to 35 nV Hz^{-1/2} corresponding to a noise-equivalent power of 9.7 nW Hz^{-1/2}, a specific detectivity of 2.5×10⁵ Jones, and good repeatability and stability at room-temperatures. Furthermore, the device exhibits a lower photoresponse at lower temperatures (FIGS. 15A-B), which results from the low-temperature gradient owing to the efficient heat dissipation or high thermal conductivity at low temperatures.

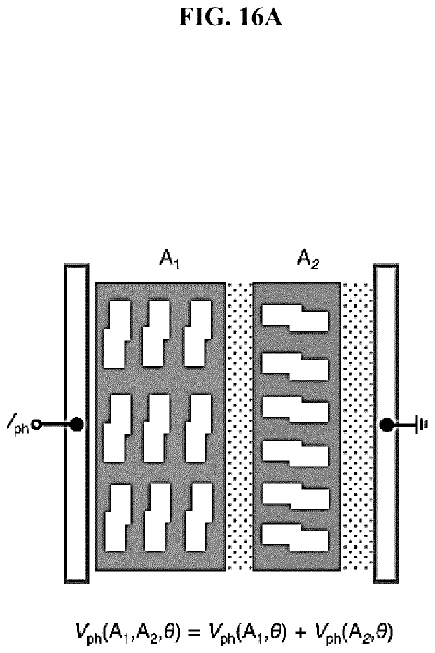

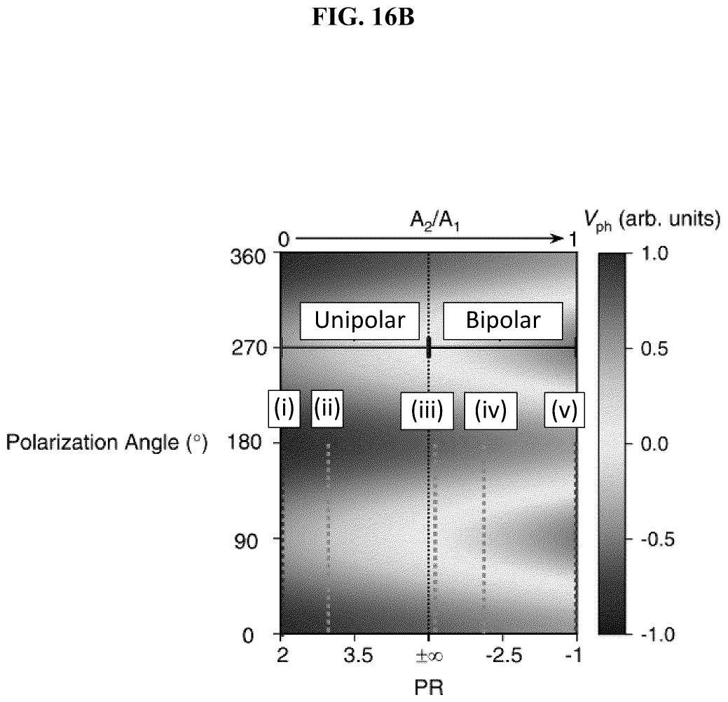

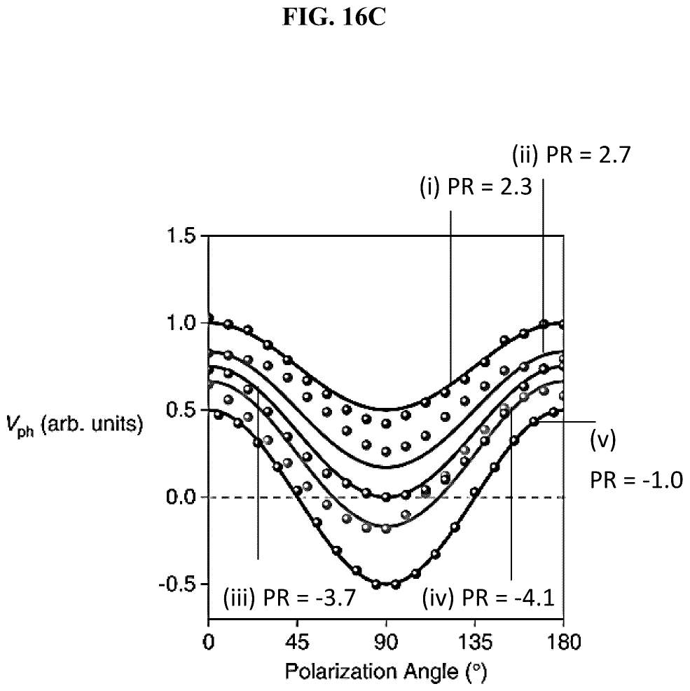

Leveraging on the linear and circular polarization dependence of the metamaterials mediated photoresponse, devices with a geometrically configurable polarity transition for linear polarization-sensitive detection may be designed by using LH metamaterials distributed in the left-half (A₁) and right-half (A₂) channel with a fixed relative orientation angle α=90°. FIG. 16A is a schematic of a photodetector having two pixels or nanoantenna arrays with an orientation angles of 90° between each other according to various embodiments. The two pixels or arrays may have a distribution area ratio A₂/A₁ for generation of a linear polarization angle θ-dependent photoresponse Vₚₕ (A₁, A₂, θ). The polarization-dependent photovoltage responses Vₚₕ for different distribution area ratio (A₂/A₁) are calculated and plotted in FIG. 16B showing that the PR changes from 2 to −1 with a polarity transition (from unipolar to bipolar) when A₂/A₁ changes from 0 to 1. This is clear evidence that the linear polarization sensitive detector exhibits a geometrically configurable polarity transition.

FIG. 16B shows a plot of polarization angle (in degrees or °) as a function of polarization ratio (PR) illustrating the variation of the linear polarization angle θ-dependent photoresponse Vₚₕ (A₁, A₂, θ) and the PR transition from unipolar regime to bipolar regime according to various embodiments. The bar shows the normalized photoresponse. FIG. 16C shows a plot of photoresponse Vₚₕ (in arbitrary units or a.u.) as a function of polarization angle (in degrees or °) illustrating the simulated (lines) and measured (solid circles) photoresponse of five devices (i)-(v) according to various embodiments. The polarization ratio (PR) values of the five devices are indicated in FIG. 16B. The five fabricated devices (i)-(v), with A₂/A₁=0, 0.33, 0.5, 0.67, and 1 experimentally verify the configurability of PR.

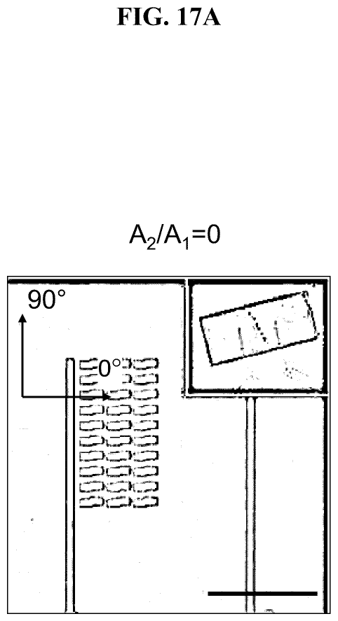

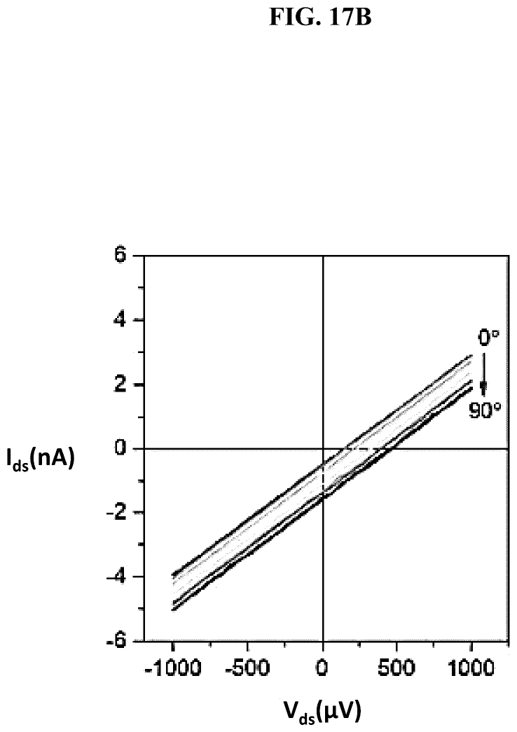

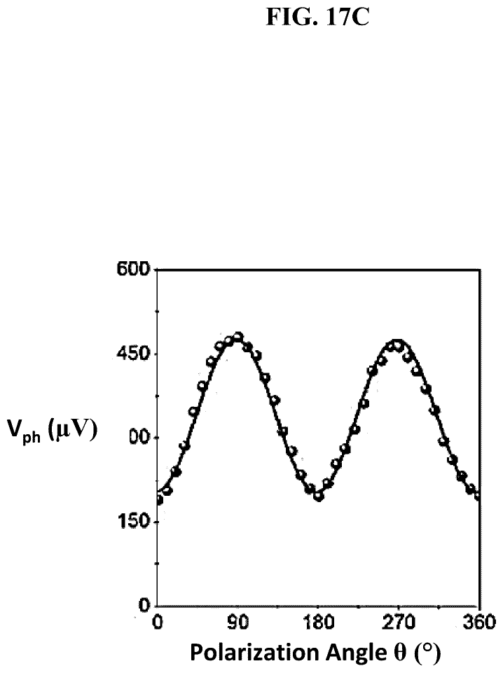

FIG. 17A shows an optical image of a device with A₂/A₁ ratio of 0 according to various embodiments. The scale bar represents 20 μm. FIG. 17B shows a plot of the channel current (I_{ds}) (in nanoAmperes or nA) as a function of the channel voltage (V_{ds}) (in microVolts or μV) of the device with A₂/A₁ ratio of 0 according to various embodiments. FIG. 17C shows a plot of photovoltage response Vₚₕ (in microVolts or μV) as a function of polarization angle θ (in degrees or °) showing the linear polarization response of the device with A₂/A₁ ratio of 0 according to various embodiments. The light polarization angle along the channel direction is set to be 0°.

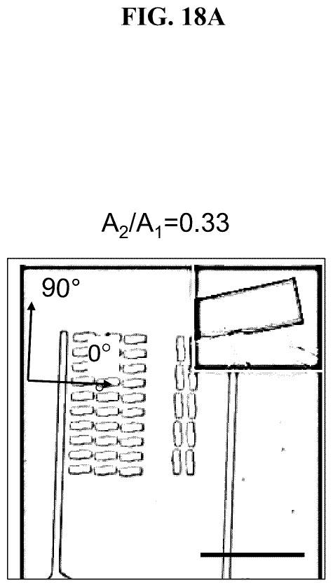

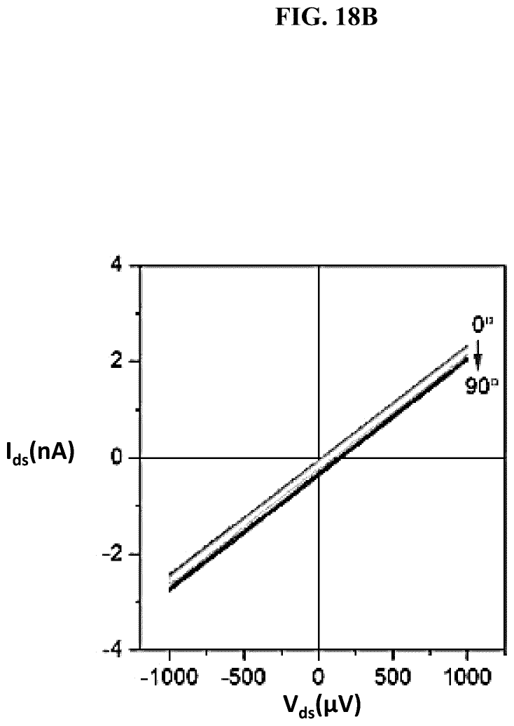

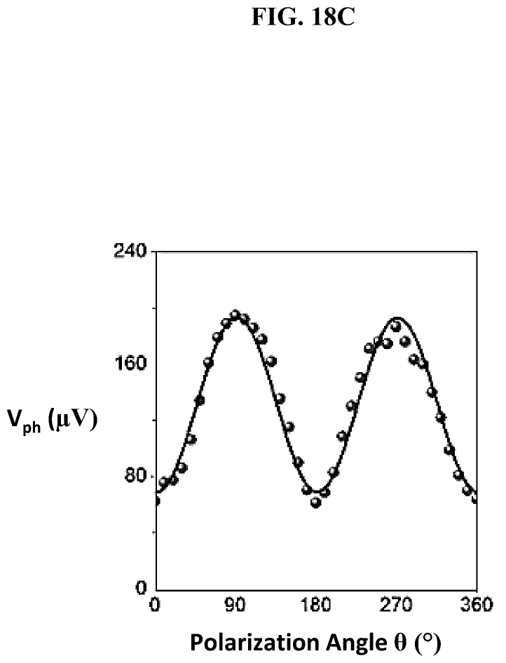

FIG. 18A shows an optical image of a device with A₂/A₁ ratio of 0.33 according to various embodiments. The scale bar represents 20 μm. FIG. 18B shows a plot of the channel current (I_{ds}) (in nanoAmperes or nA) as a function of the channel voltage (V_{ds}) (in microVolts or μV) of the device with A₂/A₁ ratio of 0.33 according to various embodiments. FIG. 18C shows a plot of photovoltage response Vₚₕ (in microVolts or μV) as a function of polarization angle θ (in degrees or °) showing the linear polarization response of the device with A₂/A₁ ratio of 0.33 according to various embodiments. The light polarization angle along the channel direction is set to be 0°.

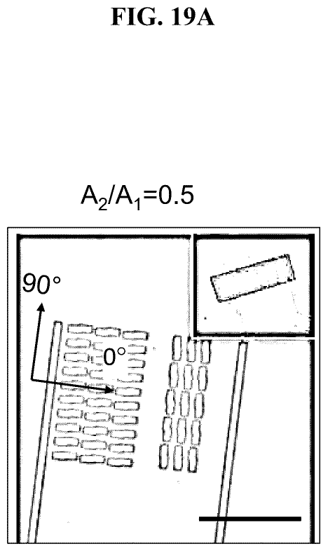

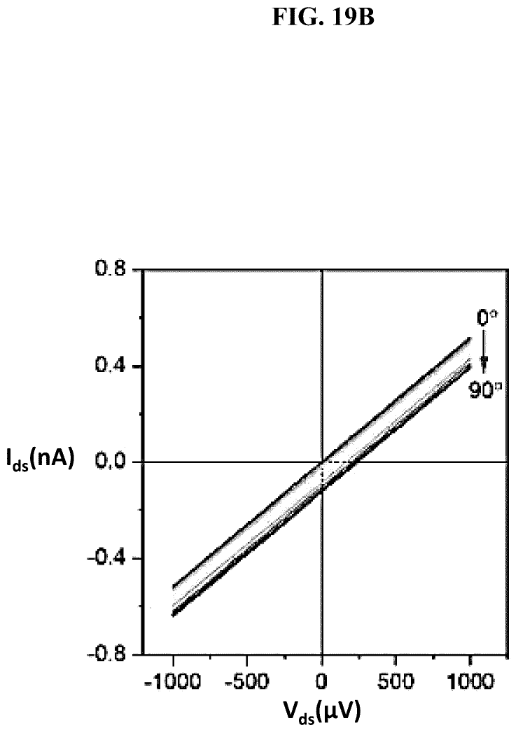

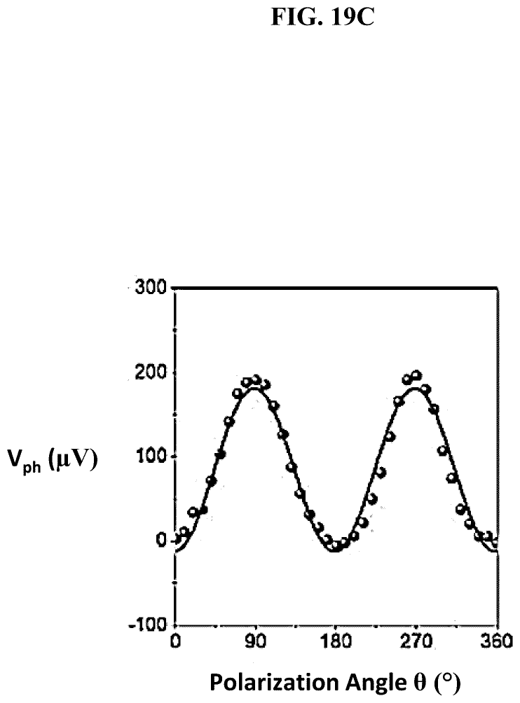

FIG. 19A shows an optical image of a device with A₂/A₁ ratio of 0.5 according to various embodiments. The scale bar represents 20 μm. FIG. 19B shows a plot of the channel current (I_{ds}) (in nanoAmperes or nA) as a function of the channel voltage (V_{ds}) (in microVolts or μV) of the device with A₂/A₁ ratio of 0.5 according to various embodiments. FIG. 19C shows a plot of photovoltage response Vₚₕ (in microVolts or μV) as a function of polarization angle θ (in degrees or °) showing the linear polarization response of the device with A₂/A₁ ratio of 0.5 according to various embodiments. The light polarization angle along the channel direction is set to be 0°.

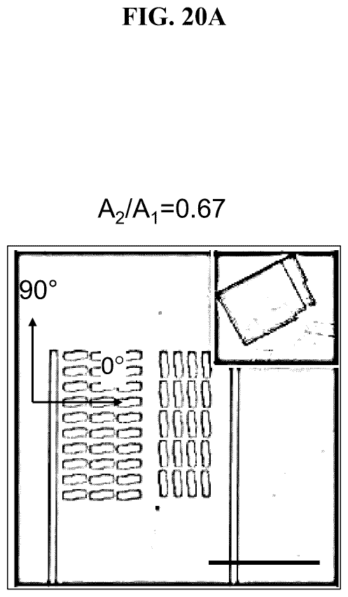

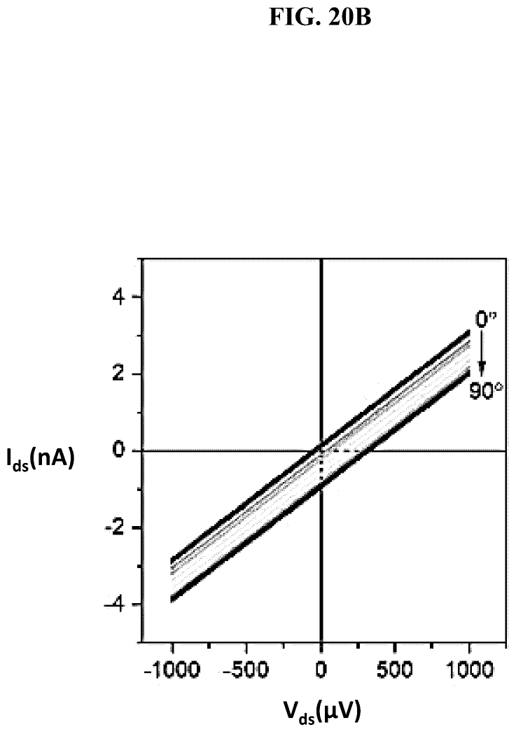

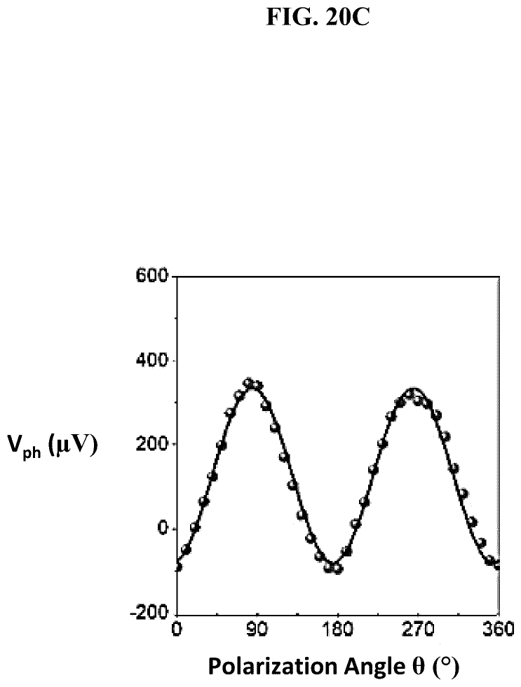

FIG. 20A shows an optical image of a device with A₂/A₁ ratio of 0.67 according to various embodiments. The scale bar represents 20 μm. FIG. 20B shows a plot of the channel current (I_{ds}) (in nanoAmperes or nA) as a function of the channel voltage (V_{ds}) (in microVolts or μV) of the device with A₂/A₁ ratio of 0.67 according to various embodiments. FIG. 20C shows a plot of photovoltage response Vₚₕ (in microVolts or μV) as a function of polarization angle θ (in degrees or °) showing the linear polarization response of the device with A₂/A₁ ratio of 0.67 according to various embodiments. The light polarization angle along the channel direction is set to be 0°.

Normalized experimental polarization-resolved photoresponses, with PR=2.3, 2.7, −37, −4.1, and −1, show good agreements with the calculated results in the configurable polarity transition (FIG. 16C).

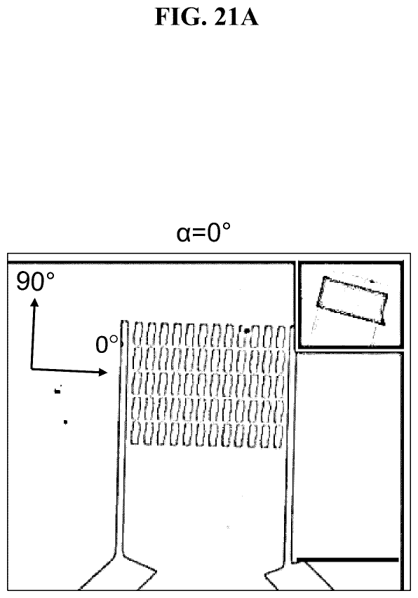

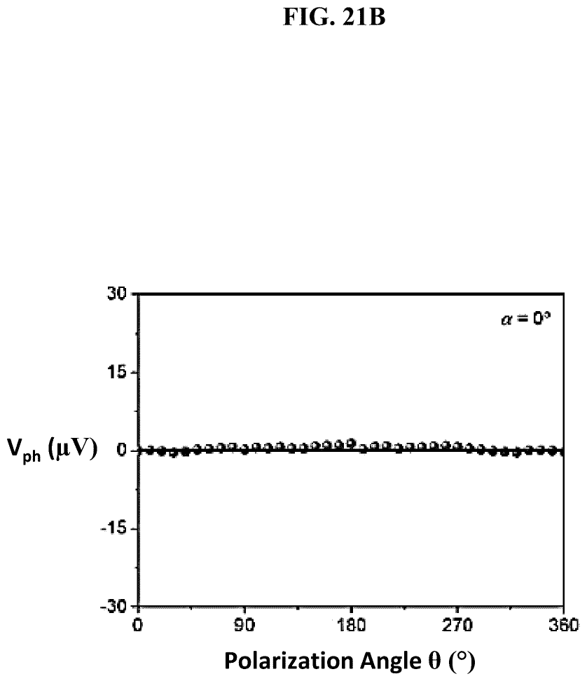

The configurable polarization dependence of designed devices with A₂/A₁=1 by changing the relative orientation angle α from 0° to 90° is also investigated. FIG. 21A shows an optical image of a device with A₂/A₁ ratio of 1 and orientation angle α of 0° according to various embodiments. The scale bar represents 20 μm. FIG. 21B shows a plot of photovoltage response Vₚₕ (in microVolts or μV) as a function of polarization angle θ (in degrees or °) showing the linear polarization response of the device with A₂/A₁ ratio of 1 and orientation angle α of 0° according to various embodiments. The light polarization angle along the channel direction is set to be 0°.

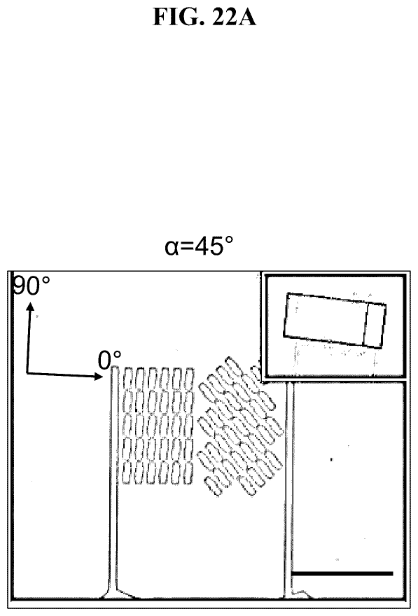

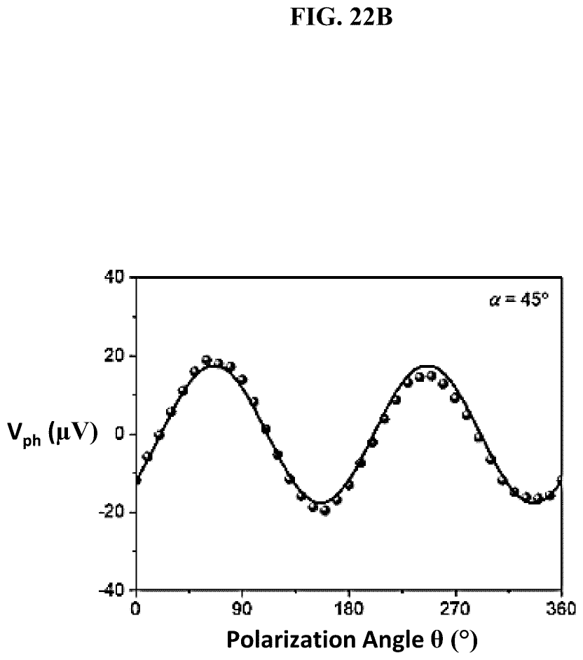

FIG. 22A shows an optical image of a device with A₂/A₁ ratio of 1 and orientation angle α of 45° according to various embodiments. The scale bar represents 20 μm. FIG. 22B shows a plot of photovoltage response Vₚₕ (in microVolts or μV) as a function of polarization angle θ (in degrees or °) showing the linear polarization response of the device with A₂/A₁ ratio of 1 and orientation angle α of 45° according to various embodiments. The light polarization angle along the channel direction is set to be 0°.

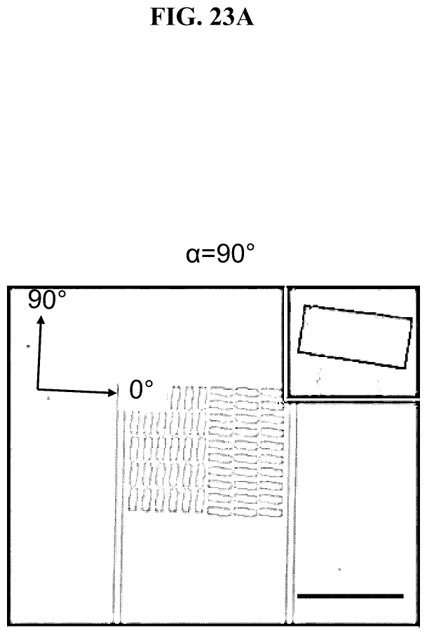

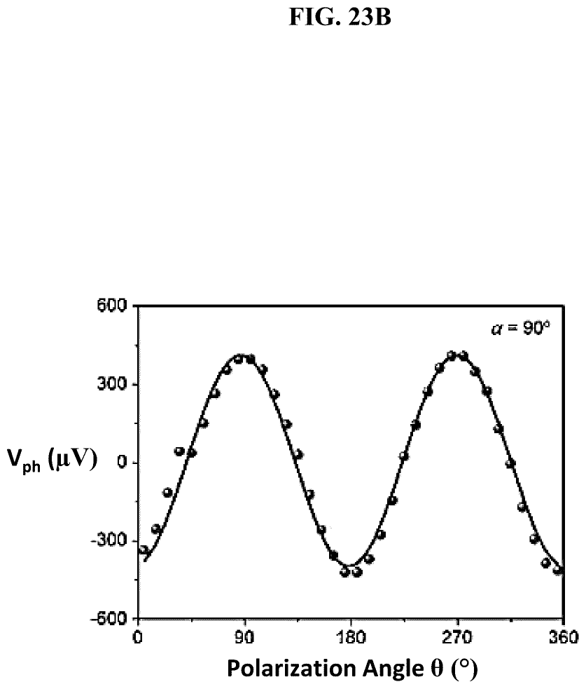

FIG. 23A shows an optical image of a device with A₂/A₁ ratio of 1 and orientation angle α of 90° according to various embodiments. The scale bar represents 20 μm. FIG. 23B shows a plot of photovoltage response Vₚₕ (in microVolts or μV) as a function of polarization angle θ (in degrees or °) showing the linear polarization response of the device with A₂/A₁ ratio of 1 and orientation angle α of 90° according to various embodiments. The light polarization angle along the channel direction is set to be 0°.

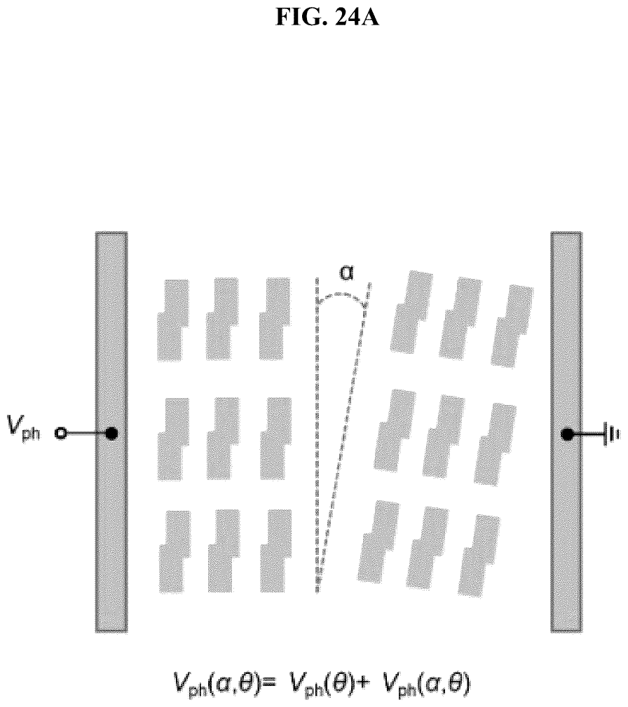

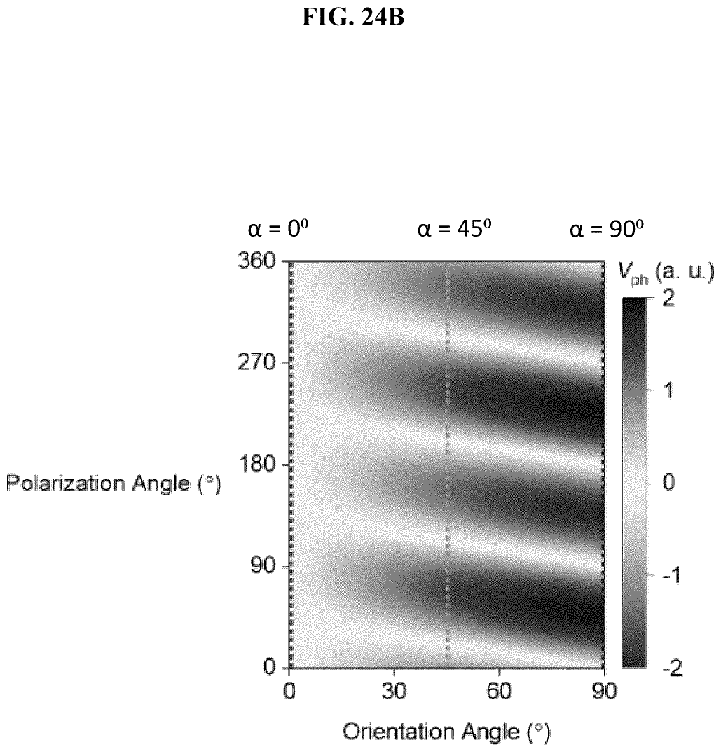

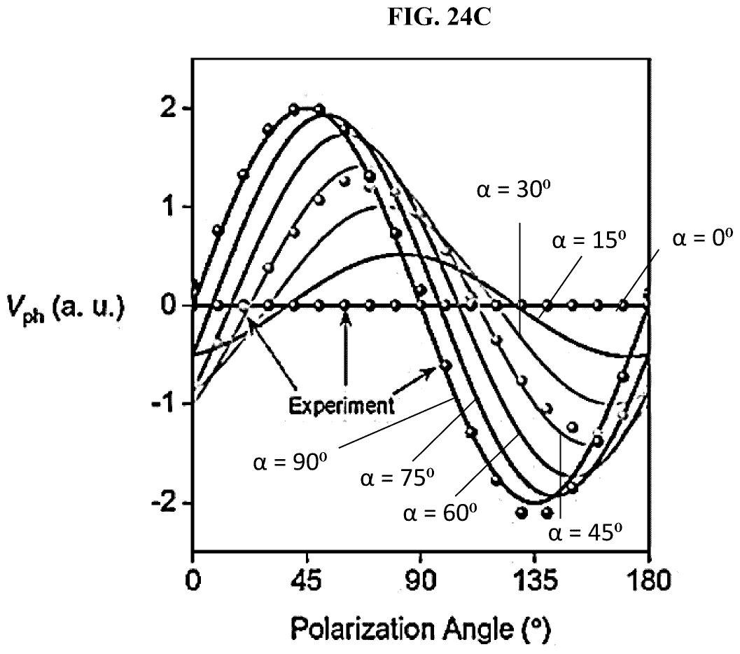

FIG. 24A is a schematic showing the calculation of the linear polarization angle θ-dependent photoresponses Vₚₕ (α, θ) with different orientation angles α of two arrays of metamaterials with the same distribution area according to various embodiments. FIG. 24B is a plot of polarization angle θ(in degrees or °) as a function of orientation angle (in degrees or °) illustrating the variation of linear polarization angle θ-dependent photoresponses Vₚₕ (α, θ) of the device with orientation angle according to various embodiments. The bar shows the normalized photoresponses. FIG. 24C shows a plot of normalized photoresponses (in arbitrary units or a.u.) as a function of polarization angle θ (in degrees or °) illustrating the simulated photoresponses of various devices (lines) and measured photoresponses of three devices (circles) with polarization ratio (PR) of −1 according to various embodiments. The measured photoresponses of the three devices are also indicated in FIG. 24B. As shown, the calculated polarization-dependent photovoltage responses exhibit an α-independent PR, but with a phase shift of the maximum response angle. The fabricated devices with α=0°, 45°, and 90°, show a good agreement in phase shift with the calculated results indicating a configurable polarization dependence, which is useful for full-Stokes detection in practical applications.

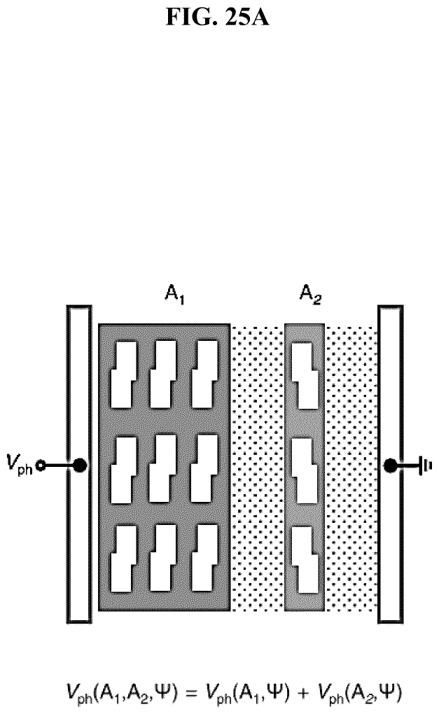

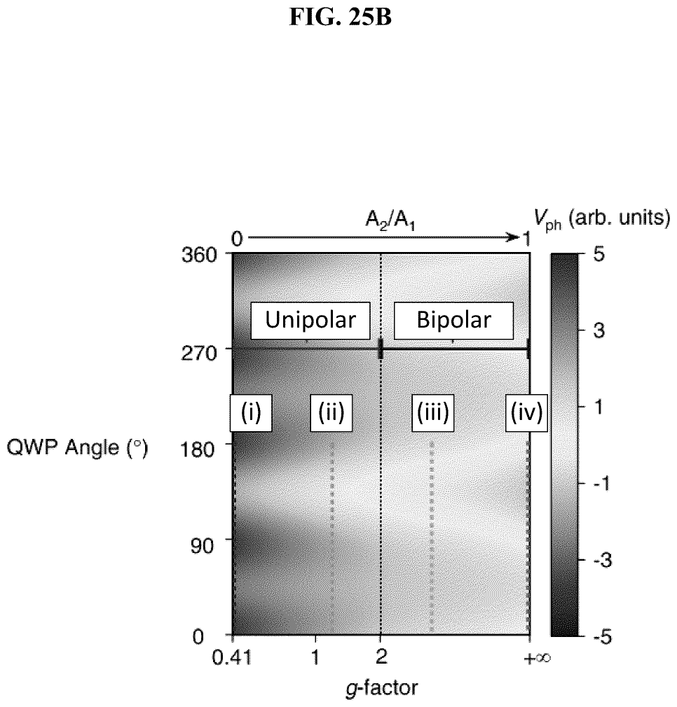

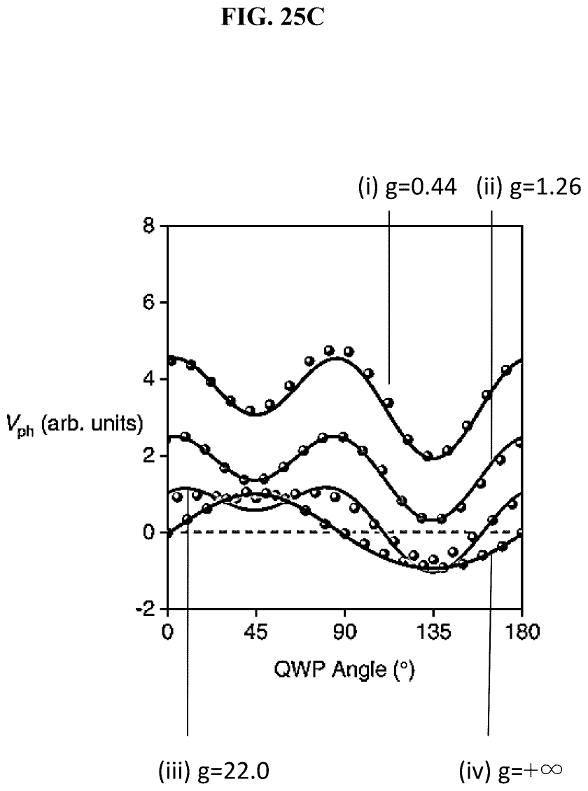

Thanks to the configuration flexibility of metamaterials, the proposed resonant PTE response may also enable the realization of circular polarization detection. The geometrically configurable polarity transition for the circular polarization sensitive detection may be investigated, which is crucial for realizing direct detection of chirality and ellipticity, simultaneously. Here, a series of devices with LH and RH metamaterials distributed in the left-half (A₁) and right-half (A₂) channels with various distribution area ratios A₂/A₁ were designed. FIG. 25A is a schematic of a photodetector having a pixel or nanoantenna array having left-hand (LH) and another pixel or nanoantenna array having right-hand (RH) metamaterials according to various embodiments. With a fixed A₁, the g-factor changes from about 0.41 to +∞ as the ratio A₂/A₁ changes from 0 to 1, with the polarity transition occurring at g=2. When the g-factor is in the range of 0-2, the device shows a unipolar circular polarization dependent photoresponse. While when the g-factor is in the range of g>2, the device shows a bipolar photoresponse. FIG. 25B shows a plot of quarter-wave plate QWP angle (in degrees or °) as a function of g-factor illustrating the variation of the QWP angle ψ (A₁, A₂, ψ) and the g-factor transition from unipolar regime to bipolar regime according to various embodiments. The bar shows the normalized photoresponse.

In the same way, a series of devices with various distribution area ratios A₂/A₁ were fabricated and their circular polarization-dependent photoresponses were measured by rotating a quarter-wave plate (QWP). The quarter-wave plate changes linearly polarized light into circularly polarized light. When the quarter-wave plate changes, circularly polarized light with different ellipticity angles may be generated. Experimental results of the QWP angle-dependent photoresponses are also compared with the calculation in FIG. 25C. FIG. 25C shows a plot of photoresponse Vₚₕ (in arbitrary units or a.u.) as a function of quarter-wave plate QWP angle (in degrees or °) illustrating the simulated (lines) and measured (solid circles) photoresponse of four devices (i)-(iv) according to various embodiments. The g-factor values of the four devices are indicated in FIG. 25B. Four fabricated devices with A₂/A₁=0, 0.33, 0.67, and 1 exhibit a g-factor of 0.44, 1.26, 22, and +∞, respectively. This indicates a configurable polarity transition for the circular polarization-sensitive detection.

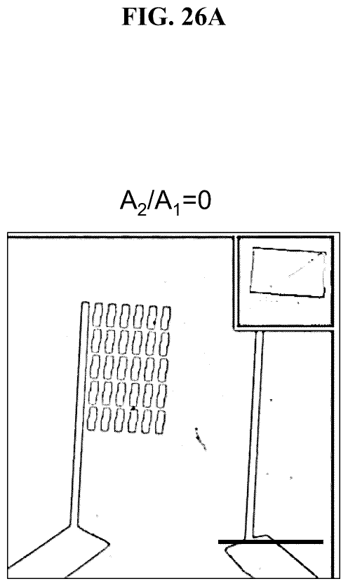

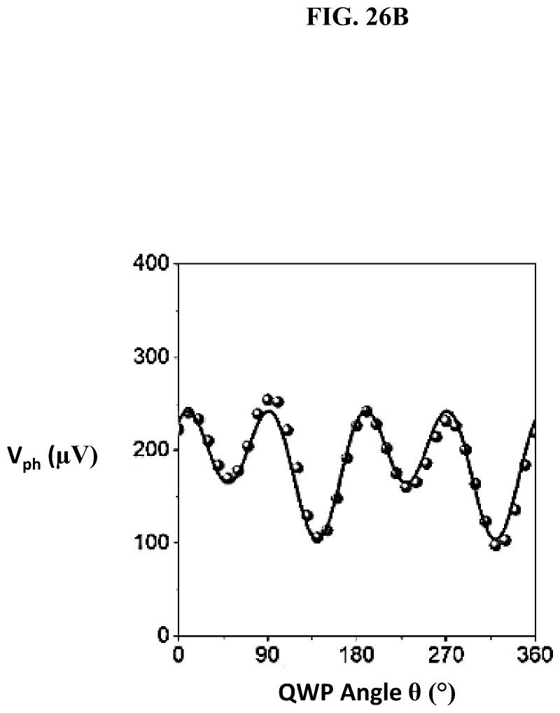

FIG. 26A shows an optical image of a device with A₂/A₁ ratio of 0 according to various embodiments. The scale bar represents 20 μm. FIG. 26B shows a plot of photovoltage response Vₚₕ (in microVolts or μV) as a function of quarter-wave plate QWP angle (in degrees or °) showing the measured QWP angle dependent response of the device with A₂/A₁ ratio of 0 according to various embodiments. The light polarization angle along the channel direction is set to be 0°.

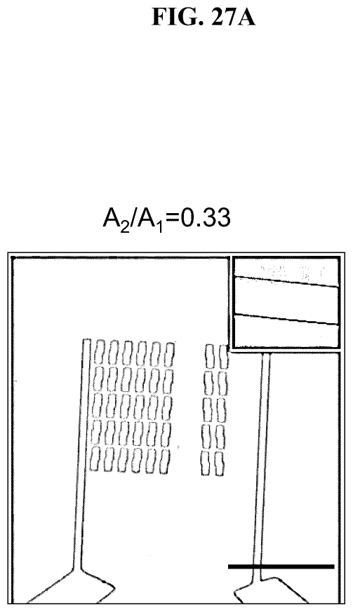

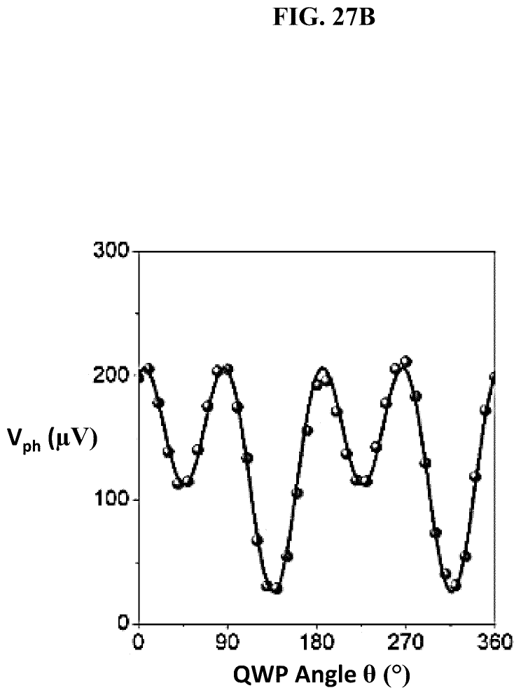

FIG. 27A shows an optical image of a device with A₂/A₁ ratio of 0.33 according to various embodiments. The scale bar represents 20 μm. FIG. 27B shows a plot of photovoltage response Vₚₕ (in microVolts or μV) as a function of quarter-wave plate QWP angle (in degrees or °) showing the measured QWP angle dependent response of the device with A₂/A₁ ratio of 0.33 according to various embodiments. The light polarization angle along the channel direction is set to be 0°.

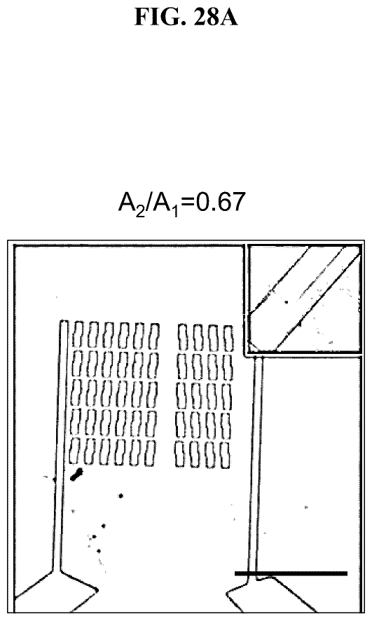

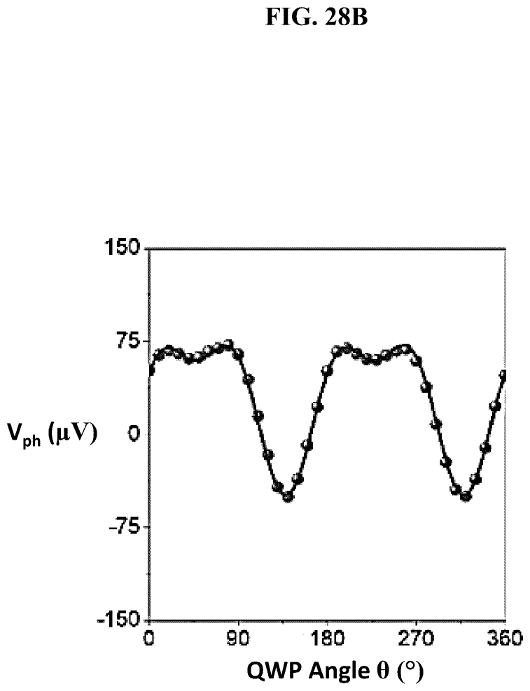

FIG. 28A shows an optical image of a device with A₂/A₁ ratio of 0.67 according to various embodiments. The scale bar represents 20 μm. FIG. 28B shows a plot of photovoltage response Vₚₕ (in microVolts or μV) as a function of quarter-wave plate QWP angle (in degrees or °) showing the measured QWP angle dependent response of the device with A₂/A₁ ratio of 0.67 according to various embodiments. The light polarization angle along the channel direction is set to be 0°.

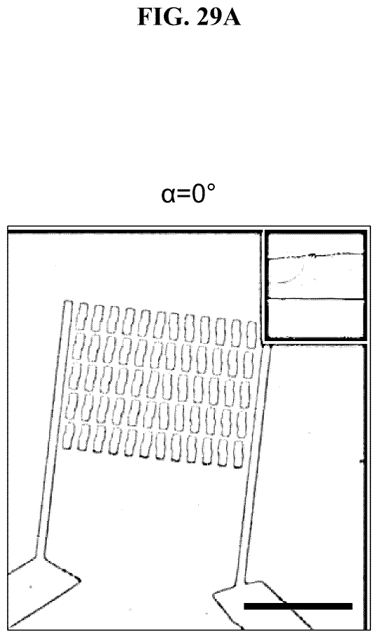

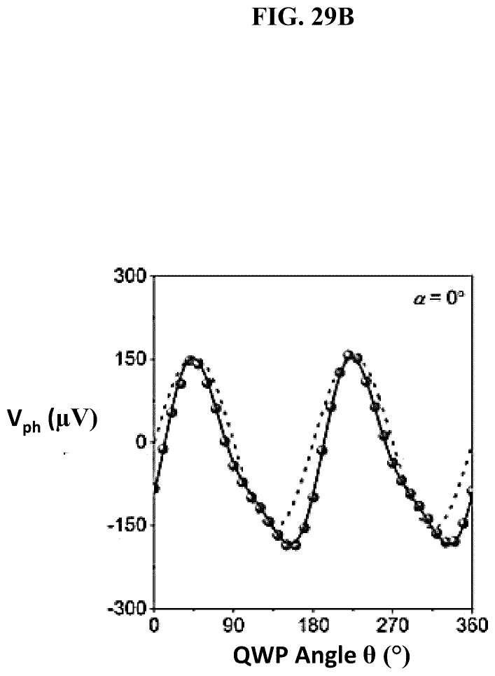

FIG. 29A shows an optical image of a device with A₂/A₁ ratio of 1 and orientation angle α of 0° according to various embodiments. The scale bar represents 20 μm. FIG. 29B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 0° according to various embodiments. The light polarization angle along the channel direction is set to be 0°.

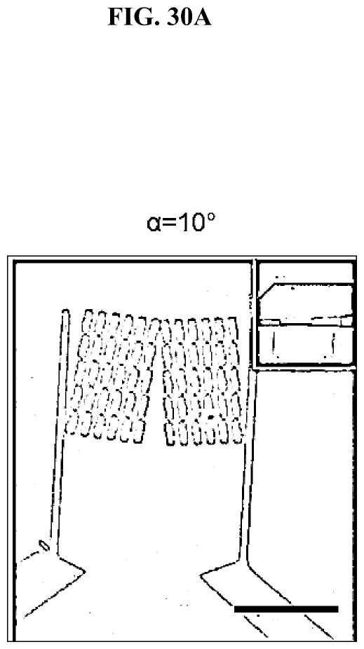

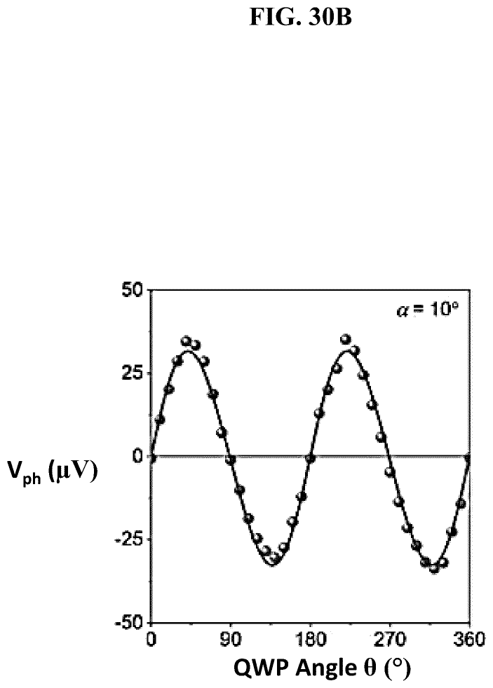

FIG. 30A shows an optical image of a device with A₂/A₁ ratio of 1 and orientation angle α of 10° according to various embodiments. The scale bar represents 20 μm. FIG. 30B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 10° according to various embodiments. The light polarization angle along the channel direction is set to be 0°.

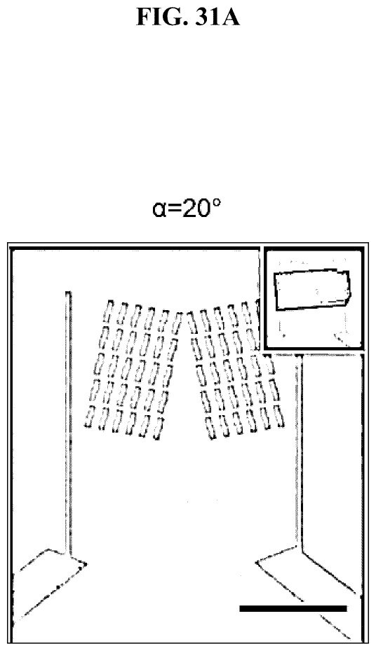

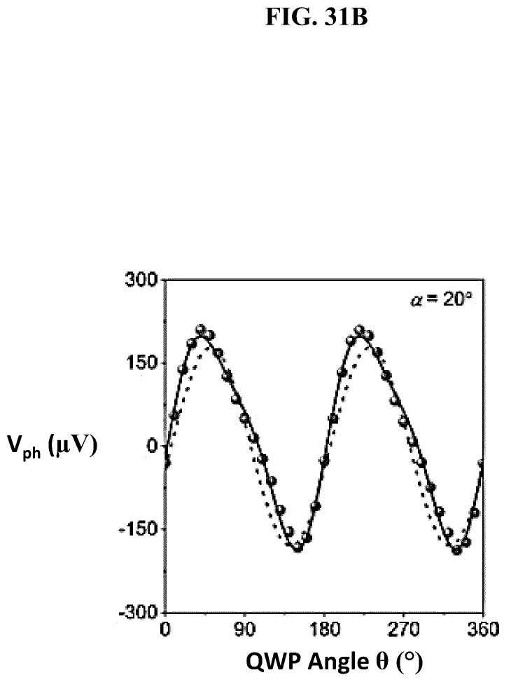

FIG. 31A shows an optical image of a device with A₂/A₁ ratio of 1 and orientation angle α of 20° according to various embodiments. The scale bar represents 20 μm. FIG. 31B shows a plot of photovoltage response Vₚₕ (in microVolts or μV) as a function of quarter-wave plate QWP angle (in degrees or °) showing the measured QWP angle dependent response of the device with A₂/A₁ ratio of 1 and orientation angle α of 20° according to various embodiments. The light polarization angle along the channel direction is set to be 0°.

It is worth noting that, owing to the phase shift of linear polarization-dependent absorption between LH and RH metamaterials as shown in FIG. 9F, the relative orientation angle α may be set as 20° to eliminate the linear polarization component from the QWP angle-dependent photoresponse. This results in a pure circular polarization-resolved photovoltage response, which can be fitted by a standard Sine function (FIG. 31B). It may be noted that the change of QWP angle from 450 to 1350 corresponds to an ellipticity angle change from 450 (LCP) to −45° (RCP) along with chirality and ellipticity changes. The photovoltage response of the device with A₂/A₁=1 and α=200 shows a monotonic relation with QWP angle in the range of 45°-135°, and a sign-flipping at 90°, indicating the ability of simultaneous detections of the chirality and ellipticity. In addition, the QWP angle-dependent photovoltage response shows a robustness to the linear polarization angle θ.

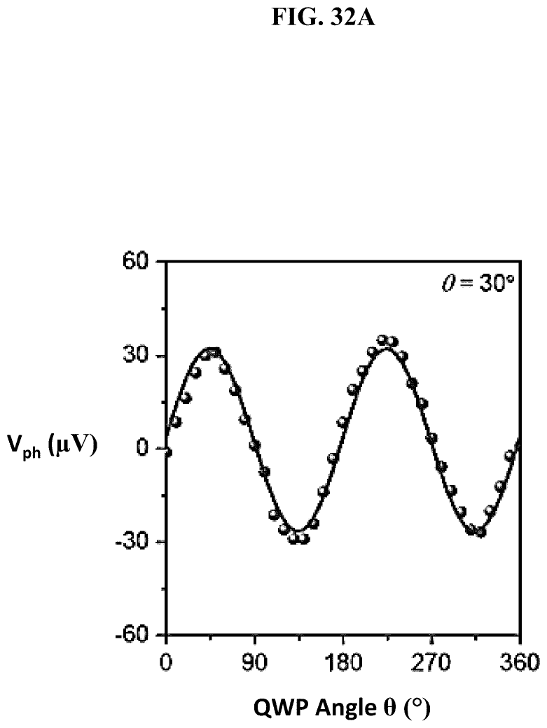

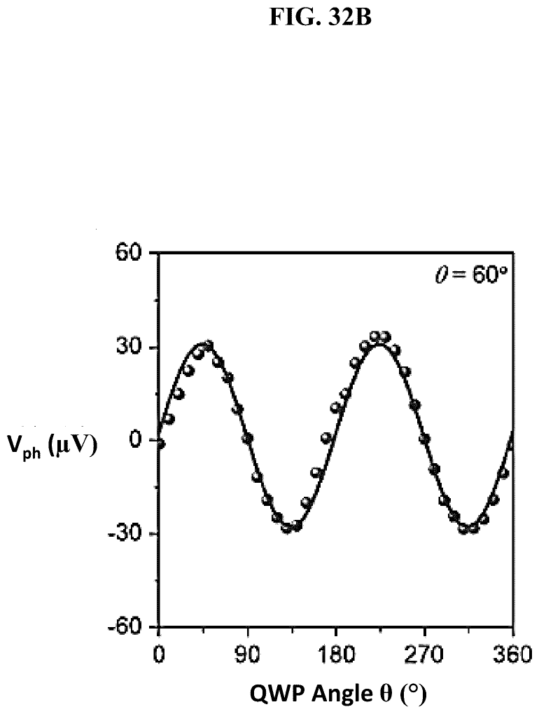

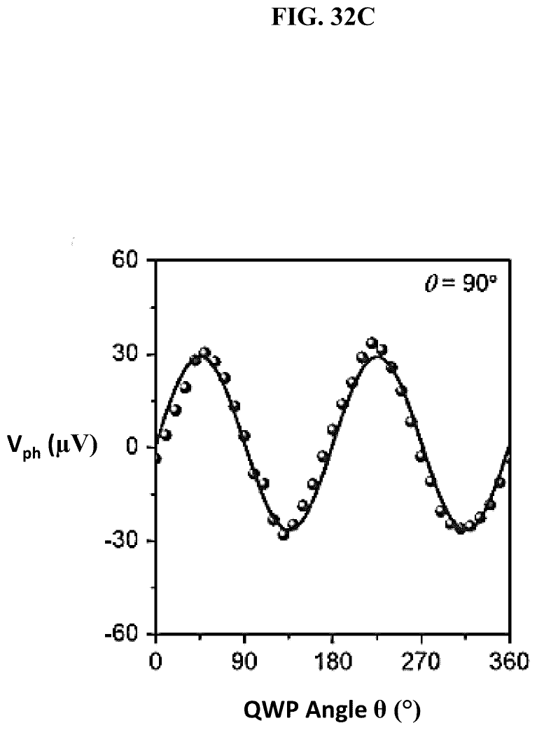

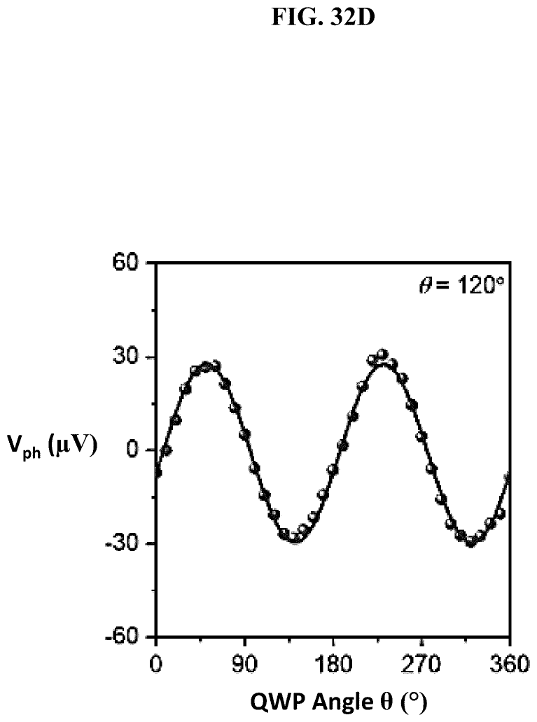

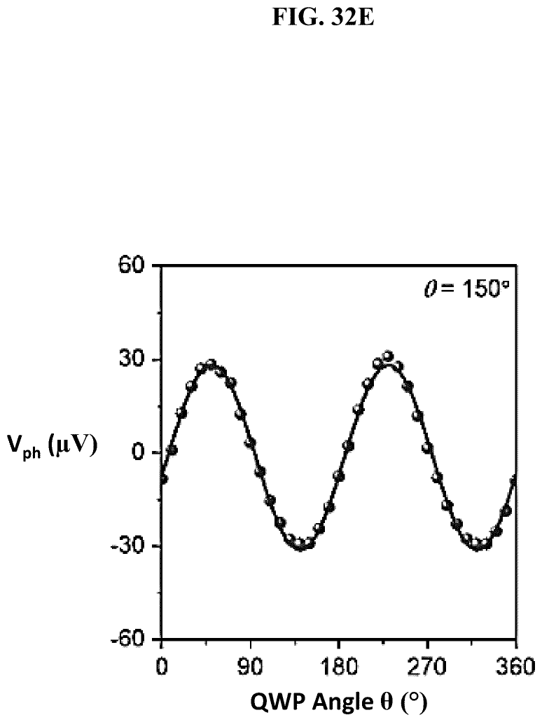

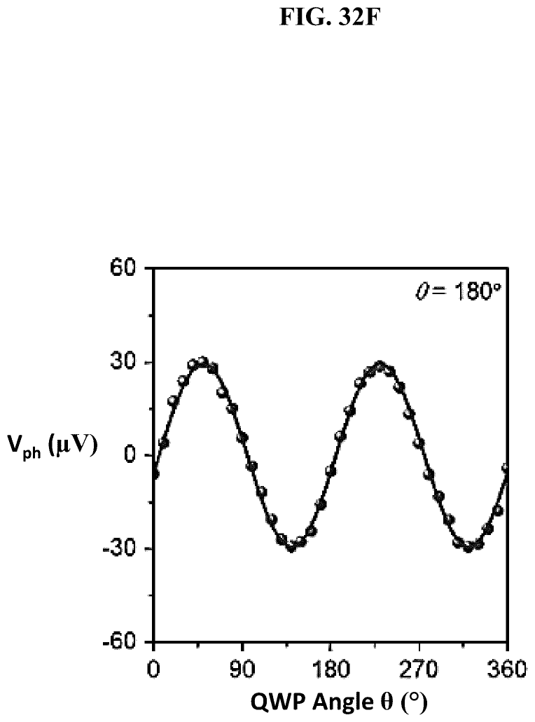

FIG. 32A shows a plot of photovoltage response Vₚₕ (in microVolts or μV) as a function of quarter-wave plate QWP angle (in degrees or °) showing the measured QWP angle dependent response of the device when the linear polarization angle is 30° according to various embodiments. FIG. 32B shows a plot of photovoltage response Vₚₕ (in microVolts or μV) as a function of quarter-wave plate QWP angle (in degrees or °) showing the measured QWP angle dependent response of the device when the linear polarization angle is 60° according to various embodiments. FIG. 32C shows a plot of photovoltage response Vₚₕ (in microVolts or μV) as a function of quarter-wave plate QWP angle (in degrees or °) showing the measured QWP angle dependent response of the device when the linear polarization angle is 90° according to various embodiments. FIG. 32D shows a plot of photovoltage response Vₚₕ (in microVolts or μV) as a function of quarter-wave plate QWP angle (in degrees or °) showing the measured QWP angle dependent response of the device when the linear polarization angle is 120° according to various embodiments. FIG. 32E shows a plot of photovoltage response Vₚₕ (in microVolts or μV) as a function of quarter-wave plate QWP angle (in degrees or °) showing the measured QWP angle dependent response of the device when the linear polarization angle is 150° according to various embodiments. FIG. 32F shows a plot of photovoltage response Vₚₕ (in microVolts or μV) as a function of quarter-wave plate QWP angle (in degrees or °) showing the measured QWP angle dependent response of the device when the linear polarization angle is 180° according to various embodiments.

Therefore, by geometrical configuration such as changing the distribution area ratio and the relative orientation angle, the designed device can not only distinguish the LCP and RCP light, but also directly detect the chirality and ellipticity, simultaneously.

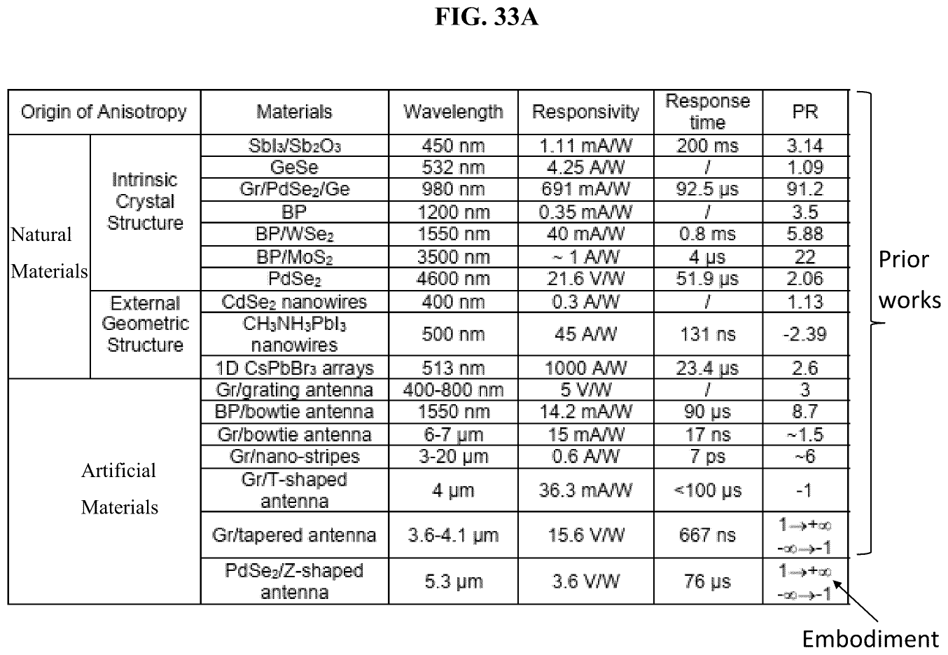

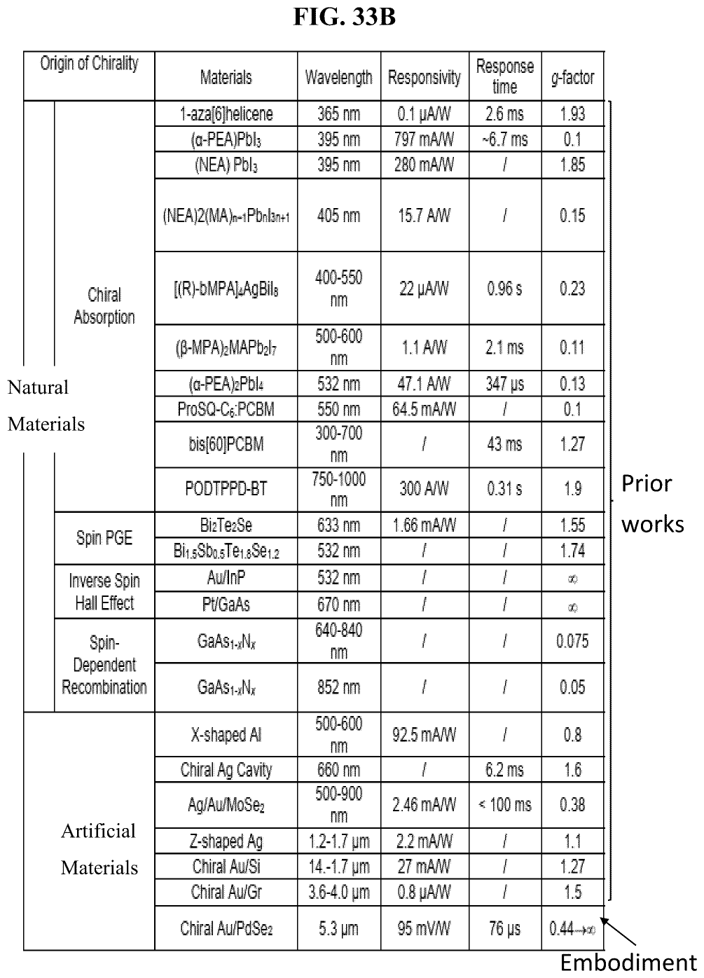

More detailed comparisons with the existing linear and circular polarization-sensitive photodetectors are provided in FIGS. 33A-B. FIG. 33A shows a table comparing existing linear polarization sensitive photodetectors with the photodetector according to various embodiments. FIG. 33B shows a table comparing existing circular polarization sensitive photodetectors with the photodetector according to various embodiments.

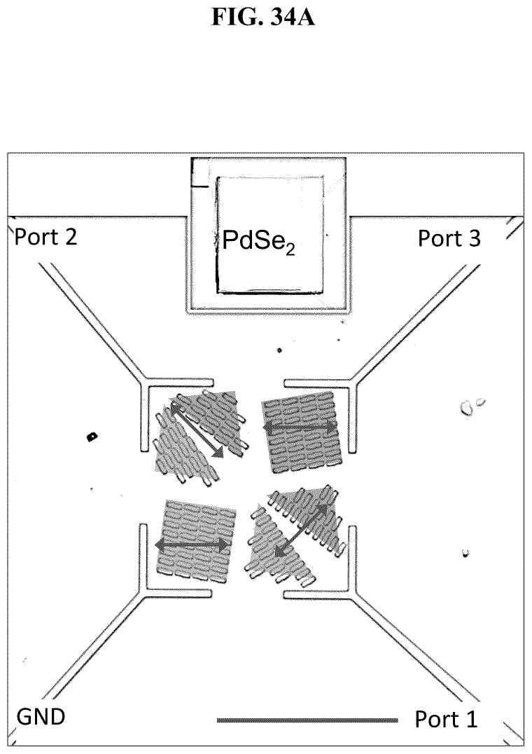

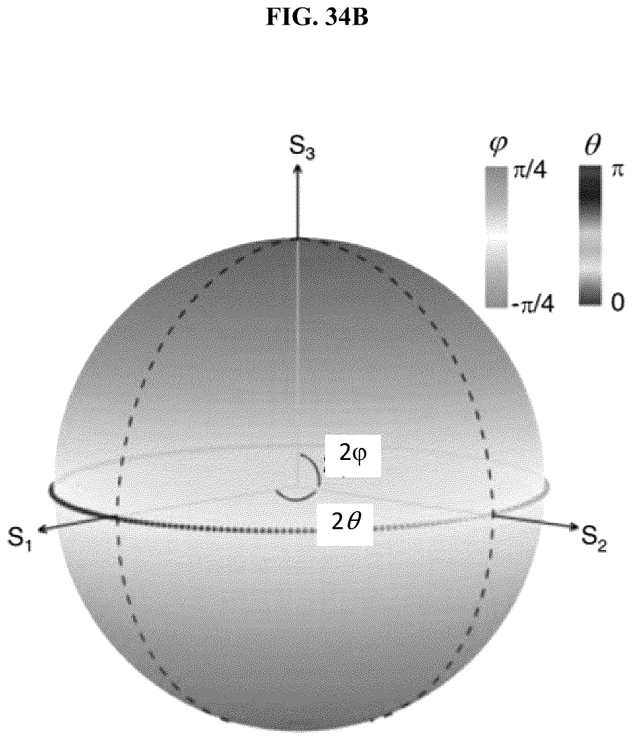

To demonstrate the usefulness of the bipolar devices for both linear and circular polarized light detection, a three-ports photodetector may be designed with the advantages of resolving the SoP of different incident polarized light. FIG. 34A shows an optical image of a three-ports photodetector according to various embodiments. The GND port may be used as the ground terminal for other three port outputs. The arrows indicate the equivalent orientation of metamaterials in each part. The image also indicates LH and RH chiral metamaterials. The scale bar represents 25 μm. The inset shows a zoomed-out image of the photodetector. For an arbitrary SoP, it can be described by using the geometrical parameters of an ellipse including the amplitude A, the azimuthal angle θ and the ellipticity angle φ. On the other hand, the SoP can also be described by a Stokes vector in a Poincare sphere as shown in FIG. 34B. FIG. 34B shows a schematic illustration of the full-Stokes information in a Poincare sphere according to various embodiments. Here, four Stokes parameters include the total intensity S₀, the two linear components S₁ and S₂, and the chiral component S₃. In other words, S₁ and S₂ are the linear parameters that characterize the direction of the linear component, while S₃ is the circularly polarized parameter that quantifies the circular component. For a fully polarized light, the relation between Stokes parameters and geometrical ellipse parameters can be described with following formula:

$${S}_{0} = {A}^{2} \qquad ( 5 )$$

$${S}_{1} = {A}^{2} cos 2 θcosφ \qquad ( 6 )$$

$${S}_{2} = {A}^{2} sin 2 θcosφ \qquad ( 7 )$$

$${S}_{3} = {A}^{2} sin 2 φ \qquad ( 8 )$$

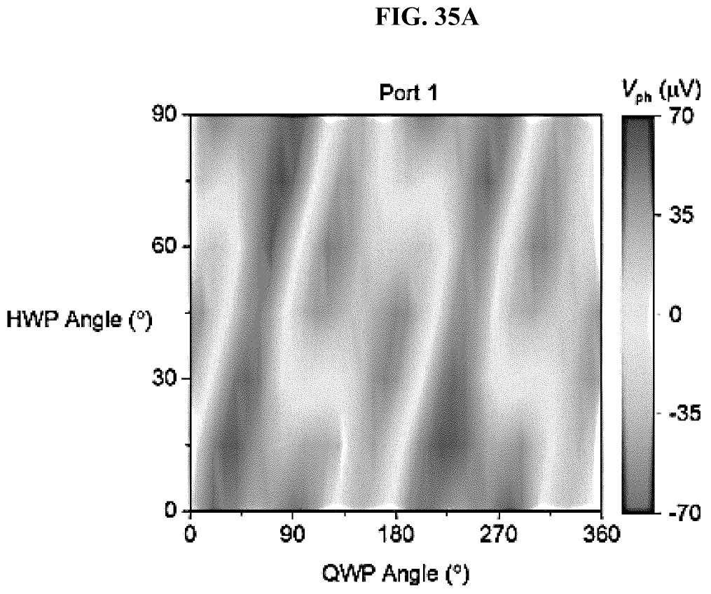

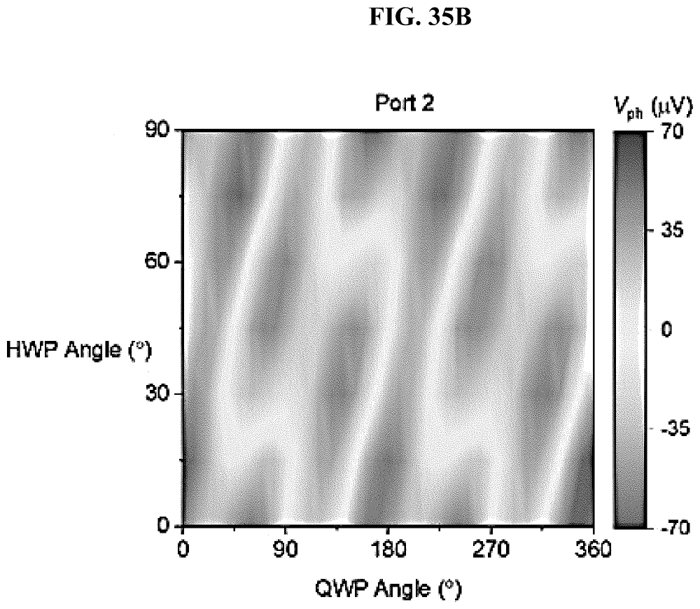

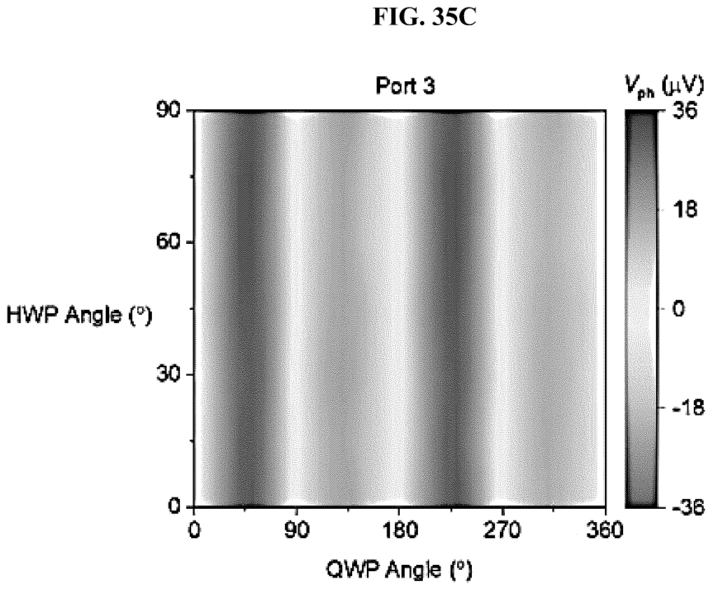

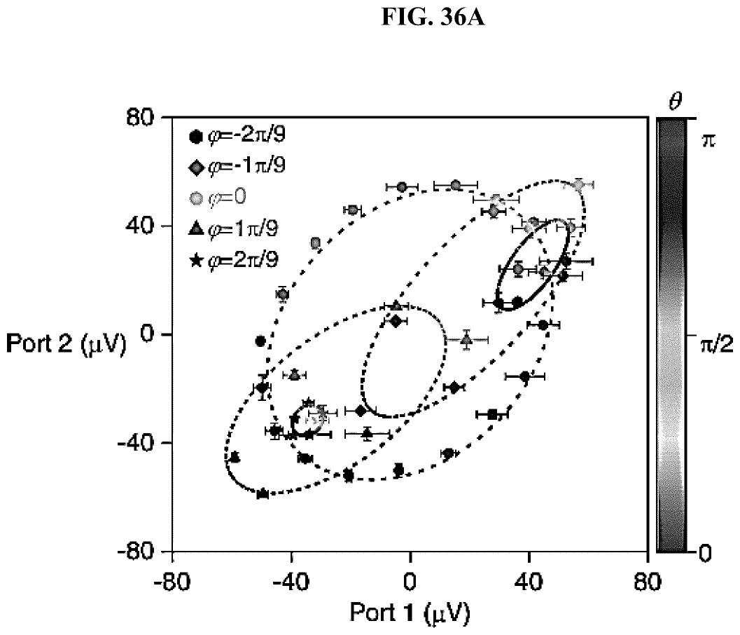

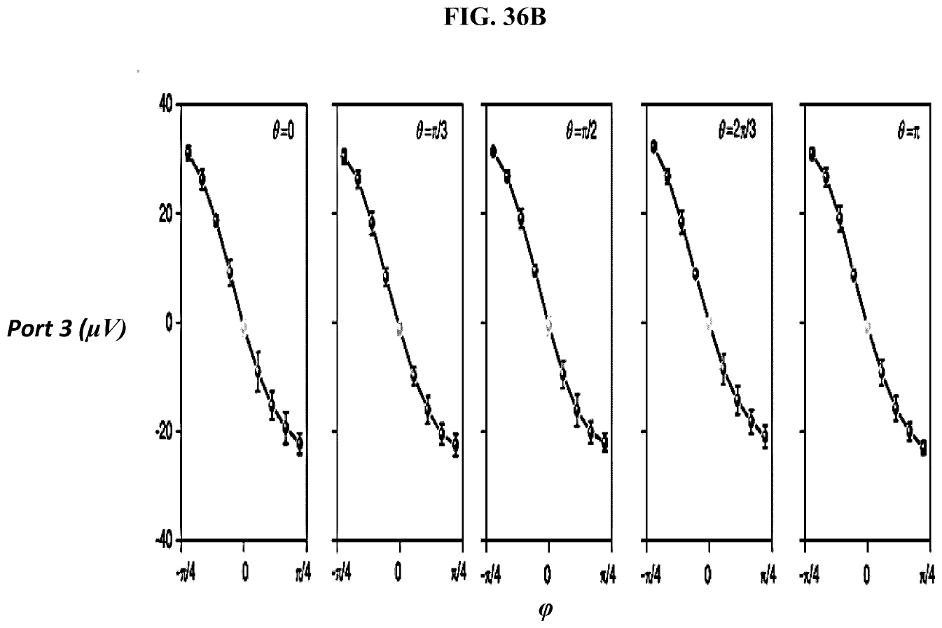

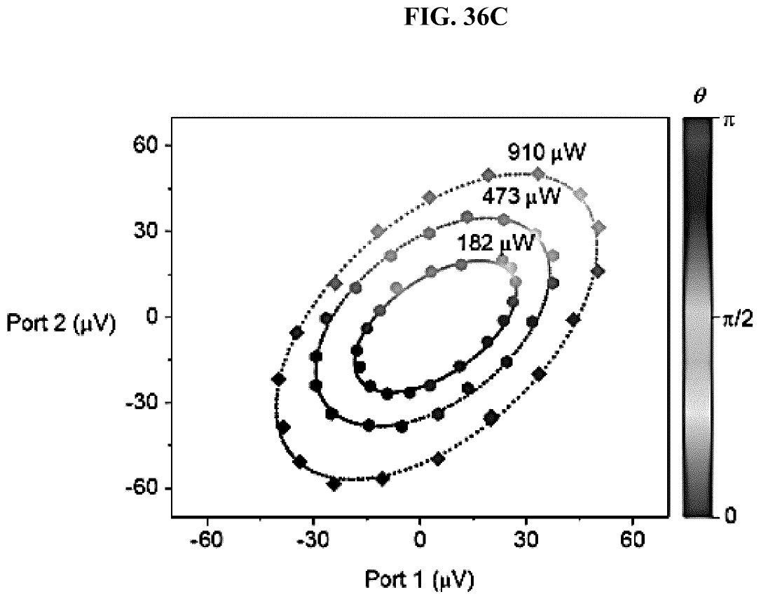

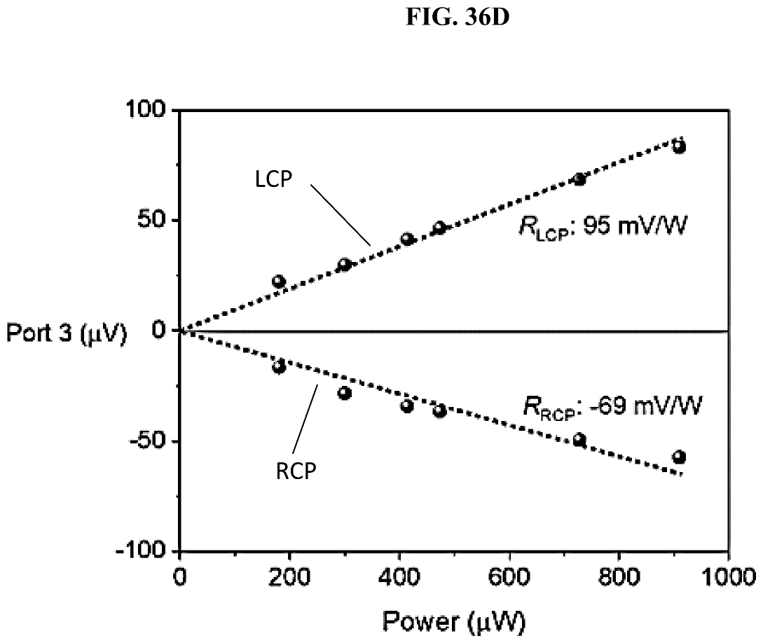

Generally, six individual pixels are required to fully retrieve the full-Stokes parameters. Here, taking advantages of the configurability of the proposed resonant PTE detection mechanism, a three-ports device may be designed to extract the geometrical ellipse parameters instead of the three Stokes parameters (S₁, S₂, and S₃). It's worth noting that, owing to the polarization-sensitive photoresponses of the three ports outputs, the Stokes parameter S₀ would not be extracted using the designed three-ports device. On the other hand, the SoP in this work is focused on fully polarized light but not on partially polarized or unpolarized light. As shown in FIG. 34A, the GND port is used as the ground terminal for other three ports. The relative orientation angle of LH and RH metamaterials distributed in triangle shape is set to be 200 to align their equivalent orientations as discussed above. With a consideration of the existence of a mirror symmetry in linear polarization-dependent photoresponse in the range of 0-180°, at least two outputs with a phase shift not equal to 90° are required to unambiguously detect the polarization angle. The equivalent orientation (arrows) for each part and the LH and RH metamaterials distributions may be designed in view of the abovementioned. Ports 1 and 2 of the device may be used to extract the azimuthal angle θ, and port 3 is used for extracting the ellipticity angle φ. To verify the unambiguous detection of SoP in the three-ports device, the photovoltage outputs of three ports are measured at different polarization angles obtained by changing the HWP and QWP angles but constant incident power. FIG. 35A shows a plot of half-wave plate (HWP) angle (degrees or °) as a function of quarter-wave plate (QWP) angle (degrees or °) illustrating the photoresponse (Vₚₕ) of Port 1 of the photodetector with HWP angle and QWP angle according to various embodiments. FIG. 35B shows a plot of half-wave plate (HWP) angle (degrees or °) as a function of quarter-wave plate (QWP) angle (degrees or °) illustrating the photoresponse (Vₚₕ) of Port 2 of the photodetector with HWP angle and QWP angle according to various embodiments. FIG. 35C shows a plot of half-wave plate (HWP) angle (degrees or °) as a function of quarter-wave plate (QWP) angle (degrees or °) illustrating the photoresponse (Vₚₕ) of Port 3 of the photodetector with HWP angle and QWP angle according to various embodiments. Based on the theoretical analyses and experimental results, the azimuthal angle θ and ellipticity angle (p may be calculated as follows:

$$\begin{matrix}θ = \frac{1}{2} ( {tan}^{- 1} \frac{{P}_{1} + {P}_{3}}{{P}_{2} + {P}_{3}} + 45 ) & when {P}_{2} < 0\end{matrix} \qquad ( 9 )$$

$$\begin{matrix}θ = \frac{1}{2} ( {tan}^{- 1} \frac{{P}_{1} + {P}_{3}}{{P}_{2} + {P}_{3}} + 45 ) + 90 & when {P}_{2} > 0\end{matrix} \qquad ( 10 )$$

$$φ = {tan}^{- 1} \frac{{P}_{3}}{C} \qquad ( 11 )$$

where C refers to the maximum photovoltage output under LCP or RCP light illumination with a typical incident power (the derivation of these expressions is provided below). FIG. 36A shows a two-dimensional (2D) plot of the photoresponse voltage at Port 2 (in microVolts or μV) as a function of the photoresponse voltage at Port 1 (in microVolts or μV) of the photodetector under different azimuthal angles θ and the ellipticity angles φ according to various embodiments. The symbols represent measured data, which are presented as mean values±standard deviation (SD), n=4 replicated measurements. The dashed lines are fitting curves. The shapes of the dots are based on the ellipticity angles φ of the incident polarized light, while the intensities of the dots are based on the azimuthal angle θ. For a typical ellipticity angle φ, the (Port 1, Port 2) pairs move anticlockwise along a closed elliptical curve. In addition, when the ellipticity angle φ changes from −45° to 45°, the elliptic centre moves from the first quadrant to the third quadrant through the origin point. Although the (Port 1, Port 2) pairs show a dependence on both the azimuthal angle θ and the ellipticity angle φ, another photovoltage output may be necessary to unambiguously detect the SoP. This is because there may be some intersections between the elliptic curves for different ellipticity angles φ.

FIG. 36B shows plots of the photoresponse voltage at Port 3 (in microVolts or μV) as a function of ellipticity angle φ (in radians) showing the variation of the photoresponse voltage with ellipticity angle φ at different azimuthal angles θ according to various embodiments. The symbols represent measured data, which are presented as mean values±standard deviation (SD), n=4 replicated measurements. The monotonic relationship between the Port 3 output and ellipticity angle φ ranging from −45° to 45° may enable the ellipticity angle (p to be directly readout even for different azimuthal angles θ. Furthermore, based on the relation between the incident light power and the photovoltage outputs of the three ports, the amplitude A with calibration can be obtained.

FIG. 36C shows a two-dimensional (2D) plot of the photoresponse voltage at Port 2 (in microVolts or μV) as a function of the photoresponse voltage at Port 1 (in microVolts or μV) of the photodetector under different incident light powers according to various embodiments. FIG. 36D shows a plot of the photoresponse voltage at Port 3 (in microVolts or μV) as a function of power (in microWatts or μW) illustrating the photoresponse for left-handed circular polarized (LCP) and right-handed circular polarized (RCP) light under different laser powers at the photodetector according to various embodiments. In order to evaluate the polarimetry accuracy of the three-ports device, the deviation of the three Stokes parameters may be calculated based on a set of measurements.

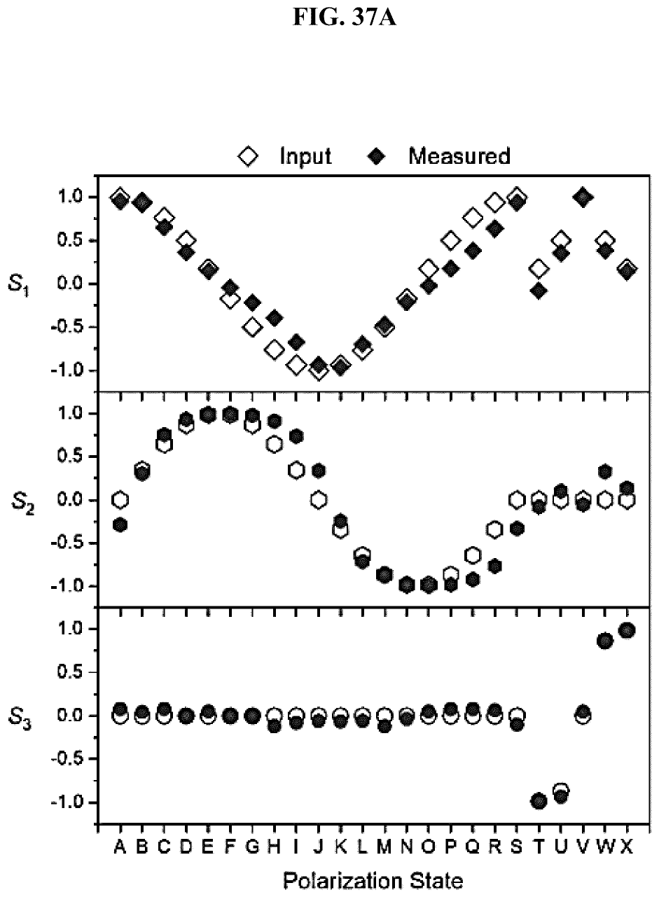

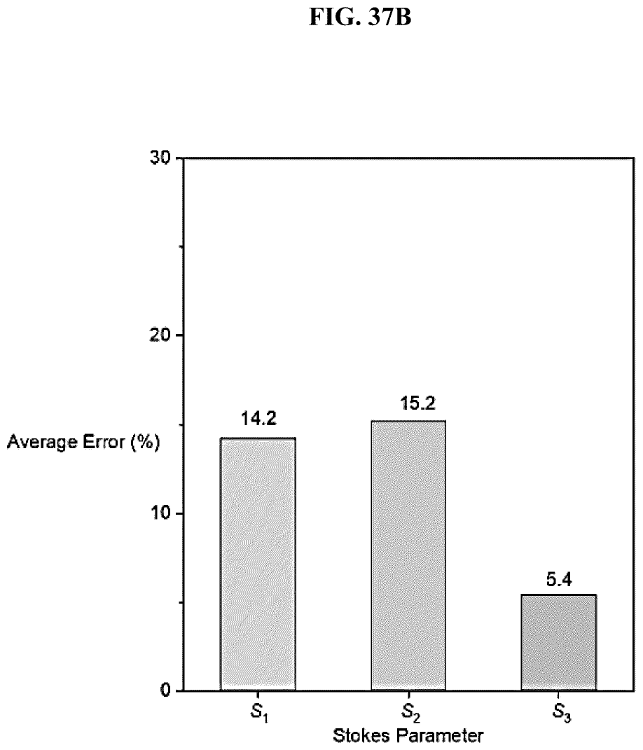

The result is shown in FIGS. 37A-B. FIG. 37A illustrates the retrieved Stokes parameters with different polarization states according to various embodiments. The hollow marks indicate input polarization states, and the solid marks indicate the measured polarization states. FIG. 37B shows a plot of average error (in percent or %) as a function of Stokes parameter illustrating the calculated average errors of three Stokes parameters (S₁, S₂ and S₃) according to various embodiments. The average measurement errors of S₁, S₂, and S₃ are 14.2%, 15.2%, and 5.4%, respectively. The relative higher measurement errors for S₁ and S₂ than that for S₃ can be attributed to the nonimmune photoresponses of Port 1 and Port 2 against the circular polarization. On the other hand, the imperfect fabrication of metamaterials, the imperfect Gaussian distribution of laser beam, the inaccuracy of input light polarization, and so on, will also introduce measurement errors for the Stokes parameters.

To highlight the practical usage of our polarimeter with the compact and simplified configuration, a polarization imaging application is demonstrated using the three-ports device. The polarimetric imaging enables us to obtain important information about the surfaces of targets by detecting the spatially and temporally varying SoP of light.

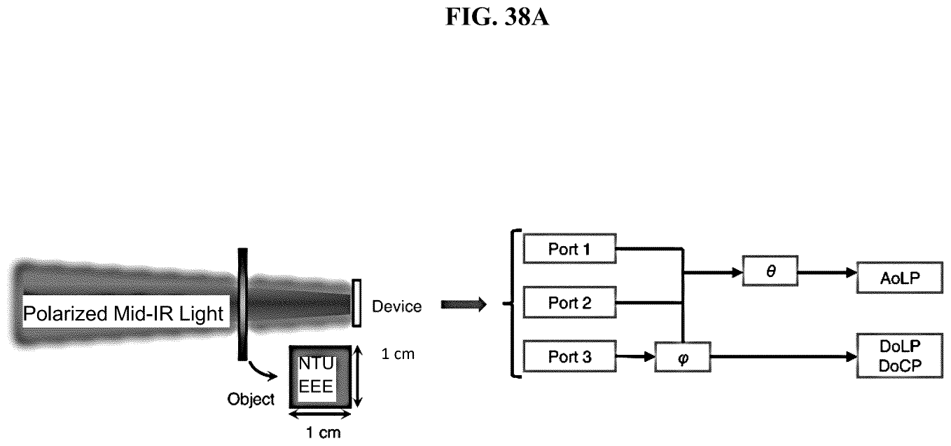

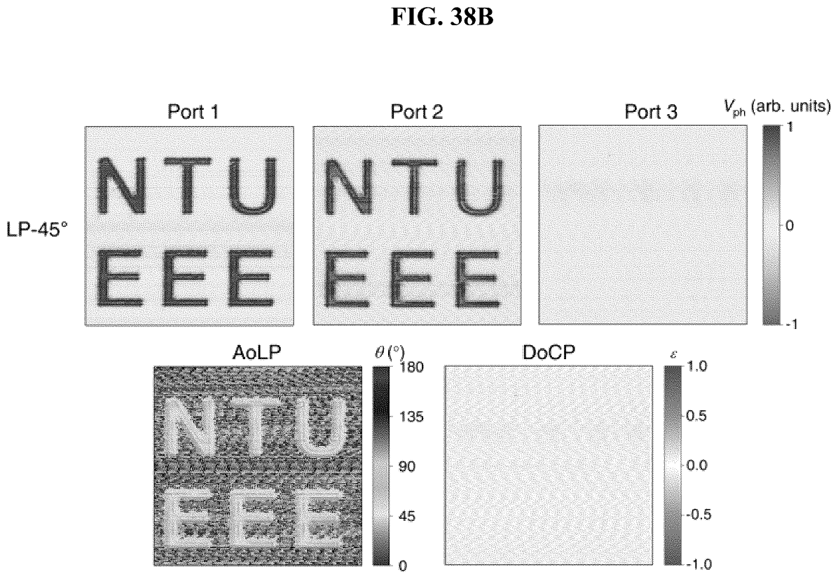

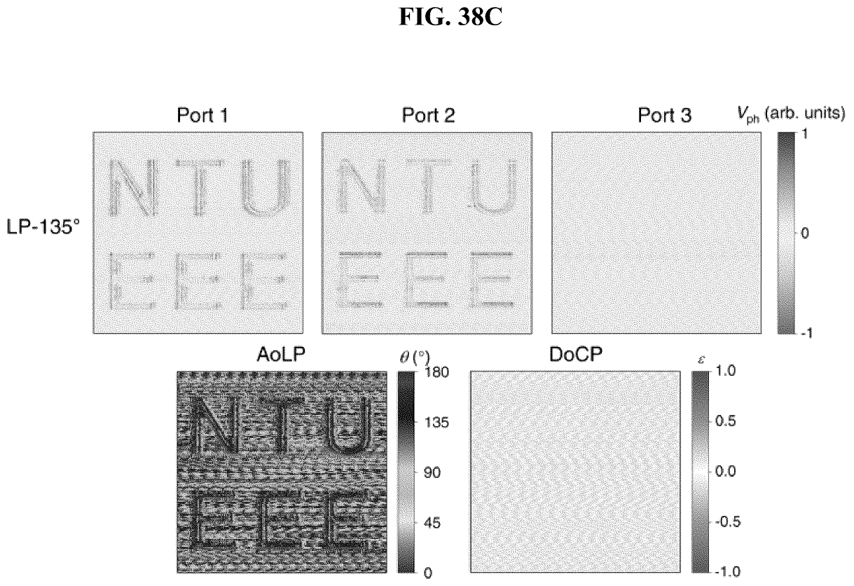

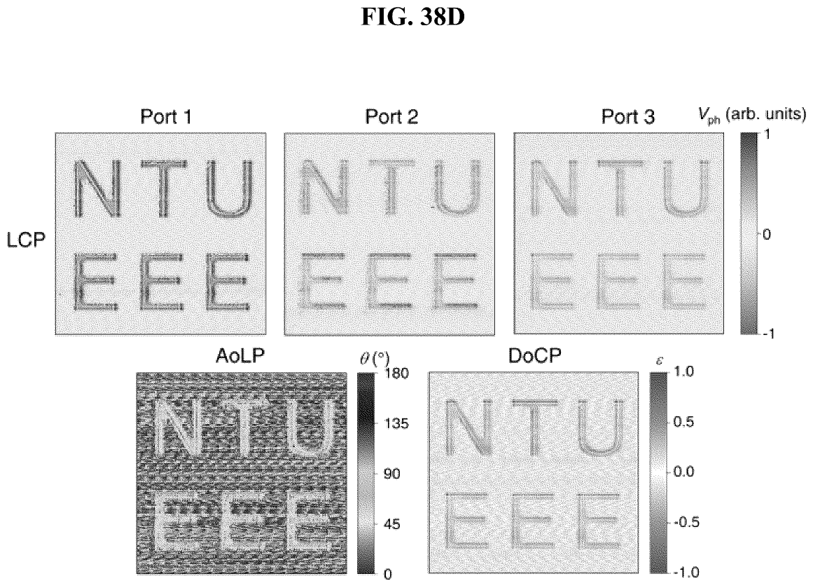

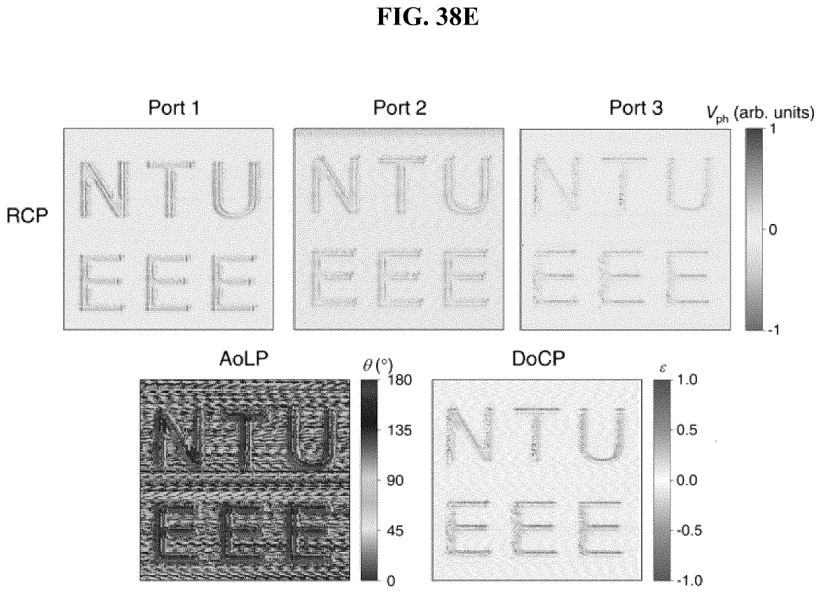

FIG. 38A shows a schematic of the polarimetric imaging measurement system and the mechanism for the calculation of angle of linear polarization (AoLP), degree of linear polarization (DoLP) or degree of circular polarization (DoCP) according to various embodiments. The inset is the schematic of the object with text patterns “NTU” and “EEE”. As shown in FIG. 38A, the polarized mid-IR light is illuminated onto the photodetector through an object with patterned NTU and EEE letters. Based on the photovoltage signal outputs from the three ports, both the ellipticity angle φ and the azimuthal angles θ can be calculated. In addition, the angle of linear polarization (AoLP), degree of linear polarization (DoLP), or degree of circular polarization (DoCP) can be calculated by data processing. Particularly, considering the pully polarized incident light, the DoCP and DoLP may be calculated as:

$$AOLP = θ \qquad ( 12 )$$

$$DoCP = \frac{2 εsin ( 2 φ )}{1 + {ε}^{2}} \qquad ( 13 )$$

$$DoLP = \sqrt{1 + {DoCP}^{2}} \qquad ( 14 )$$

where ε refers to the ellipticity and is calculated by ε=tan φ.

FIGS. 38B-E show the imaging results from three ports under a 5.3 μm light illumination with LP-45°, LP-135°, LCP, and RCP polarization statuses respectively. FIG. 38B shows the measured imaging results of the ports (Port 1, Port 2, and Port 3) and calculated imaging results of angle of linear polarization (AoLP) and degree of circular polarization (DoCP) under linear polarized (LP) 45° light illumination according to various embodiments. FIG. 38C shows the measured imaging results of the ports (Port 1, Port 2, and Port 3) and calculated imaging results of angle of linear polarization (AoLP) and degree of circular polarization (DoCP) under linear polarized (LP) 135° light illumination according to various embodiments. FIG. 38D shows the measured imaging results of the ports (Port 1, Port 2, and Port 3) and calculated imaging results of angle of linear polarization (AoLP) and degree of circular polarization (DoCP) under left circular polarized (LCP) light illumination according to various embodiments. FIG. 38E shows the measured imaging results of the ports (Port 1, Port 2, and Port 3) and calculated imaging results of angle of linear polarization (AoLP) and degree of circular polarization (DoCP) under right circular polarized (RCP) light illumination according to various embodiments.

For different polarizations of the incident light, all three ports can obtain clearer polarization imaging results and exhibit a typical combining form, which is a one-to-one correspondence to the SoP. In addition, both the corresponding AoLP and DoCP imaging results can also be obtained with data processing. Compared with conventional division-of-focal-plane polarimeters that require at least four signal outputs, the proposed three-ports device according to various embodiments including two bipolar linear polarization detectors and one bipolar circular polarization detector may show potential in high-resolution and fast polarization imaging applications owing to its compact configuration and simplified signal processing procedure. Therefore, various embodiments may show great potentials in mid-IR polarimetric imaging. For practical imaging applications, the size of single pixel, the crosstalk between adjacent pixels, and the scalability of the read-out circuit, may also need to be considered.

Various embodiments may relate to a mid-IR polarization-sensitive PTE detector with several advantages such as filterless, uncooled, bandgap-independent, tailorable in the operating wavelength, compact, and configurable in polarization-dependence. Combining the SoP-dependent optical response and the design flexibility of the chiral plasmonic metamaterials with the two-dimensional thermoelectric materials, polarity transition can be realized for both the linear and the circular polarizations. Leveraging on the bipolar photoresponse, a three-ports device has been demonstrated to unambiguously detect the SoP of incident light with a compact device configuration and a simplified signal process procedure. The infrared polarimetric imaging capability such as AoLP and DoCP imaging of the proposed detection strategy using the three-ports polarimeter has also been demonstrated. Various embodiments may show great potential as emerging optical technologies in the mid-IR range, such as polarimetric imaging, molecule sensing, fiber optics and/or free-space communications.

### Simulation

The simulation of optical responses and photothermal effect of the chiral plasmonic metamaterials were done using Lumerical finite difference time domain (FDTD) Solutions and HEAT packages. In all simulations, a single unit structure and a plane wave light source were used. Periodic boundary conditions and perfectly matched layers were used in the x&y boundaries and z boundaries, respectively. The simulated structure includes a silicon substrate, SiO₂ (285 nm thickness), gold metal layer or backplate (200 nm thickness), Al₂O₃ dielectric spacer (200-270 nm), gold metamaterials or antennas (50 nm thickness) and air. The power density absorption was calculated using the equation: P_{abs}=½ωε″|E|², where ω is the light frequency and ε″ is the imaginary part of the dielectric function. For the photothermal effect simulation in HEAT package, an import heat source according to the optical absorption data obtained from FDTD simulation result is used as the heat input. One temperature monitor placed surrounding the antenna is used to record the temperature profile. Considering the weak thermal flow through convection and diffusion at the boundaries, different boundary conditions were applied for different surfaces/interfaces in the simulations, i.e., (1) a convection of 10 W/(m²·K) is applied at the top surfaces of Au nanostructures and the Al₂O₃; (2) a heat flux of 10 W/m2 is set across the interfaces between Au and Al₂O₃, Au and SiO₂, SiO₂ and S₁ to simulate the weak thermal flow in the solid interfaces; (3) the temperature of the bottom boundary of the simulation domain is fixed as room temperature (293K). For the simulation of temperature distribution of device with large scale (2×2 mm²), COMSOL Multiphysics software with Heat Transfer Modules was used. The fixed temperature thermal boundary condition is applied at the surface of antennas according to the result from the photothermal effect simulation in the HEAT package, while other boundaries, which are far away from the Au nanostructures, has a temperature fixed as the room temperature (293 K).

### Device Fabrication

As the first step to device fabrication, a 200-nm-thick gold thin film (for forming the backplate or metal layer) and Al₂O₃ dielectric layer (for forming the dielectric spacer) with a typical thickness (200-270 nm) were first deposited onto a heavily p-doped silicon wafer grown with 285 nm thermal SiO₂ using e-beam evaporation. Then, electrodes and gold nanoantenna arrays were patterned on the chips using standard electron-beam lithography followed by thermal deposition of 5-nm thick chromium (Cr) and 50-nm-thick gold (Au) and lift-off process (submerging samples in acetone for 1 h). Thereafter, two-dimensional thermoelectric materials, such as Graphene (Gr), black phosphorus (BP), and palladium diselenide (PdSe₂) nanoflakes were mechanically exfoliated from their bulk crystal and then were transferred onto the special position of the chip with electrodes and metamaterials by a dry-transfer method.

### Characterization

The optical absorption and CD spectrum were obtained using a Fourier Transform Infrared spectrometer (FTIR, Bruker) with a microscope (Thermo Fisher). Linear and circular polarized lights are generated by using a linear polarizer and a quarter-wave plate. For the reflection spectra, the same sample without chiral metamaterials was used as the reference. The transmission is negligible due to the optically thick gold backplate. The absorbance spectra of the metamaterials were calculated by using equation: Abs(1−Ref)×100%. The polarized photoresponse is measured by using a homemade photocurrent measurement system where the infrared light with different polarization status is obtained from a serious quantum cascade lasers (Daylight Solutions, MIRcat) with high linear polarization purity (>100:1) and tunable wavelength in the range of 4-8 μm combining a half-wave plate and quarter-wave plate, and the focused on the samples using a zinc selenide IR focusing lens with a focal length of 50 mm. The generated photovoltage was then recorded by a highly sensitive source meter unit (Keysight, B2912A). For the low-temperature photoresponse measurement, the device is mounted in a vacuum cryostat with a temperature controller. Three wavelengths are selected based on the operating wavelength of the half-wave plate and quarter-wave plate, 4.5 μm (Thorlabs, WPLH05M-4500 and WPLQ05M-4500), 5.3 μm (Thorlabs, WPLH05M-5300 and WPLQ05M-5300), and 7.0 μm (Edmund, #85-121 and #85-114). The voltage noise is measured by using a lock-in amplifier (Zurich Instruments, HF2LI). The voltage data were collected within 1 min with a time constant of 1 μs and a typical internal reference frequency. The low frequency (<1 kHz) temporal photoresponse for response speed analysis was measured using an oscilloscope (Keysight, DSOX3054T) with the signal pre-amplified (Stanford Research Systems, SR570) and an optical chopper (Thorlabs, MC1F10A).

### Polarization Imaging Measurements

The imaging measurements are carried out by using a homemade imaging system. The polarized infrared light with different polarization status is obtained as mentioned above. An optical mask with “NTU EEE” letter was put into the light path and its position is controlled by two step motors along the x-axis and y-axis. By changing the mask location, the photoresponse signals from the three-ports device are amplified using a preamplifier and recorded by an oscilloscope.

### State of Polarization Dependent Absorption of the Chiral Metamaterials

As shown above, the state of polarization dependent absorption can fit well with a cosine function of the azimuthal angle θ with a weighted shift factor given by ellipticity angle φ. In detail, the extraction process of the coefficients (a₁, a₂, b₁, b₂) in the equation is as follows: Firstly, by fitting the azimuthal angle θ dependent absorption with a fixed ellipticity angle φ using a cosine function, a series of coefficients pairs (a, b) can be obtained. Secondly, the coefficient a as a sine function of ellipticity angle φ is fitted and two coefficients (a₁ and a₂) representing the constant component and the amplitude of the φ-resolved component can be obtained. Thirdly, the coefficient b as a cosine function of ellipticity angle φ is fitted and two coefficients (b₁ and b₂) representing the constant component and the amplitude of the φ-resolved component can also be obtained.

### Derivation of the Expressions for Calculation of Geometrical Ellipse Parameters

The photovoltage output of each port is polarization dependent as per design of the device. Particularly, the photovoltage outputs of Port 1 and Port 2 are linear and circular polarization dependent, and the photovoltage output of Port 3 is only circular polarization dependent. The general expression of the photovoltages for each part in the designed device can be expressed as:

$${V}_{ph} = {L}_{i} sin ( 2 θ ) + {C}_{i} tan ( φ ) \qquad ( 15 )$$

where Lᵢ sin(20) is the linear-polarization-resolved (θ-resolved) photovoltage component and Cᵢ tan (φ) is the circular-polarization-resolved (φ-resolved) photovoltage component. No constant background photoresponse is available due to the bipolar responses of our devices. In detail, the expression of each port in our three-ports device can be expressed as:

$${P}_{1} = ( {L}_{1} sin ( 2 ( θ + 45 ) ) + 0.5 {C}_{1} tan ( φ ) ) - ( {L}_{0} sin ( 2 θ ) - 0.5 {C}_{0} tan ( φ ) ) \qquad ( 16 )$$

$${P}_{2} = ( {L}_{2} sin ( 2 ( θ + 135 ) ) + 0.5 {C}_{2} tan ( φ ) ) - ( {L}_{0} sin ( 2 θ ) - 0.5 {C}_{0} tan ( φ ) ) \qquad ( 17 )$$

$${P}_{3} = ( {L}_{3} sin ( 2 ( θ ) ) + {C}_{3} tan ( φ ) ) - ( {L}_{0} sin ( 2 θ ) - {C}_{0} tan ( φ ) ) \qquad ( 18 )$$

Here, the coefficients (Lᵢ and Cᵢ) for each port output can be obtained by calibration with the experimental results. Based on the experimental results as shown in FIG. 35A-C, Equations (16)-(18) may be simplified as:

$${P}_{1} = ( {L}_{1}^{′} sin ( 2 ( θ - 112.5 ) ) + {C}_{1}^{′} tan ( φ ) ) \qquad ( 19 )$$

$${P}_{2} = ( {L}_{2}^{′} sin ( 2 ( θ - 67.5 ) ) + {C}_{2}^{′} tan ( φ ) ) \qquad ( 20 )$$

$${P}_{3} = - {C}_{3}^{′} tan ( φ ) \qquad ( 21 )$$

According to fitting results with experimental results, the coefficients can meet relationships as: L″=L₁′=L₂′, and C″=C₁′=C₂′=C₃′. Therefore, Equations (19)-(21) can be further simplified as:

$${P}_{1} = ( {L}^{″} sin ( 2 ( θ - 45 ) ) + {C}^{″} tan ( φ ) ) \qquad ( 22 )$$

$${P}_{2} = ( {L}^{″} cos ( 2 ( θ - 45 ) ) + {C}^{″} tan ( φ ) ) \qquad ( 23 )$$

$${P}_{3} = - {C}^{″} tan ( φ ) \qquad ( 24 )$$

Therefore, the azimuthal angle θ and ellipticity angle φ can be calculated as:

$$\begin{matrix}θ = \frac{1}{2} ( {tan}^{- 1} \frac{{P}_{1} + {P}_{3}}{{P}_{2} + {P}_{3}} + 45 ) & when {P}_{2} < 0\end{matrix} \qquad ( 25 )$$

$$\begin{matrix}θ = \frac{1}{2} ( {tan}^{- 1} \frac{{P}_{1} + {P}_{3}}{{P}_{2} + {P}_{3}} + 45 ) + 90 & when {P}_{2} > 0\end{matrix} \qquad ( 26 )$$

$$φ = {tan}^{- 1} \frac{{P}_{3}}{C} \qquad ( 27 )$$

where only one coefficient (C) is needed to be extracted, which is related to the incident light power.

On-chip polarimeters are highly desirable for next-generation ultra-compact optical and optoelectronic systems. So far, the polarization-sensitive photodetectors based on the anisotropy of natural/artificial materials has been emerged as a promising candidate for on-chip polarimeters. However, they are usually used either for linearly polarized light detection or for circularly polarized light detection. Various embodiments may relate to chiral plasmonic metamaterials-mediated mid-infrared thermoelectric photodetectors, which can detect the linear and circular polarization with geometrically configurable polarity transition. By manipulating the distribution of chiral metamaterials, the reversable temperature gradient built by photothermal effect is utilized to generate polarization-resolved photovoltage with a transition between unipolar and bipolar responses. Various embodiments may relate to a three-port device integrating three balanced photodetectors demonstrated as polarimeter for the full-Stokes detection, as well as the polarimetric imaging application. Various embodiments may provide an alternative strategy for next-generation ultra-compact optoelectronic devices, especially for developing multifunctional photodetectors with tunable bandgap-unlimited working wavelength in mid-infrared regime.

1. A photodetector pixel comprising:
a chiral plasmonic molecule array configured to generate heat upon incidence of an electromagnetic wave on the chiral plasmonic molecule array; and
a thermoelectric layer configured to generate an electric current or voltage upon transfer of heat from the chiral plasmonic molecule array to the thermoelectric layer; wherein the chiral plasmonic molecule array comprises a metal layer;
wherein the chiral plasmonic molecule array comprises one or more nanostructures;
wherein the chiral plasmonic molecule array comprises a dielectric spacer such that the dielectric spacer is between the metal layer and the one or more nanostructures; and
wherein the one or more nanostructures comprise one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

2. The photodetector pixel according to claim 1, wherein the thermoelectric layer comprises any material that exhibits Seebeck effect.

3. The photodetector pixel according to claim 1, wherein the thermoelectric layer comprises a two-dimensional (2D) thermoelectric material.

4. The photodetector pixel according to claim 1,
wherein the one or more left hand (LH) chiral metamaterial nanostructures are “Z” shaped nanostructures; and
wherein the one or more right hand (RH) chiral metamaterial nanostructures are “Z” shaped nanostructures.

5. The photodetector pixel according to claim 1, wherein the one or more nanostructures comprise a metal.

6. (canceled)

7. A photodetector comprising:
a first photodetector pixel;
a second photodetector pixel, the second photodetector pixel oriented substantially 90° to the first photodetector pixel;
a third photodetector pixel, the third photodetector oriented substantially 45° to the first photodetector pixel; and
a fourth photodetector pixel, the fourth photodetector pixel oriented substantially 45° to the first photodetector pixel;
wherein each of the first photodetector pixel, the second photodetector pixel, the third photodetector pixel and the fourth photodetector pixel comprises:
a chiral plasmonic molecule array configured to generate heat upon incidence of an electromagnetic wave on the chiral plasmonic molecule array; and
a thermoelectric layer configured to generate an electric current or voltage upon transfer of heat from the chiral plasmonic molecule array to the thermoelectric layer; wherein the chiral plasmonic molecule array comprises a metal layer;
wherein the chiral plasmonic molecule array comprises one or more nanostructures; and
wherein the chiral plasmonic molecule array comprises a dielectric spacer such that the dielectric spacer is between the metal layer and the one or more nanostructures;
wherein the one or more nanostructures of the first photodetector pixel comprise one or more left hand (LH) chiral metamaterial nanostructures and one or more right hand (RH) chiral metamaterial nanostructures;
wherein the one or more nanostructures of the second photodetector pixel comprise one or more left hand (LH) chiral metamaterial nanostructures and one or more right hand (RH) chiral metamaterial nanostructures:
wherein the one or more nanostructures of the third photodetector pixel comprise one or more left hand (LH) chiral metamaterial nanostructures:
wherein the one or more nanostructures of the fourth photodetector pixel comprise one or more right hand (RH) chiral metamaterial nanostructures:
wherein the third photodetector pixel or the fourth photodetector pixel is configured to determine an ellipticity angle of a state of polarization of the electromagnetic wave; and
wherein the first photodetector pixel and the second photodetector pixel are configured to determine an azimuthal angle of the state of polarization of the electromagnetic waves.

8. The photodetector according to claim 7,
wherein the one or more left hand (LH) chiral metamaterial nanostructures of the first photodetector pixel have an angle of substantially 20° relative to the one or more right hand (RH) chiral metamaterial nanostructures of the first photodetector pixel; and
wherein the one or more left hand (LH) chiral metamaterial nanostructures of the second photodetector pixel have an angle of substantially 20° relative to the one or more right hand (RH) chiral metamaterial nanostructures of the second photodetector pixel.

9. The photodetector according to claim 7, wherein the ellipticity angle is also determined by the first photodetector pixel and the second photodetector pixel.

10. A method of forming a photodetector pixel, the method comprising:
forming a chiral plasmonic molecule array configured to generate heat upon incidence of an electromagnetic wave on the chiral plasmonic molecule array; and
forming a thermoelectric layer configured to generate an electric current or voltage upon transfer of heat from the chiral plasmonic molecule array to the thermoelectric layer;
wherein the chiral plasmonic molecule array comprises a metal layer;
wherein the chiral plasmonic molecule array comprises one or more nanostructures;
wherein the chiral plasmonic molecule array comprises a dielectric spacer such that the dielectric spacer is between the metal layer and the one or more nanostructures; and
wherein the one or more nanostructures comprise one or more left hand (LH) chiral metamaterial nanostructures, one or more right hand (RH) chiral metamaterial nanostructures, or one or more left hand (LH) chiral metamaterial nanostructures and one or more right hand (RH) chiral metamaterial nanostructures.

11. The method according to claim 10, wherein the thermoelectric layer comprises any material that exhibits Seebeck effect.

12. The method according to claim 10, wherein the thermoelectric layer comprises a two-dimensional (2D) thermoelectric material.

13. The method according to claim 10,
wherein forming the chiral plasmonic molecule array comprises forming the metal layer over a substrate;
wherein forming the chiral plasmonic molecule array further comprises forming the dielectric spacer over the metal layer; and
wherein forming the chiral plasmonic molecule array also comprises forming the one or more nanostructures over the dielectric spacer.

14. The method according to claim 13,
wherein the metal layer is formed using electron beam evaporation or thermal evaporation;
where the dielectric spacer is formed using electron beam evaporation or thermal evaporation; and
wherein the one or more nanostructures is formed using a lithography process.

15. The method according to claim 10, wherein the thermoelectric layer is formed over the chiral plasmonic molecule array.

16. The method according to claim 15, wherein the thermoelectric layer is formed over the chiral plasmonic molecule array via a dry-transfer method.

17. The method according to claim 10,
wherein the one or more left hand (LH) chiral metamaterial nanostructures are “Z” shaped nanostructures; and
wherein the one or more right hand (RH) chiral metamaterial nanostructures are “Z” shaped nanostructures.

18. The method according to claim 10, wherein the one or more nanostructures comprise a metal.

19. A method of forming a photodetector, the method comprising:
forming a first photodetector pixel;
forming a second photodetector pixel, the second photodetector pixel oriented substantially 90° to the first photodetector pixel;
forming a third photodetector pixel, the third photodetector oriented substantially 45° to the first photodetector pixel; and
forming a fourth photodetector pixel, the fourth photodetector pixel oriented substantially 45° to the first photodetector pixel;
wherein each of the first photodetector pixel, the second photodetector pixel, the third photodetector pixel and the fourth photodetector pixel comprises:
a chiral plasmonic molecule array configured to generate heat upon incidence of an electromagnetic wave on the chiral plasmonic molecule array; and
a thermoelectric layer configured to generate an electric current or voltage upon transfer of heat from the chiral plasmonic molecule array to the thermoelectric layer; wherein the chiral plasmonic molecule array comprises a metal layer;
wherein the chiral plasmonic molecule array comprises one or more nanostructures; and
wherein the chiral plasmonic molecule array comprises a dielectric spacer such that the dielectric spacer is between the metal layer and the one or more nanostructures:
wherein the one or more nanostructures of the first photodetector pixel comprise one or more left hand (LH) chiral metamaterial nanostructures and one or more right hand (RH) chiral metamaterial nanostructures:
wherein the one or more nanostructures of the second photodetector pixel comprise one or more left hand (LH) chiral metamaterial nanostructures and one or more right hand (RH) chiral metamaterial nanostructures:
wherein the one or more nanostructures of the third photodetector pixel comprise one or more left hand (LH) chiral metamaterial nanostructures:
wherein the one or more nanostructures of the fourth photodetector pixel comprise one or more right hand (RH) chiral metamaterial nanostructures:
wherein the third photodetector pixel or the fourth photodetector pixel is configured to determine an ellipticity angle of a state of polarization of the electromagnetic wave; and
wherein the first photodetector pixel and the second photodetector pixel are configured to determine an azimuthal angle of the state of polarization of the electromagnetic waves.

20. The method according to claim 19,
wherein the one or more left hand (LH) chiral metamaterial nanostructures of the first photodetector pixel have an angle of substantially 20° relative to the one or more right hand (RH) chiral metamaterial nanostructures of the first photodetector pixel; and
wherein the one or more left hand (LH) chiral metamaterial nanostructures of the second photodetector pixel have an angle of substantially 20° relative to the one or more right hand (RH) chiral metamaterial nanostructures of the second photodetector pixel.

21. The method according to claim 19, wherein the ellipticity angle is also determined by the first photodetector pixel and the second photodetector pixel.
